(19) United States
(12) Patent Application Publication
(10) Pub. No.: US 2025/0326969 A1
(43) Pub. Date: Oct. 23, 2025

(54) INTERCONNECTED NANODOMAIN NETWORKS, METHODS OF MAKING, AND USES THEREOF

(71) Applicant: University of Florida Research Foundation, Inc., Gainesville, FL (US)

(72) Inventors: Yunwei Charles CAO, Gainesville, FL (US); Tianyuan XIAO, Gainesville, FL (US); Derek LAMONTAGNE, Gainesville, FL (US)

(21) Appl. No.: 18/870,767

(22) PCT Filed: Jun. 27, 2023
(86) PCT No.: PCT/US2023/069139

§ 371 Date: Dec. 2, 2024

Related U.S. Application Data
(60) Provisional application No. 63/367,057, filed on Jun. 27, 2022.

(51) Int. Cl. C09K 11/88; B82Y 20/00; B82Y 40/00; C09K 11/02; C09K 11/08; C09K 11/56; C09K 11/61; C09K 11/66; C09K 11/70

(52) U.S. Cl. CPC C09K 11/883; C09K 11/02; C09K 11/0883; C09K 11/565; C09K 11/616; C09K 11/665; C09K 11/70; C09K 11/881; B82Y 20/00; B82Y 40/00

(57) ABSTRACT

In one aspect, the disclosure relates to nanocrystal solids including a metastable high-pressure phase that is kinetically trapped at ambient conditions and a second phase that is thermodynamically stable at ambient conditions, methods of making the same, and articles including the same. In one aspect, the methods are generalizable across a wide range of materials. In another aspect, the nanocrystal solids may form superconducting or semiconducting materials useful in computing and other fields. This abstract is intended as a scanning tool for purposes of searching in the particular art and is not intended to be limiting of the present disclosure.

### CROSS-REFERENCE TO RELATED APPLICATIONS

This application claims the benefit of U.S. Provisional Application No. 63/367,057, filed on Jun. 27, 2022, which is incorporated herein by reference in its entirety.

### STATEMENT REGARDING FEDERALLY SPONSORED RESEARCH OR DEVELOPMENT

This invention was made with government support under Grant No. DMR1309798 and Grant No. 1710509 awarded by the National Science Foundation. The government has certain rights in the invention.

### BACKGROUND

Solids from a collection of atoms can adopt a variety of structural phases having respective physical and chemical properties, providing the foundation for materials discovery. At ambient temperature and pressure, there is often one thermodynamically stable phase for a given atomic collection, and the rest can potentially become metastable as kinetically trapped phases with positive free energy above the equilibrium state. A general strategy for engineering kinetic barriers has yet to be developed but is essential for the rational synthesis of new materials and for expanding the space of synthesizable metastable materials.

Phase transformations in bulk solids exhibit complex kinetics involving different microscopic pathways occurring in parallel at different locations in one crystal domain, which are thus difficult to determine experimentally. On the other hand, transition pressures measured in experiments match well with the theoretical values determined via electronic structure calculations. For instance, the thermodynamic transition in silicon from a diamond to a β-tin structure was calculated to be 8.0 GPa, while this transformation was observed experimentally in the range 8.8-12.5 GPa. However, based on theoretical stability analysis, Mizushima, Yip, and Kaxiras (MYK) have predicted that defect- and strain-free bulk Si can remain metastable in the diamond structure up to 64 GPa, which implies a huge intrinsic activation barrier (˜0.3 eV/atom) in the structural transformation. This discrepancy indicates that the predicted intrinsic energy barrier in ideal crystals is drastically decreased by mechanisms associated with defects in real bulk solids during high-pressure experiments.

Despite advances in materials research, there is still a scarcity of useful nanocrystal systems that able to host metastable high-energy phases at ambient conditions. Similarly, there is no known, generalizable method for producing such systems. These needs and other needs are satisfied by the present disclosure.

### SUMMARY

In accordance with the purpose(s) of the present disclosure, as embodied and broadly described herein, the disclosure, in one aspect, relates to nanocrystal solids including a metastable high-pressure phase that is kinetically trapped at ambient conditions and a second phase that is thermodynamically stable at ambient conditions, methods of making the same, and articles including the same. In one aspect, the methods are generalizable across a wide range of materials. In another aspect, the nanocrystal solids may form superconducting or semiconducting materials useful in computing and other fields.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIGS. 1A-1B show pressure evolution of WAXS and SAXS patterns during compression and decompression (de) process of 8.2-nm spherical PbS nanocrystals functionalized with dodecylamine of (FIG. 1A) 62% surface coverage, and (FIG. 1B) 95% surface coverage.

FIGS. 2A-2B show pressure evolution of WAXS and SAXS patterns during compression and decompression (de) process of 8.2-nm spherical PbSe nanocrystals functionalized with dodecylamine of (FIG. 2A) 62% surface coverage, and (FIG. 2B) 95% surface coverage.

FIGS. 3A-3B show pressure evolution of WAXS and SAXS patterns during compression and decompression (de) process of 14.0-nm spherical PbTe nanocrystals functionalized with dodecylamine of (FIG. 3A) 62% surface coverage, and (FIG. 3B) 95% surface coverage.

FIGS. 4A-4B show pressure evolution of WAXS and SAXS patterns during compression and decompression (de) process of 4.8-nm spherical InP nanocrystals with different ligand coverage: (FIG. 4A) a mixture of butylamine and CTAB (with a molar ratio of 5:1) of 58% surface coverage in terms of hydrocarbon chains, and (FIG. 4B) butylamine with 89% surface coverage.

FIGS. 5A-5B show pressure evolution of WAXS and SAXS patterns during compression and decompression (de) process of 35-nm MnS nanocrystals with full oleylamine coverage (FIG. 5A) without pressure medium and (FIG. 5B) with oleylamine as pressure medium.

FIG. 6 shows a temperature profile as function of time. The temperature increase process labeled as 1, 3, 5, 7, 9, 11 took 20±2 s, 24±3 s, 28±3 s, 30±5 s, 35±6 s, and 40±10 s, respectively; the cooling process labeled as 2, 4, 6, 8, 10, 12 took 25±5 s, 30±5 s, 33±7 s, 38±8 s, 41±10 s, and 45±13 s, respectively. Temperature fluctuation is less than ±0.2° C. at each setting.

FIGS. 7A-7F show mechanism of thermos induced RS-to-ZB phase transition. FIG. 7A: Schematic of nanodomain breakage after heat treatment; FIG. 7B: Propagation of RS-to-ZB in interconnected nanodomain network i: initiation step, ii: propagation step, and iii: termination step; FIG. 7C: 4.8-nm CdS nanospheres in RS phase; FIG. 7D: 4.8-nm CdS nanospheres after pressurization and heat treatment; FIG. 7E: 23.8-nm CdSe/CdS nanorods after pressurization process retained in RS phase; and FIG. 7F: 23.8-nm CdSe/CdS nanorods after pressurization process and heat treatment, inserts is length distribution collected of resulting nanorods. Length distribution data collected from FIGS. 25A-26I.

FIGS. 8Ai-8Bvi show TEM images, electron diffraction pattern, and integrated ED pattern of rock-salt sample under high density electron beam (310-620 e·Å⁻¹·s⁻¹) for a designated period of time. TEM imaging and electron diffraction pattern collection were conducted under low density electron beam of 6.2-12.5 e·Å⁻¹·s⁻¹. (FIGS. 8Ai-8Aix) CdSe/CdS core/shell nanorods after high density electron beam irradiation of (FIGS. 8Ai-8Aiii) 0 s, (FIGS. 8Aiv-8Avi) 0.5 s, and (FIGS. 8Avii-8Aix) 2.0 s. (FIGS. 8Bi-8Bvi) Spherical CdSe/CdS core/shell nanocrystals after high density electron beam irradiation of (FIGS. 8Bi-8Biii) 0 s and (FIGS. 8Biv-8Bvi) 2.0 s.

FIG. 9 shows state space of a dimer system comprising 4 states and 4 transitions.

FIG. 10 shows a flow chart of the simulation program based on coarse-grain analysis.

FIG. 11 shows a schematic of state-space transition of a CTMC model comprising 4-nanocrystals.

FIG. 12 shows a transition rate matrix Q in a CTMC model with all nanocrystals interconnected in real space. The color pattern in the transition rate matrix indicates the transition rate constant as a function of the number of neighboring nanocrystals reacted.

FIG. 13 shows state space of a dimer system having nanocrystals in RS phase and ZB phase.

FIG. 14 shows probability vs time for each state in a dimer system.

FIG. 15 shows the fraction of nanocrystals in RS phase vs time.

FIG. 16 shows a simulated decay curve for analysis.

FIG. 17 shows a simulation of dependent reaction with activation energy distribution.

FIG. 18A shows a simulation of dimer clusters with different impact energies. FIG. 18B shows a simulation of trimer clusters with different impact energies. FIG. 18C shows a decay curve of a dimer cluster with increasing impact energies.

FIGS. 19A-19G show size distribution combined with WTA coupled cluster. FIG. 19A: Decay curve following WTA model as a function of cluster size; FIGS. 19B-19D: Size distribution with FIG. 19B: Exponential-decay, FIG. 19C: Gaussian, and FIG. 19D: U-shaped model; FIGS. 19E-19G: Simulated decay curve with FIG. 19E: exponential decay, FIG. 19F: Gaussian, and FIG. 19G: U-shaped size distribution model.

FIGS. 20A-20C show simulation results of heating treatment for 8-nm CdS nanocrystals capped with (N₂H₅)₄Sn₂S₆ after pressed processed at 21.0 GPa. FIG. 20A: Experimental and simulated RS phase fraction at different temperatures; FIG. 20B: Experimental and simulated RS phase fraction during heating treatment at 300° C. for different time; and FIG. 20C: Simulated activation energy distribution profiles before and after stepwise heat treatment.

FIGS. 21A-21M show Upper size limit of stable rock-salt phase in CdS nanocrystals. (FIGS. 21A-21J) CdS nanocrystals in different sizes used in this study. (FIGS. 21K-21L) WAXS spectrum of CdS nanocrystals (FIG. 21K) before and (FIG. 21L) after compression-decompression process, WAXS spectrum were labeled with initial nanoparticle size determined by TEM. (FIG. 21M) percentage of rock-salt sample retained at different domain sizes; a critical size of 23 nm was determined by this study. Rock-salt domain sizes were calculated using Scherrer equation.

FIGS. 22A-22E show FIG. 22A: WAXS pattern of 5.5-nm PbSe under different temperature showing a lower limit to retain metastable high-pressure phase; FIGS. 22B-22E: Electron microscope measurements of the pressurized nanocrystal superlattices, FIG. 22B: SEM image. FIGS. 22C-22E: TEM images. The insert in FIG. 22E is the FFT pattern of the image.

FIG. 23A-23L shows TEM images of II-VI semiconductor nanocrystals in this work. FIG. 23A. 4.8-nm CdS nanospheres; FIG. 23B: 8-nm CdS nanospheres; FIG. 23C: 4.8-nm CdSe/CdS nanospheres; FIG. 23D: 8-nm CdSeCdS nanospheres; FIG. 23E: 23.8-nm CdSe/CdS nanorods; FIG. 23F: 24.5-nm CdS nanorods; FIG. 23G: 5.5-nm PbSe nanospheres; FIG. 23H: 8.2-nm PbSe nanospheres; FIG. 23I: 8.2-nm PbS nanospheres, FIG. 23J: 8-nm PbTe nanospheres; FIG. 23K: 4.4-nm InP nanospheres; and FIG. 23L: 40-nm MnS nanocrystals.

FIGS. 24A-24B show SAXS and WAXS of (FIG. 24A) 8.2-nm PbSe and (FIG. 24B) 8.2-nm PbS capped with 62% dodecylamine under different pressure. The second CsCl phase was not sufficient at highest pressure to stable orthorhombic phase under ambient conditions.

FIGS. 25A-25L show TEM images of interconnected nanocrystal networks after stepwise heat treatment with different building blocks. FIGS. 25A-25B: 23.8-nm CdSe/CdS nanorods; FIGS. 25C-25D: 24.5-nm CdS/CdS nanorods; FIGS. 25E-25F: 4.8-nm CdS nanospheres; FIGS. 25G-25H: 8-nm CdS nanocrystals; FIGS. 25I-25J: 4.8-nm CdSe/CdS nanospheres; and FIGS. 25K-25L: 8-nm CdSe/CdS nanospheres.

FIGS. 26A-26I show (FIGS. 26A-26F): TEM and (FIGS. 26G-26I): HR-TEM images of interconnected nanocrystal networks after stepwise heat treatment with different building blocks made from 23.8-nm CdSe/CdS nanorods.

FIGS. 27A-27L show TEM and HR-TEM images of interconnected nanocrystal networks after stepwise heat treatment with FIGS. 27A-27F: 4.8-nm CdS nanocrystals and FIGS. 27G-27L: 8-nm CdS nanocrystals.

FIGS. 28A-28B show WAXS peak deconvolution of 4.8-nm CdS nanocrystals in RS/ZB mixture phases in a stepwise heating treatment. Scherrer domain size are consistent in both RS phase (3.55 nm at RT and 3.57 at 140° C.) and in ZB phase (3.28 at 140° C. and 3.31 nm at 260° C.). FIG. 28A: Experimental results and simulated results; FIG. 28B: Peak deconvolution of experimental results.

FIGS. 29A-29D show TEM beam damage of interconnected CdS nanocrystals in RS phase showing clusterwise reaction. FIG. 29A: Before strong beam irradiation; FIG. 29B: After strong beam irradiation for 0.5 seconds; FIG. 29C: After weak beam irradiation for 5 minutes; and FIG. 29D: Zoom in of partially reacted area showing clusterwise reaction.

FIGS. 30A-30C show conductivity measurements of nanocrystals before heat treatment in RS phase and after heat treatment in ZB phase. FIG. 30A: 4.8-nm CdS nanocrystals; FIG. 30B: 4.8-nm CdSe/CdS nanocrystals; and FIG. 30C: 23.8-nm CdSe/CdS nanorods. Conductivity measured as 3.5±0.2 mS, 3.6±0.3 mS and 6.0±0.7 mS for 4.8-nm CdS nanospheres, 4.8-nm CdSe/CdS nanospheres, and 23.8-nm CdSe/CdS nanorods in RS phase before heating treatment, respectively. After heating treatment, all samples exhibit non-detectable conductivity.

FIGS. 31A-31D show schematics of transition rate matrix representing the topology of real-space, with four nanocrystals forming different structures. FIG. 31A: interconnected to each other; FIG. 31B: circular structure; FIG. 31C: branching structure; and FIG. 31D: linear structure.

FIG. 32 shows evolution of apparent activation energy distribution from initial distribution with mean of 1.25 eV and standard deviation of 0.15 eV following WTA model.

FIG. 33 shows a coupled dimer system fitted by independent first-order reaction system with an activation energy distribution.

FIGS. 34A-34D show heating treatment of 4.8-nm CdS nanospheres capped with octylamine in RS phase. The high-pressure treatment lasted for ten minutes before releasing pressure. FIG. 34A: Experimental and simulated result of RS phase fraction at different temperatures; FIG. 34B: Simulated activation energy distribution profile evolution as temperature increases; FIG. 34C: WAXS pattern at different temperatures; and FIG. 34D: Initial SAXS pattern of RS phase sample.

FIGS. 35A-35D show heating treatment of 4.8-nm CdS nanospheres capped with octylamine in RS phase. The high-pressure treatment lasted for three hours before releasing pressure. FIG. 35A: Experimental and simulated result of RS phase fraction at different temperatures; FIG. 35B: Simulated activation energy distribution profile evolution as temperature increases; FIG. 35C: WAXS pattern at different temperatures; and FIG. 35D: Initial SAXS pattern of RS phase sample.

FIGS. 36A-36D show heating treatment of 4.8-nm CdS nanospheres capped with octylamine in RS phase. The high-pressure treatment lasted for eight hours before releasing pressure. FIG. 36A: Experimental and simulated result of RS phase fraction at different temperatures; FIG. 36B: Simulated activation energy distribution profile evolution as temperature increases; FIG. 36C: WAXS pattern at different temperatures; and FIG. 36D: Initial SAXS pattern of RS phase sample.

FIGS. 37A-37D show heating treatment of 4.8-nm CdS nanospheres capped with (N₂H₅)₄Sn₂S₆ inorganic ligand in RS phase. FIG. 37A: Experimental and simulated result of RS phase fraction at different temperatures; FIG. 37B: Simulated activation energy distribution profile evolution as temperature increases; FIG. 37C: WAXS pattern at different temperatures; and FIG. 37D: Initial SAXS pattern of RS phase sample.

FIGS. 38A-38D show heating treatment of 4.8-nm CdS nanospheres capped with (NH₄)₂S inorganic ligand in RS phase. FIG. 38A: Experimental and simulated result of RS phase fraction at different temperatures; FIG. 38B: Simulated activation energy distribution profile evolution as temperature increases; FIG. 38C: WAXS pattern at different temperatures; and FIG. 38D: Initial SAXS pattern of RS phase sample.

FIGS. 39A-39D show heating treatment of 4.8-nm CdS nanospheres capped with (NH₄)₂S inorganic ligand in RS phase. The initial sample was soaked in Cd(NO₃)₂-methanol solution for 8 hours before pressurization process. FIG. 39A: Experimental and simulated result of RS phase fraction at different temperatures; FIG. 39B: Simulated activation energy distribution profile evolution as temperature increases; FIG. 39C: WAXS pattern at different temperatures; and FIG. 39D: Initial SAXS pattern of RS phase sample.

FIGS. 40A-40D show heating treatment of 4.8-nm CdS nanospheres capped with (NH₄)₂S inorganic ligand in RS phase. The initial sample was soaked in Ca(NO₃)₂-methanol solution for 8 hours before pressurization process. FIG. 40A: Experimental and simulated result of RS phase fraction at different temperatures; FIG. 40B: Simulated activation energy distribution profile evolution as temperature increases; FIG. 40C: WAXS pattern at different temperatures; and FIG. 40D: Initial SAXS pattern of RS phase sample.

FIGS. 41A-41D show heating treatment of 8-nm CdS nanospheres capped with octylamine in RS phase. FIG. 41A: Experimental and simulated result of RS phase fraction at different temperatures; FIG. 41B: Simulated activation energy distribution profile evolution as temperature increases; FIG. 41C: WAXS pattern at different temperatures; and FIG. 41D: Initial SAXS pattern of RS phase sample.

FIGS. 42A-42D show heating treatment of 8-nm CdS nanospheres capped with (N₂H₅)₄Sn₂S₆ inorganic ligand in RS phase, the highest pressure applied was 15.5 GPa before releasing pressure. FIG. 42A: Experimental and simulated result of RS phase fraction at different temperatures; FIG. 42B: Simulated activation energy distribution profile evolution as temperature increases; FIG. 42C: WAXS pattern at different temperatures; and FIG. 42D: Initial SAXS pattern of RS phase sample.

FIGS. 43A-43D show heating treatment of 8-nm CdS nanospheres capped with (N₂H₅)₄Sn₂S₆ inorganic ligand in RS phase, the highest pressure applied was 21.0 GPa before releasing pressure. FIG. 43A: Experimental and simulated result of RS phase fraction at different temperatures; FIG. 43B: Simulated activation energy distribution profile evolution as temperature increases; FIG. 43C: WAXS pattern at different temperatures; and FIG. 43D: Initial SAXS pattern of RS phase sample.

FIGS. 44A-44D show heating treatment of 8-nm CdS nanospheres capped with (N₂H₅)₄Sn₂S₆ inorganic ligand in RS phase, the sample was soaked in pure octylamine for 8 hours before pressurization process. FIG. 44A: Experimental and simulated result of RS phase fraction at different temperatures; FIG. 44B: Simulated activation energy distribution profile evolution as temperature increases; FIG. 44C: WAXS pattern at different temperatures; and FIG. 44D: Initial SAXS pattern of RS phase sample.

FIGS. 45A-45D show heating treatment of 8-nm CdS nanospheres capped with (NH₄)2ₛ inorganic ligand in RS phase. FIG. 45A: Experimental and simulated result of RS phase fraction at different temperatures; FIG. 45B: Simulated activation energy distribution profile evolution as temperature increases; FIG. 45C: WAXS pattern at different temperatures; and FIG. 45D: Initial SAXS pattern of RS phase sample.

FIGS. 46A-46D show heating treatment of 8-nm CdS nanospheres capped with (NH₄)₂S inorganic ligand in RS phase. The initial sample was soaked in Cd(NO₃)₂-methanol solution for 8 hours before pressurization process. FIG. 46A: Experimental and simulated result of RS phase fraction at different temperatures; FIG. 46B: Simulated activation energy distribution profile evolution as temperature increases; FIG. 46C: WAXS pattern at different temperatures; and FIG. 46D: Initial SAXS pattern of RS phase sample.

FIGS. 47A-47D show heating treatment of 8-nm CdS nanospheres capped with (NH₄)₂S inorganic ligand in RS phase. The initial sample was soaked in Ca(NO₃)₂-methanol solution for 8 hours before pressurization process. FIG. 47A: Experimental and simulated result of RS phase fraction at different temperatures; FIG. 47B: Simulated activation energy distribution profile evolution as temperature increases; FIG. 47C: WAXS pattern at different temperatures; and FIG. 47D: Initial SAXS pattern of RS phase sample.

FIGS. 48A-48D show heating treatment of 4.8-nm CdSe/CdS nanospheres capped with octylamine in RS phase. The highest pressure applied was 10.5 GPa before releasing pressure. FIG. 48A: Experimental and simulated result of RS phase fraction at different temperatures; FIG. 48B: Simulated activation energy distribution profile evolution as temperature increases; FIG. 48C: WAXS pattern at different temperatures; and FIG. 48D: Initial SAXS pattern of RS phase sample.

FIGS. 49A-49D show detailed heating treatment of 4.8-nm CdSe/CdS nanospheres capped with octylamine in RS phase. The highest pressure applied was 10.7 GPa before releasing pressure. FIG. 49A: Experimental and simulated result of RS phase fraction at different temperatures; FIG. 49B: Simulated activation energy distribution profile evolution as temperature increases; FIG. 49C: WAXS pattern at different temperatures; and FIG. 49D: Initial SAXS pattern of RS phase sample.

FIGS. 50A-50D show heating treatment of 4.8-nm CdSe/CdS nanospheres capped with octylamine in RS phase. The highest pressure applied was 15.1 GPa before releasing pressure. FIG. 50A: Experimental and simulated result of RS phase fraction at different temperatures; FIG. 50B: Simulated activation energy distribution profile evolution as temperature increases; FIG. 50C: WAXS pattern at different temperatures; and FIG. 50D: Initial SAXS pattern of RS phase sample.

FIGS. 51A-51D show heating treatment of 4.8-nm CdSe/CdS nanospheres capped with (N₂H₅)₄Sn₂S₆ inorganic ligand in RS phase. FIG. 51A: Experimental and simulated result of RS phase fraction at different temperatures; FIG. 51B: Simulated activation energy distribution profile evolution as temperature increases; FIG. 51C: WAXS pattern at different temperatures; and FIG. 51D: Initial SAXS pattern of RS phase sample.

FIGS. 52A-52D show heating treatment of 8-nm CdSe/CdS nanospheres capped with octylamine in RS phase. FIG. 52A: Experimental and simulated result of RS phase fraction at different temperatures; FIG. 52B: Simulated activation energy distribution profile evolution as temperature increases; FIG. 52C: WAXS pattern at different temperatures; and FIG. 52D: Initial SAXS pattern of RS phase sample.

FIGS. 53A-53D show heating treatment of 8-nm CdSe/CdS nanospheres capped with (N₂H₅)₄Sn₂S₆ inorganic ligand in RS phase. FIG. 53A: Experimental and simulated result of RS phase fraction at different temperatures; FIG. 53B: Simulated activation energy distribution profile evolution as temperature increases; FIG. 53C: WAXS pattern at different temperatures; and FIG. 53D: Initial SAXS pattern of RS phase sample.

FIGS. 54A-54D show heating treatment of 23.8-nm CdSe/CdS nanorods capped with octylamine in RS phase. The highest pressure applied was 7.3 GPa before releasing pressure. FIG. 54A: Experimental and simulated result of RS phase fraction at different temperatures; FIG. 54B: Simulated activation energy distribution profile evolution as temperature increases; FIG. 54C: WAXS pattern at different temperatures; and FIG. 54D: Initial SAXS pattern of RS phase sample.

FIGS. 55A-55D show heating treatment of 23.8-nm CdSe/CdS nanorods capped with octylamine in RS phase. The highest pressure applied was 8.5 GPa before releasing pressure. FIG. 55A: Experimental and simulated result of RS phase fraction at different temperatures; FIG. 55B: Simulated activation energy distribution profile evolution as temperature increases; FIG. 55C: WAXS pattern at different temperatures; and FIG. 55D: Initial SAXS pattern of RS phase sample.

FIGS. 56A-56D show heating treatment of 23.8-nm CdSe/CdS nanorods capped with octylamine in RS phase. The highest pressure applied was 10.5 GPa before releasing pressure. FIG. 56A: Experimental and simulated result of RS phase fraction at different temperatures; FIG. 56B: Simulated activation energy distribution profile evolution as temperature increases; FIG. 56C: WAXS pattern at different temperatures; and FIG. 56D: Initial SAXS pattern of RS phase sample.

FIGS. 57A-57D show heating treatment of 23.8-nm CdSe/CdS nanorods capped with octylamine in RS phase. The highest pressure applied was 13.5 GPa before releasing pressure. FIG. 57A: Experimental and simulated result of RS phase fraction at different temperatures; FIG. 57B: Simulated activation energy distribution profile evolution as temperature increases; FIG. 57C: WAXS pattern at different temperatures; and FIG. 57D: Initial SAXS pattern of RS phase sample.

FIGS. 58A-58D show heating treatment of 23.8-nm CdSe/CdS nanorods capped with octylamine in RS phase. The highest pressure applied was 14.5 GPa before releasing pressure. FIG. 58A: Experimental and simulated result of RS phase fraction at different temperatures; FIG. 58B: Simulated activation energy distribution profile evolution as temperature increases; FIG. 58C: WAXS pattern at different temperatures; and FIG. 58D: Initial SAXS pattern of RS phase sample.

FIGS. 59A-59D show heating treatment of 23.8-nm CdSe/CdS nanorods capped with octylamine in RS phase. The highest pressure applied was 18.3 GPa before releasing pressure. FIG. 59A: Experimental and simulated result of RS phase fraction at different temperatures; FIG. 59B: Simulated activation energy distribution profile evolution as temperature increases; FIG. 59C: WAXS pattern at different temperatures; and FIG. 59D: Initial SAXS pattern of RS phase sample.

FIGS. 60A-60D show heating treatment of 23.8-nm CdSe/CdS nanorods capped with (N2H5)4Sn2S6 in RS phase. FIG. 60A: Experimental and simulated result of RS phase fraction at different temperatures; FIG. 60B: Simulated activation energy distribution profile evolution as temperature increases; FIG. 60C: WAXS pattern at different temperatures; and FIG. 60D: Initial SAXS pattern of RS phase sample.

FIGS. 61A-61D show heating treatment of 24.5-nm CdS/CdS nanorods capped with octylamine in RS phase. The highest pressure applied was 10.8 GPa before releasing pressure. FIG. 61A: Experimental and simulated result of RS phase fraction at different temperatures; FIG. 61B: Simulated activation energy distribution profile evolution as temperature increases; FIG. 61C: WAXS pattern at different temperatures; and FIG. 61D: Initial SAXS pattern of RS phase sample.

FIGS. 62A-62D show heating treatment of 24.5-nm CdS/CdS nanorods capped with octylamine in RS phase. The highest pressure applied was 15.1 GPa before releasing pressure. FIG. 62A: Experimental and simulated result of RS phase fraction at different temperatures; FIG. 62B: Simulated activation energy distribution profile evolution as temperature increases; FIG. 62C: WAXS pattern at different temperatures; and FIG. 62D: Initial SAXS pattern of RS phase sample.

FIGS. 63A-63D show heating treatment of 24.5-nm CdS/CdS nanorods capped with (N2H5)4Sn2S6 in RS phase. FIG. 63A: Experimental and simulated result of RS phase fraction at different temperatures; FIG. 63B: Simulated activation energy distribution profile evolution as temperature increases; FIG. 63C: WAXS pattern at different temperatures; and FIG. 63D: Initial SAXS pattern of RS phase sample.

FIGS. 64A-64C show a schematic of nucleation removal from a nanodomain with increasing external pressure. (FIG. 64A) At system pressure P₀, there are several nucleation sites (nucleations) with varying activation energies, ranging from low to high. (FIG. 64B) As the system pressure increases to P_{f}, the system's free energy is elevated. Nucleations with low activation energies start to be eliminated through intraparticle sintering reactions, interactions between grain boundaries (GTBs) and crystal defects, lattice distortions, and defect interactions facilitated through GTBs. (FIG. 64C) When chemical equilibrium is reached at system pressure P_{f}, nucleatons with low activation energies are completely removed, and the nanodomain exhibits a high effective activation energy.

FIGS. 65A-65F show stages in the process of partial fusion induced elimination of nucleation sites in the disclosed materials.

FIG. 66 shows a schematic of the experimental setup to apply pressure to the disclosed materials.

FIGS. 67A-67C show ligand-tailorable reversibility of the RS-to-ZB solid phase transformation in superlattices of 4.8-nm wurtzite CdSe nanocrystals. WAXS and SAXS patterns collected during compression and decompression (de) at different pressure. CdSe nanocrystals were functionalized with octylamine (FIG. 67A) of 92% surface coverage and (FIG. 67B) of 62% surface coverage; and (FIG. 67C) capped with a mixture of octylamine and CTAB (with a molar ratio of 5:1) of 63% surface coverage in terms of hydrocarbon chains. SAXS patterns shown in green. WAXS diffraction from the wurtzite/zinc-blende structure in blue, and from the rock-salt structure in red. See Supplementary Materials for details on composition-ratio determination.

FIGS. 68A-68C show ligand-tailorable ambient metastability of the rock-salt phase in 4.8-nm nanospheres. WAXS patterns of nanocrystal assemblies decompressed from a pressure above 10.4 GPa: (FIG. 68A) zinc-blende CdS nanocrystals, (FIG. 68B) wurtzite CdSe/CdS core/shell nanocrystals, and (FIG. 68C) wurtzite CdS/CdSe core/shell nanocrystals. Type of ligand and surface coverage are given on the corresponding curves for octylamine (OcAm) or oleylamine (OAm). Pyridine ligand with 100% coverage, and excess of ODT corresponding to ˜150% surface coverage.

FIGS. 69A-69K show superlattice structures of CdSe/CdS wurtzite nanorods and rock-salt nanorods. Superlattices of wurtzite nanorods before compression: (FIG. 69A) TEM image; (FIG. 69B) small-angle electron diffraction (SAED) pattern at 0°-tilt condition; the wide-angle electron diffraction (WAED) pattern (FIG. 69C) at 0°-tilt condition with [21̅1̅0] zone axis, and (FIG. 69D) at 30°-tilt condition with [101̅0] zone axis. (FIG. 69E) 3D atomic nanorod model viewed along the zone axis directions of ED patterns shown FIGS. 69C and 69D, respectively. Superlattices of rock-salt nanorods: (FIG. 69F) TEM image, (FIG. 69G) SAED pattern at 0°-tilt condition. The WAED pattern (FIG. 69H) at 0°-tilt condition and (FIG. 69I) at 45°-tilt condition, superimposed with simulated diffraction spots from corresponding three rock-salt domains. (FIG. 69J) 3D atomic model of a double-bend nanorod with three rock-salt domains (α, β, γ) viewed at angles corresponding to those for ED patterns in FIGS. 69H-69I, with labeled zone axis, where u=(\sqrt{6}+1)/5 and v=(\sqrt{6}−4)/5 at an off-axis direction. (FIG. 69K) Reconstructed 3D superlattice model showing each rock-salt nanorod atomically overlapping with its four neighboring rods at corresponding rectangular areas on their β-domains. Please note that rock-salt structures are extremely sensitive to electron beam irradiation, which limits the ability to use conventional high-resolution TEM to study detailed features in rock-salt nanostructures.

FIGS. 70A-70E show electric conductivity as indictor of interparticle sintering. The I-V curve for films composed of assemblies of (FIG. 70A) 23.8-nm wurtzite CdSe/CdS nanorods, and (FIG. 70B) 4.8-nm wurtzite CdSe/CdS core/shell nanospheres in (1) the wurtzite phase before phase transition obtained by decompression from ˜1.8 GPa, (2) the ambient stable rock-salt phase obtained by decompression from ˜10.4 GPa, or (3) the zinc-blende phase that transformed from rock-salt nanocrystals with excess ODT after decompression from ˜12.5 GPa. (FIG. 70C) Measured conductivity: column A for nanorods and column B for nanospheres. (FIG. 70D) and (FIG. 70E) schematic of proposed interparticle sintering mechanism for nanorods and nanospheres, respectively: (1) initial nanostructures at ambient pressure, (2) the rock-salt phase in the form of interconnected nanocrystal networks at a high pressure, and (3) the rock-salt phase in the form of “free” nanocrystals isolated with strong-binding ligands at a high pressure. In recovered samples after decompression, no or low-degrees of interparticle sintering was observed with TEM.

FIGS. 71A-71F show Wurtzite CdSe nanocrystals (4.8±0.2 nm): (FIG. 71A) and (FIG. 71B) TEM images and (FIG. 71C) UV-Vis absorption and photoluminescence spectra. Spherical zinc-blende CdSe nanocrystals (4.8±0.3 nm): (FIG. 71D) and (FIG. 71E) TEM images, and (FIG. 71F) UV-Vis absorption and photoluminescence spectra. [a. u.=arbitrary units]

FIGS. 72A-72F show spherical wurtzite CdSe/CdS core/shell nanocrystals (4.9±0.2 nm): (FIG. 72A) and (FIG. 72B) TEM images and (FIG. 72C) UV-Vis absorption and photoluminescence spectra. Spherical zinc-blende CdSe/CdS nanocrystals (4.8±0.4 nm): (FIG. 72D) and (FIG. 72E) TEM images, and (FIG. 72F) UV-Vis absorption and photoluminescence spectra. [a. u.=arbitrary units]

FIGS. 73A-73C show Spherical wurtzite CdS/CdSe core/shell nanocrystals (4.8±0.4 nm): (FIG. 73A) and (FIG. 73B) TEM images, and (FIG. 73C) UV-Vis absorption and photoluminescence spectra. [a. u.=arbitrary units]

FIG. 74 shows thermogravimetric analysis curve of CdSe nanocrystals capped with different surface ligands. Blue line: octylamine with 92% surface coverage; Green line: octylamine with 62% surface coverage; Red line: a mixture of octylamine and CTAB (at molar ratio of 5:1) with 63% surface coverage in terms of hydrocarbon.

FIGS. 75A-75C show ligand-tailorable reversibility of the RS-to-ZB solid phase transformation in superlattices of 4.8-nm wurtzite CdSe nanocrystals. SAXS and WAXS patterns collected during compression and decompression (de) at different pressures. CdSe nanocrystals loaded with (FIG. 75A) butylamine with 93% coverage (where 4.8% rock-salt phase was maintained at ambient pressure), (FIG. 75B) butylamine with 65% coverage (where 55.9% rock-salt phase was maintained at ambient pressure), and (FIG. 75C) a mixture of butylamine and CTAB (at the molar ratio of 5:1) with 68% coverage in terms of hydrocarbon chains. SAXS patterns are shown in green, and WAXS diffraction from the wurtzite/zinc-blende structure in blue and from the rock-salt structure in red.

FIG. 76 shows SAXS and WAXS patterns collected at before and after WZ-RS phase transition, and then decompressed from two pressures. There is 3.9% of the rock-salt phase maintained when decompressed (de) from 16.2 GPa.

FIG. 77 shows Zoomed-in SAXS pattern taken from FIG. 67C, showing the first SAXS peak shifting as a function of pressure. At ambient pressure, the superlattice adopted a fee structure with d111 of 5.03 nm. The corresponding interparticle distance is 6.16 nm, and surface to surface distance is 1.36 nm. The d-spacing of the second peak (a mixture of 220 and 311) is 2.93 nm (the ratio between first and second peak is 1:1.72). At 7.5 GPa (where the WZ-RS transition was completed), d111 spacing is 4.85 nm, and that of the second peak is 2.77 nm (the ratio between first and second peak is 1:1.75), indicating the fee superlattice was slightly distorted. With further compression, the d-spacing of first peak monotonically increases. At 12.1 GPa, the fee structure transformed into a lamellar structure, where {111}planes in the fee superlattice reduced to the layers of this lamellar structure. The d-spacing of the lamellar further increased to 5.30 nm at 14.6 GPa. Upon decompression (de) to ambient pressure, the lamellar d-spacing increased to 5.83 nm. These data imply that significant ligand rearrangements occurred in this process.

FIGS. 78A-78L show TEM images of CdSe and CdSe/CdS core/shell nanospheres and CdSe/CdS nanorods. (FIG. 78A) octylamine capped 4.8-nm wurtzite CdSe nanocrystals, (FIG. 78B) zinc-blende CdSe particles transformed back from the rock-salt phase after decompressed from 15.0 GPa, (FIG. 78C) rock-salt CdSe nanocrystals, and (FIG. 78D) zinc-blende CdSe nanocrystals transformed from rock-salt aggregates with 10-second sonication. (FIG. 78E) Octylamine-capped 4.8-nm CdSe/CdS core/shell wurtzite nanocrystals, (FIG. 78F) zinc-blende CdSe/CdS nanocrystals with ODT ligand (150% coverage) transformed back from the rock-salt phase after decompression from 14.2 GPa, (FIG. 78G) rock-salt CdSe/CdS nanocrystals, and (FIG. 78H) zinc-blende CdSe/CdS nanocrystals transformed from rock-salt aggregates with 10-second sonication in an octylamine/chloroform solution (0.1%). (FIG. 78I) octylamine-capped 23.8-nm CdSe/CdS wurtzite nanorods, (FIG. 78J) zinc-blende nanorod with ODT ligand (150% coverage) transformed back from the rock-salt phase upon decompression from 12.5 GPa, (FIG. 78K) rock-salt nanorods, and (FIG. 78L) zinc-blende nanorods transformed from rock-salt aggregates after 10-second sonication in an octylamine/chloroform solution (0.1%). The chloroform dispersions of rock-salt samples (shown in FIGS. 78C, 78G, and 78K) were prepared by shaking with a vortex shaker. Inserts in FIGS. 78D, 78H, and 78L are electron diffraction patterns of corresponding samples with a scale bar of 3 nm-1. Red quarter circles highlight the electron diffraction pattern of zinc-blende (111), (220), and (311) planes, respectively. These ED measurements show that all rock-salt samples were transformed to zinc-blende phase with a sonication treatment. Please note that numerous TEM measurements conducted in this study showed that pure rock-salt nanocrystals (in all compositions: CdSe, CdS, CdSe/CdS or CdS/CdSe) existed only in the form of aggregates.

FIGS. 79A-79B show ligand-tailorable reversibility of the RS-to-ZB solid phase transformation in superlattices of 4.8-nm zinc-blende CdSe nanocrystals. SAXS and WAXS patterns collected as a function of pressure of 4.8-nm zinc-blende CdSe nanocrystals capped with (FIG. 79A) octylamine with 95% coverage, and (FIG. 79B) a mixture of octylamine and CTAB (at a molar ratio of 5:1) with 63% coverage in terms of hydrocarbon chains (‘de’ for decompression).

FIGS. 80A-80D show ligand-tailorable reversibility of the RS-to-ZB solid phase transformation in superlattices of 4.8-nm zinc-blende CdS nanocrystals. SAXS and WAXS patterns collected as a function of pressure of 4.8-nm zinc-blende CdS nanocrystals capped with (FIG. 80A) octylamine with 93% surface coverage, (FIG. 80B) oleylamine with 89% coverage, (FIG. 80C) pyridine with 100% coverage, and (FIG. 80D) excess of octadecanethiol corresponding to ˜150% surface coverage.

FIGS. 81A-81B show SAXS and WAXS patterns collected as a function of pressure of wurtzite CdSe/CdS core/shell nanocrystals capped with (FIG. 81A) octylamine with 92% surface coverage and (FIG. 81B) oleylamine with 90% surface coverage.

FIGS. 82A-82B show SAXS and WAXS patterns collected as a function of pressure of wurtzite CdSe/CdS core/shell nanocrystals capped (FIG. 82A) with pyridine with 100% surface coverage and (FIG. 82B) with excess of octadecanethiol corresponding to 150% surface coverage.

FIGS. 83A-83B show ligand-tailorable reversibility of the RS-to-ZB solid phase transformation in superlattices of 4.8-nm zinc-blende CdSe/CdS core/shell nanocrystals. SAXS and WAXS patterns collected as a function of pressure of zinc-blende CdSe/CdS core/shell nanocrystals capped (FIG. 83A) with octylamine with surface coverage of 90%, and (FIG. 83B) with excess of octadecanethiol corresponding to 150% surface coverage.

FIGS. 84A-84D show ligand-tailorable reversibility of the RS-to-ZB solid phase transformation in superlattices of 4.8-nm wurtzite CdS/CdSe core/shell nanocrystals. SAXS and WAXS patterns collected as a function of pressure of 4.8-nm wurtzite CdS/CdSe core/shell nanocrystals capped with (FIG. 84A) octylamine with 68% surface coverage, (FIG. 84B) oleylamine with 59% ligand coverage, (FIG. 84C) pyridine with ˜100% ligand coverage, and (FIG. 84D) octylamine with 93% ligand coverage. FIG. 84C shows that in the sample capped with pyridine, 39.3% of rock-salt phase transformed into the zinc-blende phase labelled with blue arrows.

FIG. 85A shows SAXS and WAXS pattern collected as a function of pressure during compression and decompression (de). 23.8-nm CdSe/CdS wurtzite core/shell nanorods functionalized with octylamine with 95% surface coverage. FIG. 85B shows a schematic of the simple hexagonal unit cell of nanorod superlattices. FIG. 85C shows a zoomed-in SAXS pattern of wurtzite nanorod superlattices collected at ambient pressure. To simplify discussion infra, the Bragg peaks are indexed as a simple hexagonal lattice, with lattice parameters a=b=6.72 nm, and c=26.2 nm. Strictly speaking, the superlattices are composed of two ordered superstructures: (1) 2D-ordered hexagonally close-packed nanorods (with lattice parameter a=6.72) forming layers in (2) an 1D-ordered lamellar structure with lattice parameter 1=26.2 nm. FIG. 85D shows SAXS and WAXS patterns collected as a function of pressure: wurtzite CdSe/CdS nanorods capped with excess of octadecanethiol corresponding to ˜150% surface coverage, in which process rock-salt phase totally transformed back to the zinc-blende phase.

FIGS. 86A-86B show fine analysis of the electron diffraction pattern of rock-salt CdSe/CdS nanorods at 0°-tilt condition. FIG. 86A: Atomic model of double-bend nanorods with three rock-salt crystalline domains, under which three simulated electron diffraction patterns are shown for respective crystal domains labeled with corresponding zone axes. FIG. 86B: Simulated electron diffraction pattern (left), the experimentally obtained electron diffraction pattern (center), and superimposed image of simulated and experimental electron diffraction pattern (right).

FIGS. 87A-87B show fine analysis of the electron diffraction pattern of rock-salt CdSe/CdS nanorods at 45°-tilt condition. FIG. 87A: Atomic model of double-bend nanorods with three rock-salt crystalline domains, under which three simulated electron diffraction patterns are shown for respective crystal domains labeled with corresponding zone axes. FIG. 87B: Simulated electron diffraction pattern (left), the experimentally obtained electron diffraction pattern (center), and superimposed image of simulated and experimental electron diffraction pattern (right).

FIG. 88A shows a schematic representation of a 23.8-nm CdSe/CdS wurtzite nanorod (in a reconstructed atomic model) transforming to double-bend three-domain CdSe/CdS rock-salt nanorod with a height of 15.8 nm (in a simulated atomic model). The dimension of 15.8 nm is obtained from TEM measurements and small-angle electron diffraction pattern. The angle between neighboring domains is calculated with simulated electron diffraction pattern. The sizes of each domain were estimated with the domain sizes determined from Bragg peaks in the WAXS pattern with the Scherrer equation and were further fine-tuned during atomic model reconstruction. FIG. 88B shows two possible configurations of double-bend nanorods, which cannot be distinguished with electron diffraction patterns. (Please note that nanorods in both configurations exhibit nearly identical spatial relationship in the superlattices, FIGS. 88A-88B).

FIGS. 89A-89I show recovered zinc-blende nanorods as “the fossil record” for the existence of double-bend nanorods. High resolution TEM images. FIG. 89A flow chart: a fringe image of wurtzite CdSe/CdS nanorod in green (left), under pressure, transforming into double-bend rock-salt rod in model (grey). After sonication, rock-salt rod transforming to zinc-blende rods shown in a fringe image labelled as three colored domains (right). FIGS. 89B-89C: wurtzite nanorods, FIGS. 89D-89I: zinc-blende nanorod with multiple domain structures as well as areas with curved lattice fringes due to strain, marked with blue arrows. These structure features are obvious traces that double-bend nanorods left in the recovered zinc-blende nanorods.

FIG. 90A shows (i) 3D reconstructed superlattice model of rock-salt nanorods with dimensions determined experimentally, a zoomed-in unit cell model shown at left, (ii) a superlattice unit cell assigned as a simple-hexagonal structure labelled with lattice constants. Such an assignment is just for simplification of discussions relating to infra. (iii) an open view of the superlattice unit cell, (iv) 2D cross-section view of the model showing that four areas (in yellow) on the surface of the β-domain atomically overlap with neighboring rods, called touching areas. (v) A 2D side-view of a double-bend rod labelled relative locations of the four-touching areas (in yellow). FIG. 90B shows a 3D atomic model labeled with four areas (in yellow) viewed at five rotations, showing the touching areas are in a rectangular shape with dimensions of ˜2.5 nm×˜4.5 nm. This 3D simulation implies that each double-bend rock-salt nanorods must atomically fuse (i.e., interparticle sintering) with four neighboring nanorods, forming interconnected networks.

FIGS. 91A-91D show formation of grain/twin boundaries between interconnected nanospheres (FIG. 91A) and nanorods (FIG. 91B), where grain/twin boundaries also exist between domains inside individual rods. Zoomed-in models for low-angle (FIG. 91C) and high-angle grain boundaries (FIG. 91D) inside interconnected nanocrystal networks.

FIGS. 92A-92D show the formation of ambient metastable rock-salt nanocrystal networks requires a critical pressure. SAXS and WAXS patterns collected as a function of pressure. FIG. 92A: assemblies of spherical wurtzite CdSe/CdS core/shell nanocrystals functionalized with octylamine with 92% surface coverage, 15.1% of rock-salt phase transformed to the zinc-blende structure upon decompression from 8.2 GPa. In contrast, the rock-salt phase was fully retained at ambient pressure if decompression from 10.4 GPa. FIG. 92B: Superlattices of CdSe/CdS nanorods capped with octylamine in 95% coverage, 34.7% rock-salt phase transformed into the zinc-blende phase when decompressed from 7.2 GPa, whereas 100% rock-salt phase was preserved if decompressed from 10.4 GPa. FIGS. 92C-92D: Schematic of proposed mechanism that a threshold pressure is required for the formation of the interconnected nanocrystal networks (shown in 3), in which rock-salt phase can be fully maintained at ambient conditions. Below this minimal pressure, the rock-salt phase in these interconnected networks (shown in 2) can be partially reversible during decompression. Pi for an intermedium pressure and Pc for a critical pressure in the experiments. * in FIG. 92B: a gasket diffraction peak from steel gasket of a diamond anvil cell.

FIGS. 93A-93B show the order level of nanocrystal assemblies affects the ambient metastability of rock-salt phase in CdSe/CdS nanorods. SAXS and WAXS patterns collected as a function of pressure. (FIG. 93A) low-level ordered and (FIG. 93B) high-level ordered assemblies of CdSe/CdS nanorods capped octylamine of 95% coverage. The low-level ordered sample was prepared through rapid precipitation: a nanorod toluene solution (10 mg/mL, 1 mL) was rapidly injected into acetone (5 mL), resulting in yellow nanorod precipitations. The precipitation was isolated with centrifugation and dried under Ar flow. In contrast, the high-level ordered nanorod assemblies were prepared at an air/liquid interface with a controlled solvent evaporation rate. In the purple dashed box, the SAXS pattern (upper) shows that low-level-ordered assemblies exhibited a hexagonal close-packed structure but with much broader Bragg diffraction peaks than those peaks from the high-level-ordered assemblies, indicating that the order level of the sample made by rapid precipitation is much lower than the sample prepared at an air/liquid interface. When decompressed from 10.8 GPa, 22.2% of rock-salt phase transformed into the zinc-blende structure in the low-level-ordered sample; in contrast, the rock-salt phase was fully retained in the high-level-ordered sample when decompressed from 10.4 GPa.

FIGS. 94A-94B show atypical X-ray scattering pattern collected on a Mar345 detector. (FIG. 94A) Enlarged SAXS area, and (FIG. 94B) enlarged WAXS area.

FIG. 95A-95C shows a picture of Keithley 4200 Parameter Analyzer setup for conductivity measurements. FIG. 95B shows a schematic of sample and probe arrangement for a two-probe electric measurement. FIG. 95C shows a SEM image of the gasket after compression-decompression process at 45-degree tilt. The thickness of sample film is estimated as 65 μm=46 m/cos 45°.

Additional advantages of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### DETAILED DESCRIPTION

Disclosed herein are solids, including, but not limited to, nanocrystal solids including an interconnected nanodomain network. In some aspects, the nanocrystals have a first phase and a second phase. In one aspect, the first phase can be a metastable high-energy, high-pressure phase kinetically trapped at ambient conditions, while the second phase can be thermodynamically stable at ambient conditions, although other phase types are contemplated and should be considered disclosed. In an aspect, the first phase and/or the second phase can be a rock-salt phase, a wurtzite phase, a zinc-blende phase, an amorphous phase, a monoclinic phase, a cubic phase, a rhombohedral phase, a hexagonal phase, a tetragonal phase, or an orthorhombic phase. In an aspect, in different materials, the crystal structures and/or identities of the first phase and the second phase can be different depending on factors including atom size, charge, ratios thereof, and the like. In any of these aspects, the nanocrystal solids can be defect free, strain free, or both. In some aspects, the nanocrystal solids can be interconnected nanocrystal networks. In another aspect, the first phase can be or include one or more first nanodomains, while the second phase can be or include one or more second nanodomains, and the one or more first nanodomains and the one or more second nanodomains can form an interconnected nanodomain network. Exemplary thermodynamic stable and metastable high pressure phases for various materials are presented in Table 1:

TABLE 1
Crystal Phases of Inorganic Materials

| | Thermodynamic | Metastable high- |
|---|---|---|
| Material | stable phase(s) | pressure phase(s) |
| CdS | Zinc blende/Wurtzite | Rock salt |
| CdSe | Zinc blende/Wurtzite | Rock salt |
| CdTe | Zinc blende/Wurtzite | Rock salt |
| ZnO | Zinc blende/Wurtzite | Rock salt |
| ZnSe | Zinc blende/Wurtzite | Rock salt |
| HgS | Cinnabar | Rock salt |
| HgSe | Zinc blende/Wurtzite | β-Sn |
| HgTe | Zinc blende/Wurtzite | Rock salt |
| MgSe | Rock salt | Cesium chloride |
| AlN | Zinc blende/Wurtzite | Rock salt |
| GaN | Zinc blende/Wurtzite | Rock salt |
| GaP | Zinc blende/Wurtzite | Rock salt |
| GaAs | Zinc blende/Wurtzite | Orthorhombic |
| InN | Zinc blende/Wurtzite | Rock salt |
| InP | Zinc blende/Wurtzite | Rock salt |
| InAs | Zinc blende/Wurtzite | Rock salt |
| PbS | Rock salt | Orthorhombic |
| PbSe | Rock salt | Orthorhombic |
| PbTe | Rock salt | Amorphous |
| MnS | Rock salt | Orthorhombic |
| MnSe | Rock salt | Orthorhombic |
| FeS | Hexagonal | Orthorhombic |
| FeSe | Tetragonal | Orthorhombic |
| InSe | rhombohedral | monoclinic/cubic |
| In₃Se₂ | N/A (not stable under ambient) | Monoclinic/cubic |
| In₄Se₃ | N/A (not stable under ambient) | Monoclinic/cubic |
| Cu₂S | Monoclinic (I) | Monoclinic (II)/ |
| | | Monoclinic (III) |
| TaS₂ | Hexagonal | I4/mmm |
| Bi₂Se₃ | R-3 m (CN = 6) | C2/m (CN = 7)/ |
| | | C2/c (CN = 8) |
| Sb₂Te₃ | Rhombohedral | Monoclinic/tetragonal |

In any of these aspects, the nanocrystal solid can include from about 0.1 to about 99.9% of the first phase, or from about 55% to about 85% of the first phase, or about 0.1, 5, 10, 15, 20, 25, 30, 35, 40, 45, 50, 55, 60, 65, 70, 75, 80, 85, 90, 95 or about 99.9% of the first phase, or a combination of any of the foregoing values, or a range encompassing any of the foregoing values. In another aspect, the nanocrystal solid can include II-VI semiconductors such as, for example, CdSe, CdS, ZnO, CdTe, ZnSe, ZnS, CdTe, HgS, HgSe, HgTe, MgSe, or any combination thereof. In one aspect, when the nanocrystals comprise II-VI semiconductors, the first phase can be a rock salt phase and the second phase can be a zinc blende phase. In another aspect, the nanocrystal solid can include a III-V semiconductor selected from AlN, GaN, GaP, GaAs, InN, InP, InAs, or any combination thereof. Further in this aspect, when the nanocrystals include a III-V semiconductor, the first phase can be an orthorhombic phase and the second phase can be a rock salt phase. In still another aspect, the nanocrystal can include a IV-VI semiconductor selected from PbS, PbSe, PbTe, or any combination thereof. Further in this aspect, when the nanocrystals include a IV-VI semiconductor, the first phase can be an orthorhombic phase and the second phase can be a rock salt phase. In yet another aspect, the nanocrystal can include a transition metal chalcogenide selected from MnS, MnSe, FeS, FeSe, InSe, In₃Se₂, In₄Se₃, Cu_{1.97}S, Cu₂S, Ta₂S, Bi₂Se₃, Bi₂Te₃ and Sb₂Te₃, or any combination thereof. In some aspects, when the nanocrystal includes a transition metal chalcogenide, the first phase can be a C2/m phase and the second phase can be an R-3m phase. In other aspects, when the nanocrystal includes a transition metal chalcogenide, the first and second phases can be different from those listed herein.

In one aspect, the nanocrystal solid includes a plurality of nanocrystals, wherein the individual nanocrystals of the plurality include one or more surface ligands. In an aspect, the surface ligands can be present at a density of about 0.1 to about 6.0 ligands per nm² of surface area of the nanocrystals, or about 0.1, 0.25, 0.5, 0.75, 1, 1.5, 2, 2.5, 3, 3.5, 4, 4.5, 5, 5.5, or about 6 ligands per nm² of surface area of the nanocrystals.

In one aspect, the one or more ligands can be selected from amines, fatty amines, salts of fatty quaternary ammonium ions, fatty acids or salts thereof, organophosphonic acids or salts thereof, thiols, fatty thiols, or any combination thereof. In another aspect, the amines can be pyridine. In still another aspect, the fatty amines can be selected from ethylamine, propylamine, pentylamine, hexylamine, heptylamine, octylaime, nonaylamine, decylamine, undecylamine, dodecylamine, tridecylamine, tetradecylamine, pentadecylamine, hexadecylamine, heptadecylamine, octadecylamine, nonadecylamine, eicosylamine, or any combination thereof. In one aspect, the salts of quaternary ammonium ions can be fluoride, chloride, bromide, or iodide salts of dodecyltrimethylammonium, didodecyldimethylammonium, or cetyltrimethylammonium ions, or any combination thereof. In another aspect, the fatty acids or salts of fatty acids can be acetic acid, propanoic acid, valeric acid, hexanoic acid, heptanoic acid, octanoic acid, nonanoic acid, decanoic acid, undecanoic acid, dodecanoic acid, tridecanoic acid, tetradecanoic acid, pentadecanoic acid, hexadecenoic acid, heptadecanoic acid, octadecanoic acid, nonadecanoic acid, eicosanoic acid, salts thereof, or any combination thereof. In an aspect, the organophosphonic acids or salts of organophosphonic acids can be or include ethylphosphonic acid, propylphosphonic acid, pentylphosphonic acid, hexylphosphonic acid, heptanylphosphonic acid, octanylphosphonic acid, nonylphosphonic acid, decylphosphonic acid, undecylphosphonic acid, dodecylphosphonic acid, tridecylphosphonic acid, tetradecyl phosphonic acid, pentadecylphosphonic acid, hexadecylphosphonic acid, heptadecylphosphonic acid, octadecylphosphonic acid, nonadecylphosphonic acid, eicosanylphosphonic acid, salts thereof, or any combination thereof. In one aspect, the thiols can be thiophenol, methylbenzenethiol, ethylbenzenethiol, or any combination thereof. In another aspect, the fatty thiols can be pentanethiol, hexanethiol, heptanethiol, octanethiol, decanethiol, dodecanethiol, tridecanethiol, tetradecanethiol, pentadecanethiol, hexadecanethiol, heptadecanethiol, octadecanethiol, nonadecanethiol, eicosanethiol, or any combination thereof. In an aspect, the organosulfate salts can be or include sodium dodecyl sulfate, sodium dodecylbenzenesulfonate, or any combination thereof.

In a further aspect, the nanocrystal solid can be a semiconductor, a superconductor, or any combination thereof.

In one aspect, interconnected nanodomain networks having nanodomains exhibiting superconductivity phases and topological phases can form a topological superconductor. Examples include, but are not limited to, FeSe and Bi₂Te₃. In another aspect, interconnected nanodomain networks having nanodomains exhibiting electric superconducting and metallic conductive properties form solids of superconductor and conductor composites for making high field magnetics, including magnetomechanical coupling in the development of high-field magnets. In one aspect, multiferroics can be or include interconnected nanodomain networks having nanodomains that exhibit two or three of the following phases: ferromagnetic phase, or a magnetization that is switchable based on an applied magnetic field; ferroelectric phase, or an electric polarization that is switchable by an applied electric field; and a ferroelastic phase, or a deformation that is switchable by an applied stress.

In one aspect, the disclosed interconnected nanodomain networks include individual nanodomains exhibiting either soft ferromagnetic or hard ferromagnetic phases, forming solids with neighboring nanodomains connected with grain boundaries between soft ferromagnetic or hard ferromagnetic phases. In a further aspect, these solids can be exchange-spring magnets exhibiting controlled exchange coupled exchange decoupled hard-soft magnetic phases, where exchange coupled exchange can result in a magnetic with an enhanced (BH)ₘₐₓ. In an alternative aspect, the disclosed interconnected nanodomain networks include individual nanodomains exhibiting either a ferromagnetic (FM) or an antiferromagnetic (AF) phase, forming exchange-biased magnets with grain boundaries between a ferromagnetic (FM) and an antiferromagnetic (AF) phase domains. In an aspect, this represents an alternative strategy to realize hard magnetic nanocomposites comprised of two exchange interacting magnetic phases in the creation of “exchange-bias” magnets. In one aspect, in exchange bias, a ferromagnetic (FM) material is exchange-coupled to an antiferromagnetic (AF) material at the interface, to produce a displacement in the hysteresis loop along the field axis. Without wishing to be bound by theory, this phenomenon is attributed to the exchange interaction at the FM/AF interface that pins FM moments during the reversal process, causing an increase of He (coercivity) and M_{R} (saturated magnetization) and providing an enhanced (BH)ₘₐₓ.

In one aspect, the disclosed interconnected nanodomain networks can include ceramic nanodomains such as BaTiO₃, forming high energy storage materials exhibiting a high electric breakdown potential and high apparent electric capacity. Without wishing to be bound by theory, it is worth noting that the finer the grain size, the more uniform the local electric field distribution. In an aspect, under the same applied electric field, the local electric field at the shell part of the coarse-grain ceramics is several times stronger than that of the fine-grain ceramics. In a further aspect, considering the breakdown always occurs where the local electric field concentrates most, the coarse-grain ceramics are therefore easy to fail.

In one aspect, in nanograined metal alloys, the disclosed interconnected nanodomain networks include metallic nanodomains such as copper, forming solids with ultra-strong, ductile and stable metal nanocomposites.

In another aspect, in nanostructured superhard materials, the disclosed interconnected nanodomain networks include nanodomains with superhard materials such as boron nitride, forming solids with improved hardness through nanostructure engineered strengthening effects.

Also disclosed herein are methods for producing an nanocrystal solid that includes a metastable high-pressure phase and a second phase, the method including at least the steps of (a) surface functionalizing a plurality of nanocrystals; and (b) sintering the plurality of nanocrystals. In one aspect, sintering the plurality of nanocrystals includes pressure assisted sintering, liquid phase sintering, electric current assisted sintering, microwave sintering, infrared light sintering, or any combination thereof. In another aspect, pressure assisted sintering can include subjecting the plurality of nanocrystals to a synthesis pressure, wherein the synthesis pressure causes the nanocrystals to sinter, forming the nanocrystal solid. In an aspect, pressure assisted sintering can be carried out at ambient temperature or at an elevated temperature. In another aspect, electric current assisted sintering can be electro sinter forging, spark plasma sintering, or any combination thereof. In one aspect, the nanocrystal solid is stable under ambient conditions.

In another aspect, the metastable high-pressure phase is a rock-salt phase, and the second phase can be a wurtzite phase or a zinc-blende phase.

In one aspect, the individual nanocrystals making up the nanocrystal solid can be nanospheres, core-shell nanospheres, nanorods, or any combination thereof. In another aspect, the nanospheres or core-shell nanospheres can have an average particle diameter of from about 1.5 to about 25 nm, or of about 1.5, 2, 2.5, 5, 6, 7, 8, 9, 10, 11, 12, 13, 14, 15, 16, 17, 18, 19, 20, 21, 22, 23, 24, or about 25 nm, or a combination of any of the foregoing values, or a range encompassing any of the foregoing values.

In another aspect, the individual nanorods can have an average length of from about 10 to about 120 nm and an average width of from about 2.5 to about 8.0 nm. In a further aspect, the average length can be about 10, 20, 30, 40, 50, 60, 70, 80, 90, 100, 110, or about 120 nm, or a combination of any of the foregoing values, or a range encompassing any of the foregoing values. In another aspect, the average width can be about 2.5, 3, 3.5, 4, 4.5, 5, 5.5, 6, 6.5, 7, 7.5, or about 8 nm, or a combination of any of the foregoing values, or a range encompassing any of the foregoing values. In one aspect, the individual nanorods can have an average length of about 23.8 mm and an average width of about 4.8 nm.

In another aspect, the synthesis pressure is at least about 2.0 GPa, or is at least about 2, 5, 10, 15, 20, 25, 30, 35, 40, 45, 50, 55, or about 60 GPa, or a combination of any of the foregoing values, or a range encompassing any of the foregoing values. In another aspect, surface functionalizing the plurality of nanocrystals includes contacting the nanocrystals with a ligand at a synthesis temperature, wherein the synthesis temperature is from about room temperature (RT) to about 1200° C., or is about 20, 25, 30, 35, 40, 45, 50, 100, 150, 200, 250, 300, 350, 400, 450, 500, 550, 600, 650, 700, 750, 800, 850, 900, 950, 1000, 1050, 1100, 1150, or about 1200° C., or a combination of any of the foregoing values, or a range encompassing any of the foregoing values.

Also disclosed are nanocrystal solids made by the disclosed methods, and articles including the nanocrystal solids. In one aspect, the articles can be or can include an ambient metastable semiconductor, a superconductor, a topological superconductor, a catalyst, a multiferroic material, a soft-hard composite magnet, a nanograined ceramic, a nanograined alloy, or a nanostructured superhard material. In another aspect, the article can be a freestanding solid or a coating on a solid substrate.

### Generalization of the Disclosed Interconnected Networks

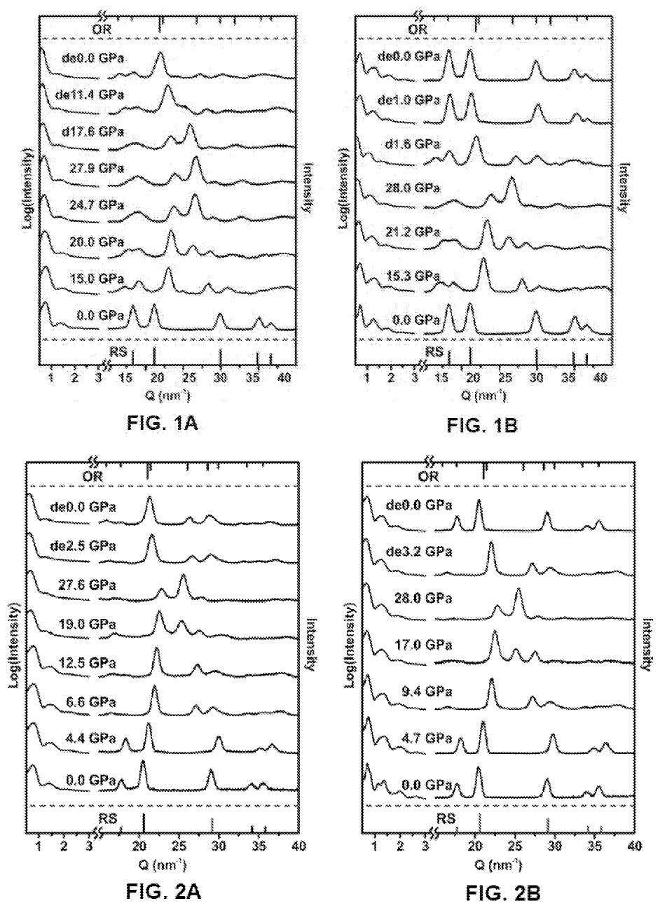

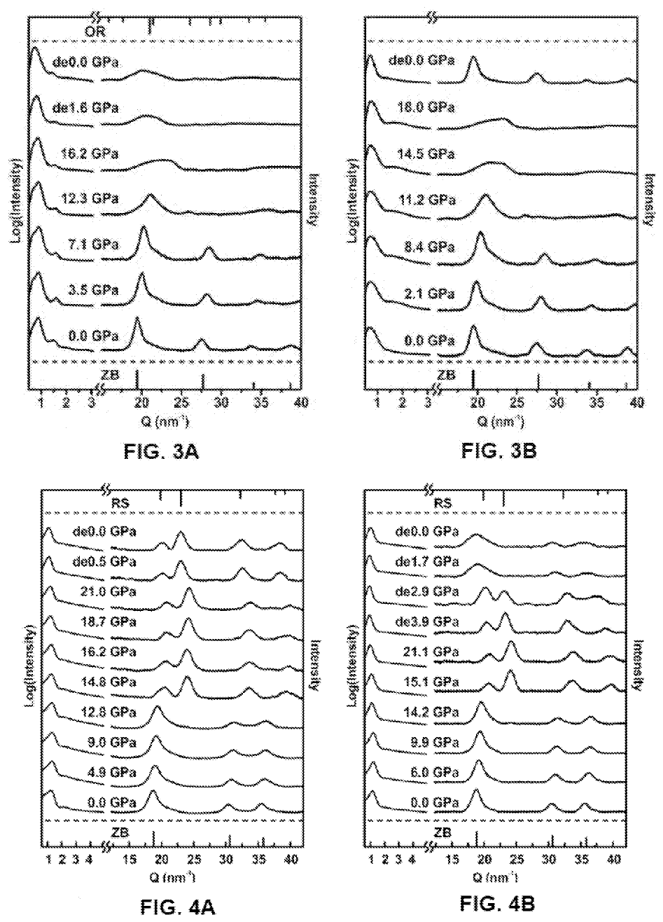

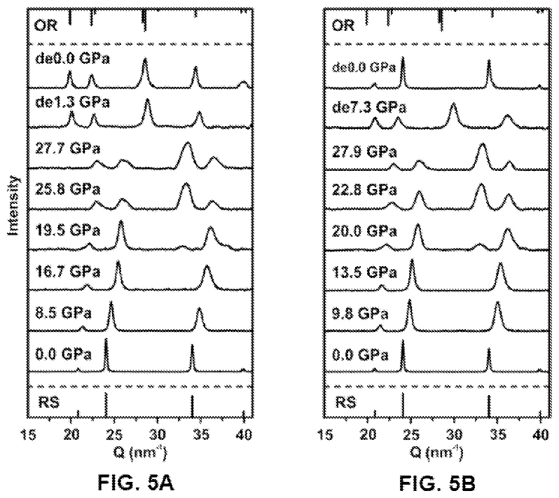

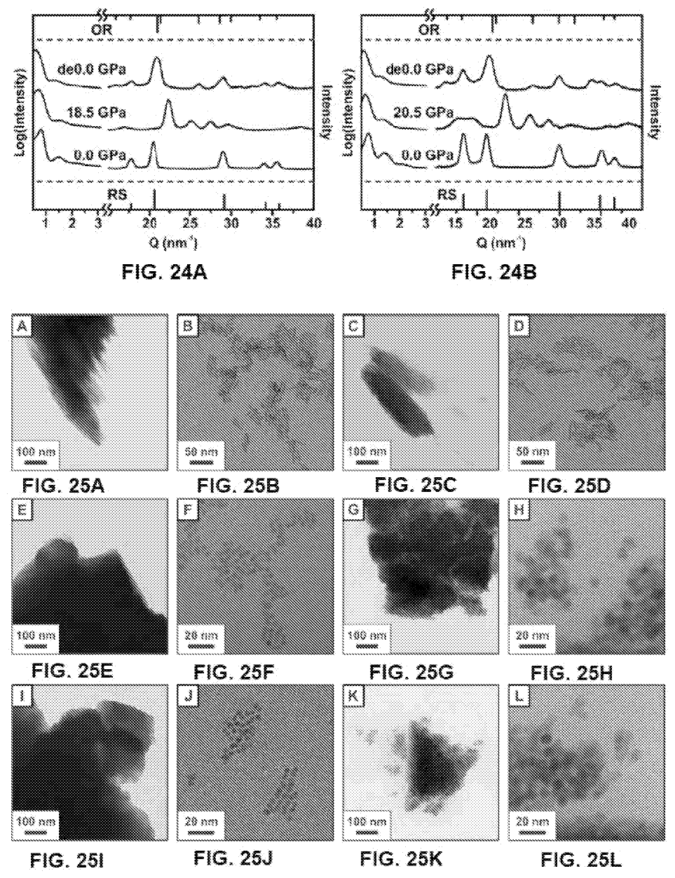

We have generalized the concept of interconnected nanocrystal/nanodomain network into other chemical compositions: IV-VI (FIGS. 1A-3B), III-V (FIGS. 4A-4B), and transition metal chalcogenides (FIGS. 5A-5B). Note that for PbS and PbSe nanocrystals, a significant high pressure is required to retain metastable orthorhombic phase under ambient condition, during the pressurization process a substantial fraction of sample showing CsCl phase at highest pressure applied (FIGS. 24A-24B); for InP nanocrystals, a secondary weak-bonding ligand is required to retain high-pressure rock-salt phase; and for PbTe and MnS nanocrystals, as synthesized sample can retain their high-pressure phase, while only when excess amount of surface ligand can trigger reverse phase transition under ambient conditions.

### Theoretical Understanding of the Activation Energy Distribution in Nanocrystal/Nanodomain Networks Formed Under High Pressures

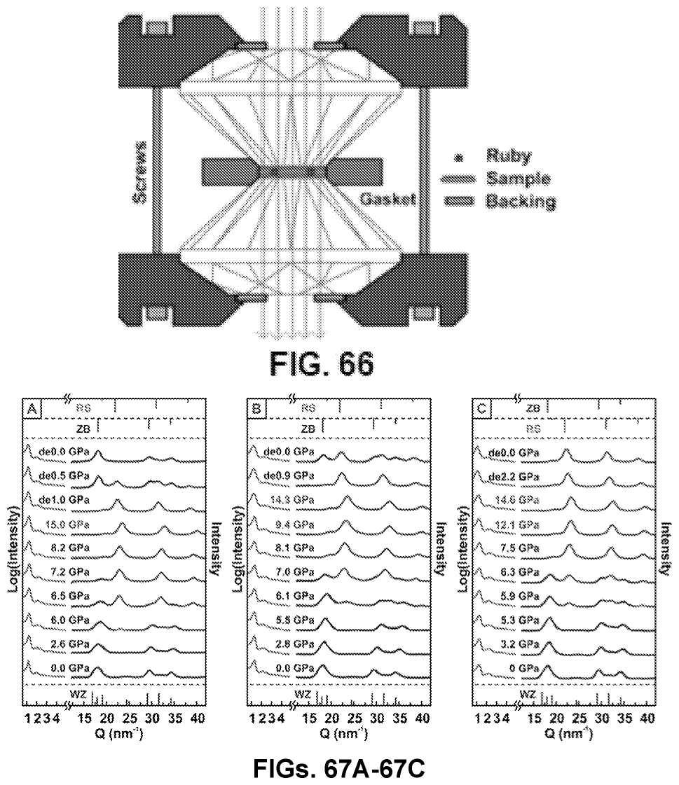

Inside diamond anvil cells (FIG. 66), the Gibbs free energy of nanocrystals increases with the external pressure. When ligand density is low, intraparticle sintering reactions takes place to minimize Gibbs Free energy of nanocrystals leading to the absorption of high energy defects and lattice distortions, which are associated with nucleation sites in the RS-ZB phase transition. The higher the free energy of lattice defects and distortions, the lower the activation energy of nucleation sites, and vice versa.

Under the external pressure without pressure media, the formation of interconnected NC networks strongly interplays with an emergent phenomenon called force chain networks, which are created by interparticle interactions and by the topological patterns of pressure applied within the system. The force chain networks result in a fluctuation in pressure experience by individual nanocrystals. The pressure difference between neighboring nanocrystals introduces a driving force for: (i) the interactions between grain/twin boundaries (GTBs) and crystal defects and lattice distortions, and (ii) defect interactions facilitated through GTBs.

Nucleation sites are eliminated through defect/strain sink/annealing reactions. The Ea of eliminated nucleation sites are monotonically related to the Ea of these defect removal reactions. With an increase in external pressure, crystal defects and lattice strains are removed in order of their Gibbs free energies, from high to low. In turn, the nucleation sites are removed in the direction of increasing activation energy, from low to high.

The formed Interparticle GTBs further acted as obstacles to block or jam dislocation motions and stabilize and harden interconnected nanocrystal/nanodomain networks and provided additional mechanisms to raise the activation barrier height for the RS-to-ZB transformation.

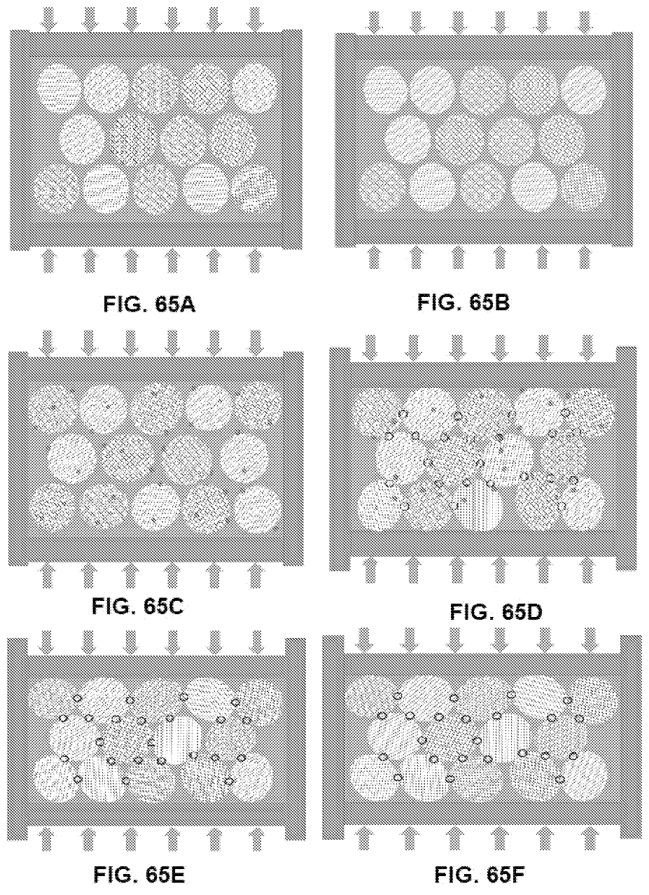

FIGS. 65A-65F show a schematic of the process of partial fusion induced elimination of nucleation sites. Pressure is applied as shown in FIG. 66. Without wishing to be bound by theory, force-chain formation can be a mechanism for pressure wave propagation. RS nanocrystals formed from pressure-induced solid-phase transitions included a large number of high-energy crystal defects and lattice distortions and served as nucleation sites for the rapid RS-to-ZB/WZ transitions observed in the systems with no or low degrees of interparticle sintering (FIG. 65C). Interparticle sintering was a main process that eliminated crystal defects and relaxed lattice distortions from high-pressure RS structures, and thus the partial restoration of the intrinsic kinetic barrier in ideal crystals creates ambient metastable nanostructures (FIG. 65D). In high-pressure/deviatoric stress induced interparticle sintering, solid-state chemical reactions, driven by the minimization of Gibbs free energy—take place between surface atoms of neighboring nanocrystals, forming effective sinks to absorb local high energy defects and lattice distortions. Stress-driven diffusion or propagation of defects allows delocalized and collective grain twin boundary (GTB)/defect interactions with an interconnected network where GTBs act as sources, sinks, or both, to eliminate crystal defects through absorption and annihilation (FIG. 65E).

Intraparticle sintering reactions: minimize Gibbs Free energy of nanocrystals leading to the absorption of high energy defects and lattice distortions, which are associated with nucleation sites exhibiting a low activation energy In the RS-ZB phase transition. Under an external pressures without pressure media, the formation of interconnected NC networks strongly interplays with an emergent phenomenon called force chain networks, which are created by interparticle interactions and by the topological patterns of pressure applied within the system. The force chain networks result in a fluctuation in pressure experience by individual nanocrystals. The pressure difference between neighboring nanocrystals forms a driving force for: (i) the interactions between grain/twin boundaries (GTBs) with crystal defects and lattice distortions and (ii) defect interactions through GTBs. A higher pressure can remove nucleation sits with higher activation energies; GTBs further acted as obstacles to block or jam dislocation motions and stabilize and harden interconnected NC networks and provided additional mechanisms to raise the activation barrier height for the RS-to-ZB transformation (visible during measurements).

Parameters that Influence the Activation Barrier Heights

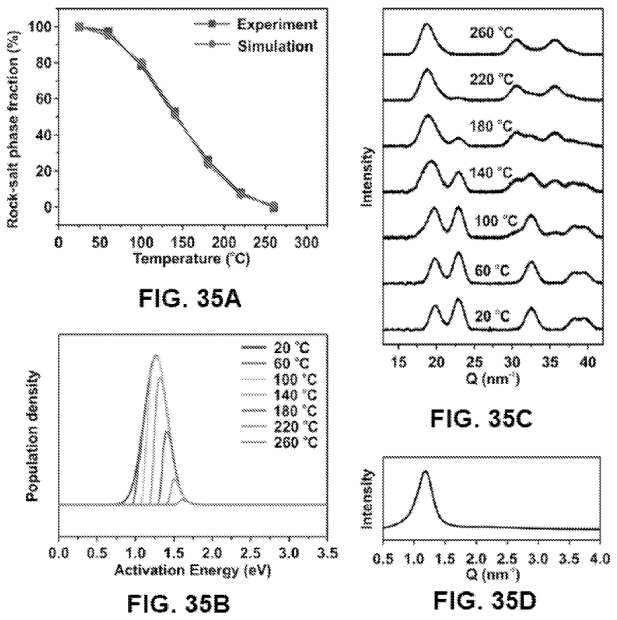

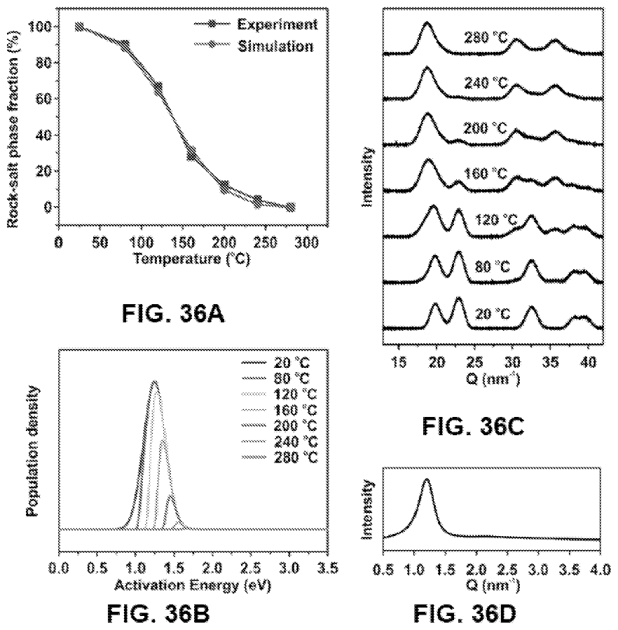

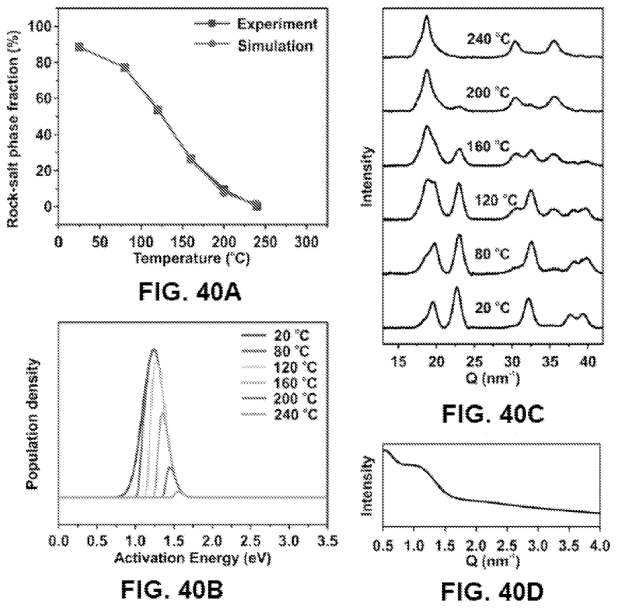

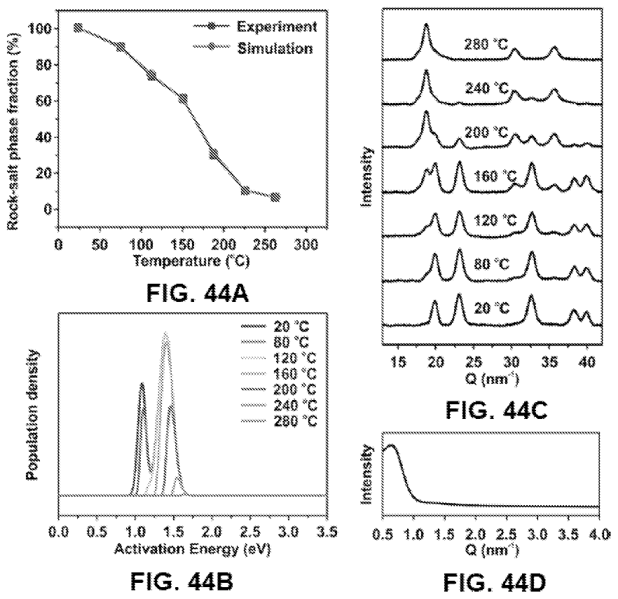

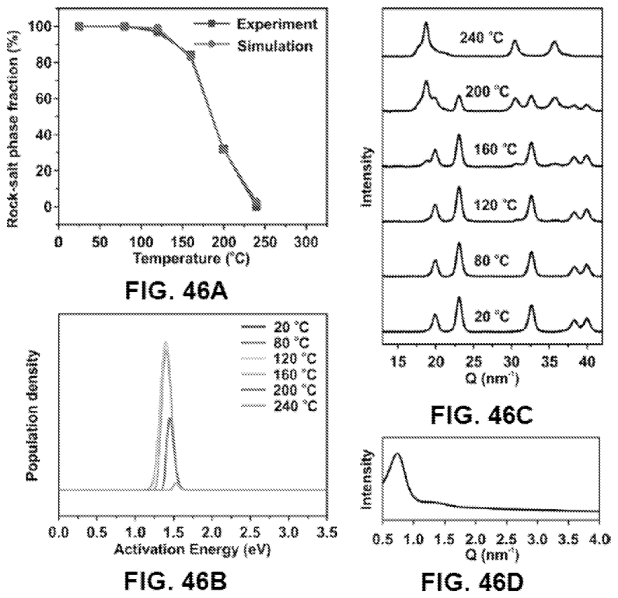

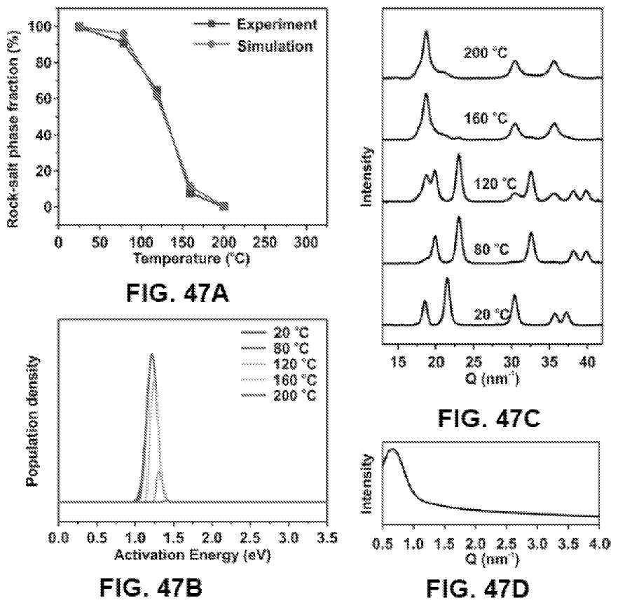

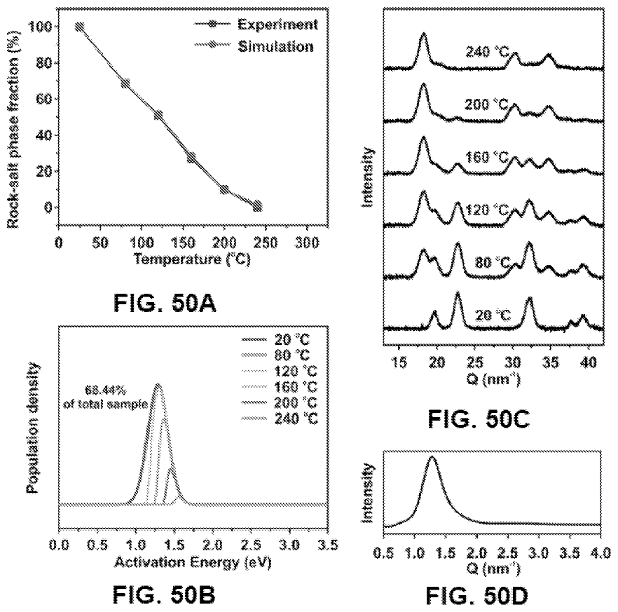

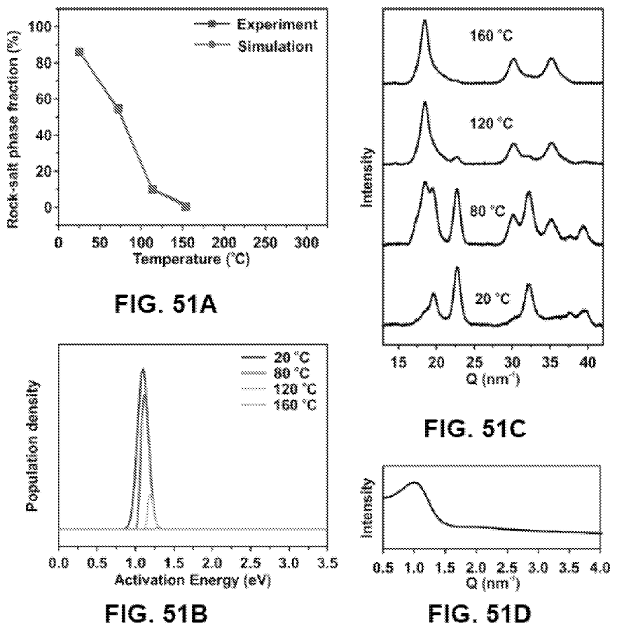

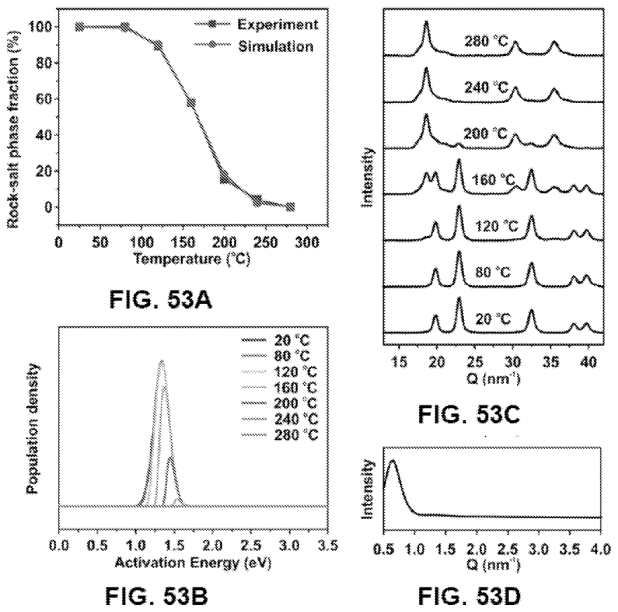

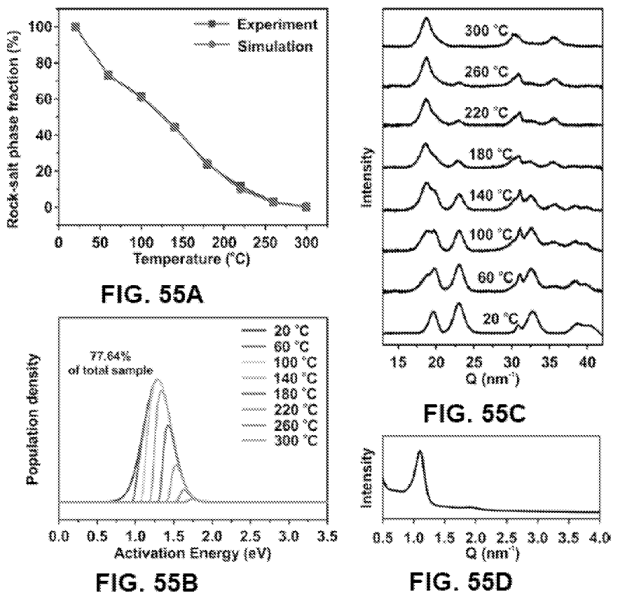

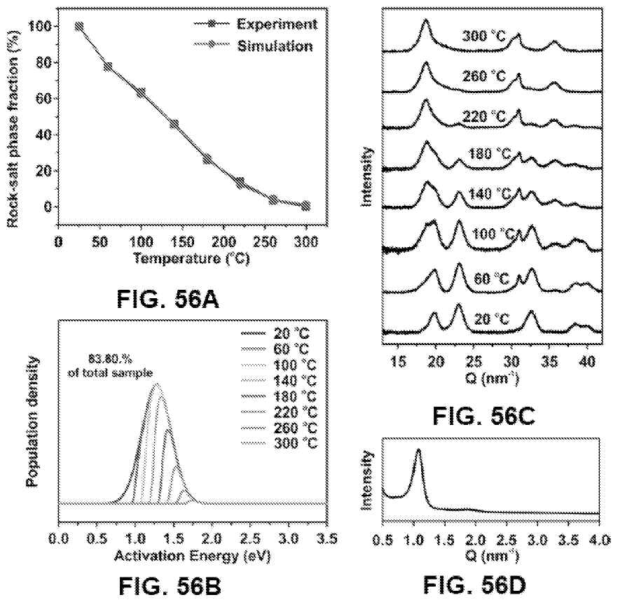

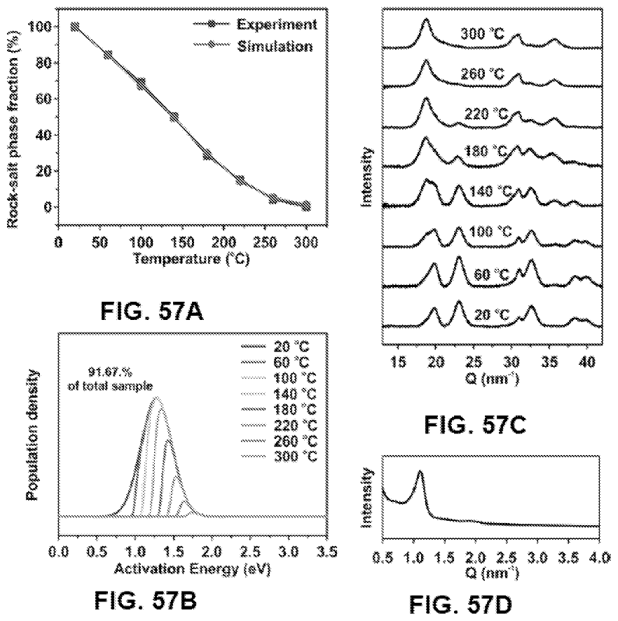

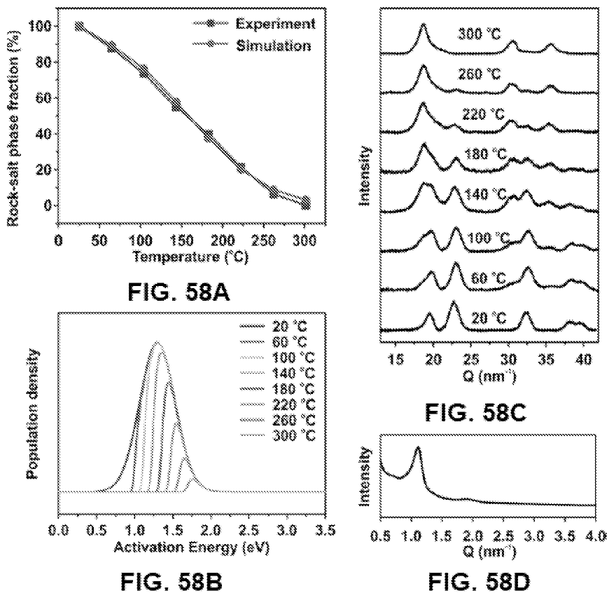

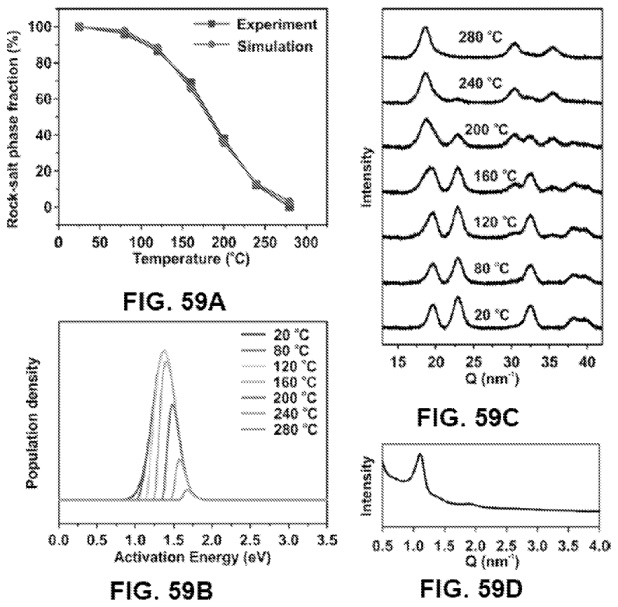

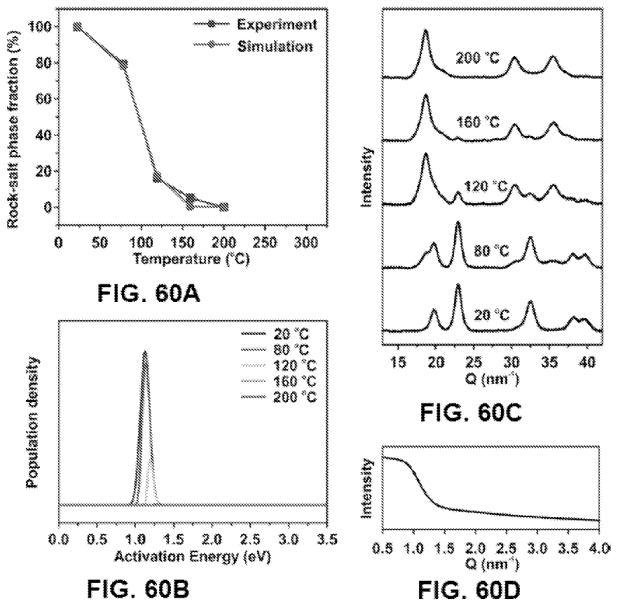

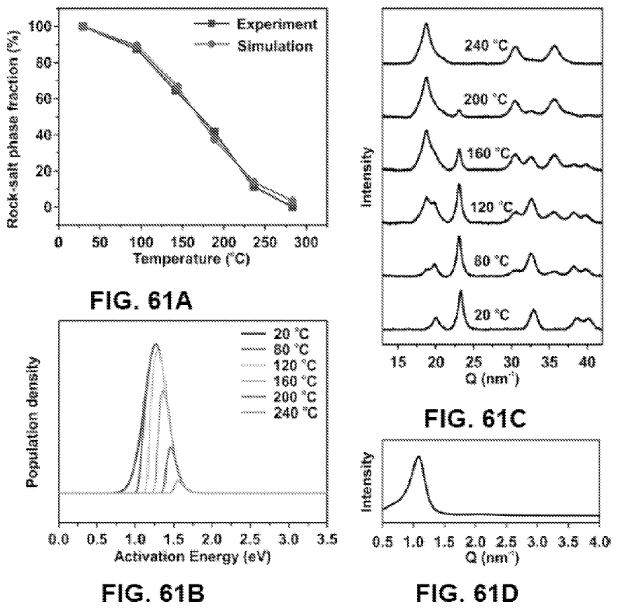

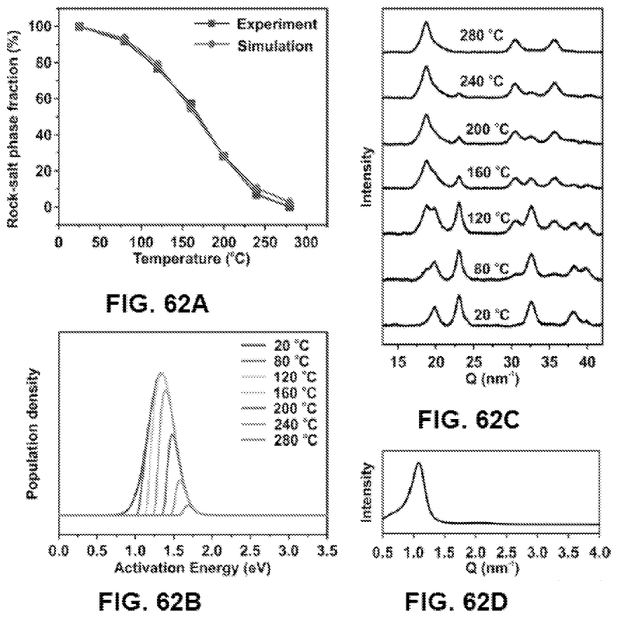

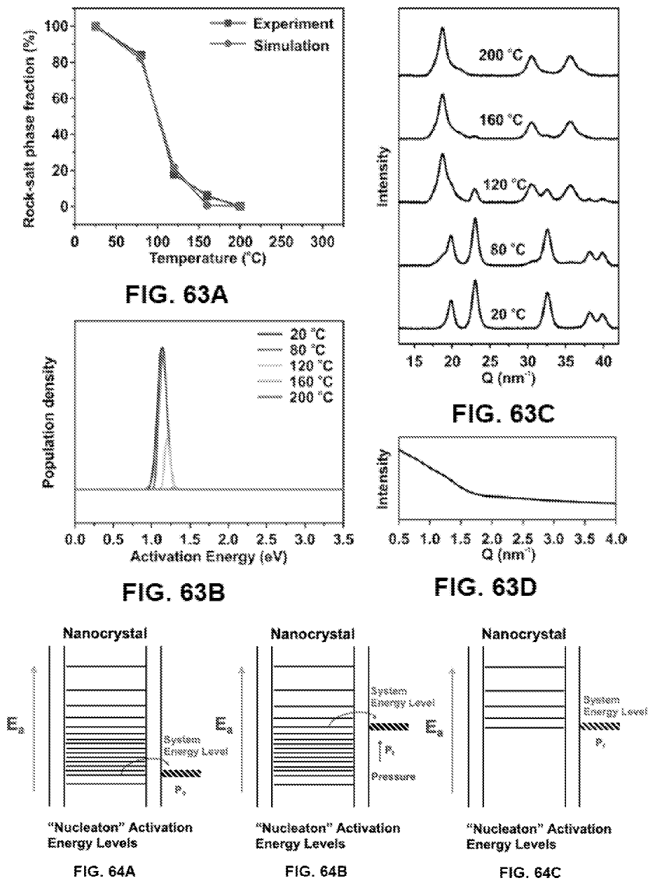

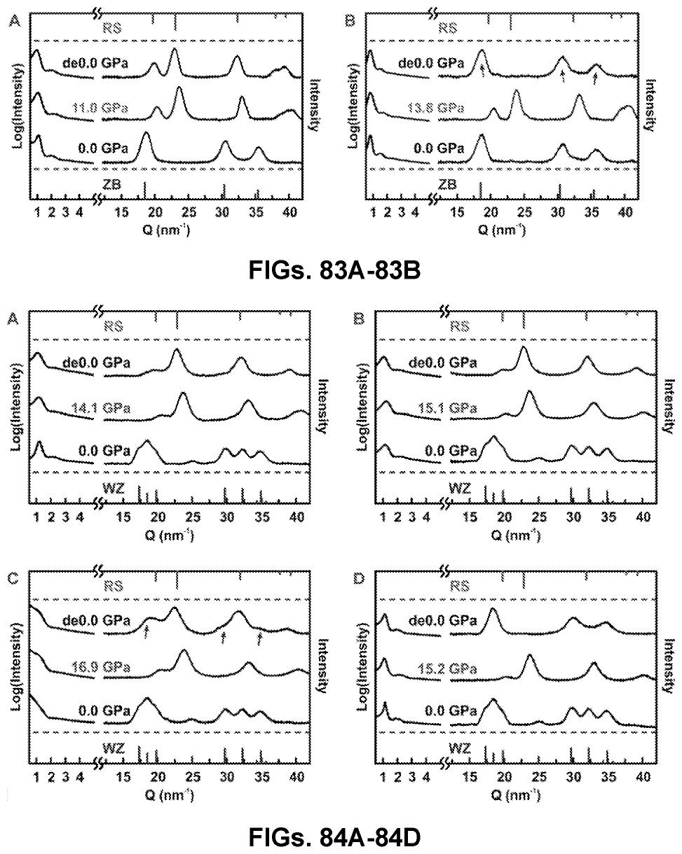

Chemical composition determines the availability of the types of chemical bonds and the corresponding bonding energies in a solid. These properties govern the formation of nucleation sites, as well as the defect/strain sink/annealing reactions that eliminate these nucleation sites. Therefore, the metastability of high-pressure crystal phases and the activation energy of nucleation sites for solid-solid phase transition should be ultimately determined by the chemical composition of the solid (FIGS. 1A-4B, 34A-63D, 67A-68C, 74A-85D, Table 3).

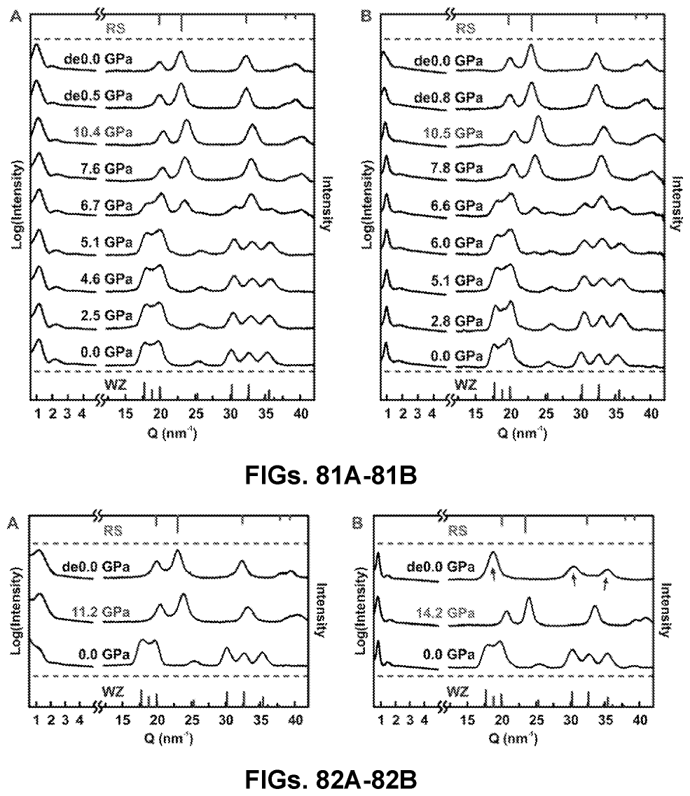

The chemistry of nanocrystal outer surface is also influential since the nanocrystal surface is composed of surface defects, which are the imperfections or irregularities that occur at the surface. These defects can include steps, cracks, vacancies and dislocations. Surface functionalization with organic and inorganic ligands can significantly modify the free energy of nanocrystal surface, chemical nature of surface defects, and surface reconstructions for minimizing free energy of nanocrystals. The existence of surface ligands also affects the defect/strain sink/annealing reactions which eliminate these nucleation sites. Therefore, the chemistry of nanocrystal outer surface should play a significant role in determining the metastability of high-pressure phases in a material (FIGS. 81A-84D).

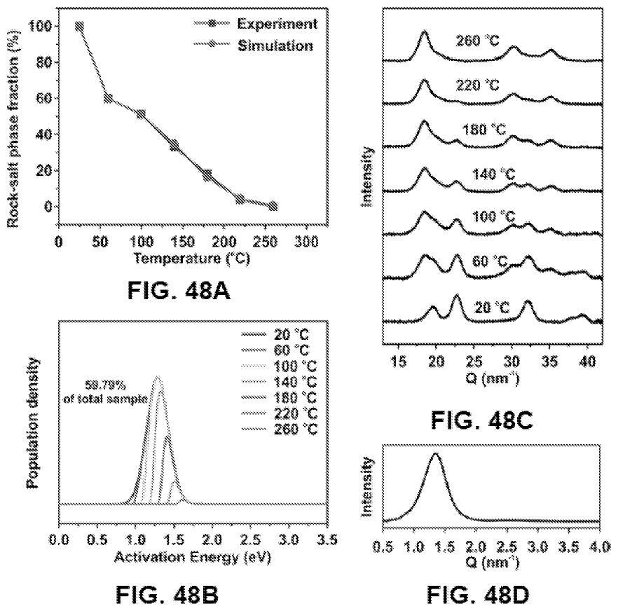

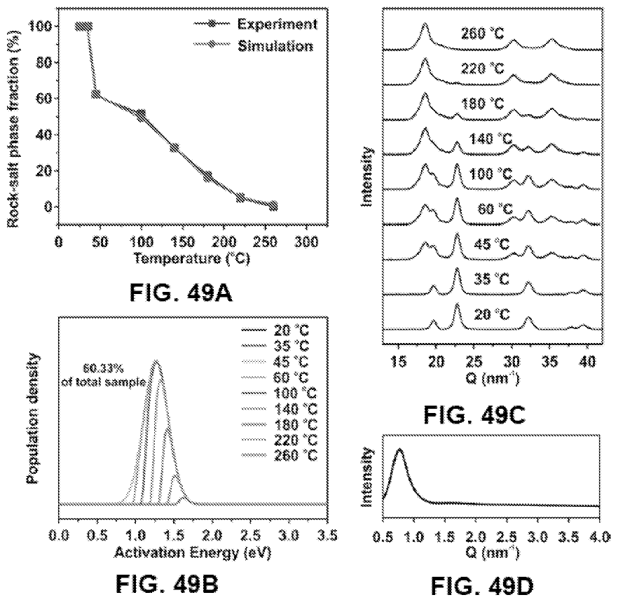

The chemistry of core/shell interface exerts and influence since this interface is also composed of surface defects including steps, cracks, vacancies, dislocations, or grain boundaries. Lattice mismatch between core/shell materials should significantly affect the chemical nature of these defects and thus elimination of these defects that are associated with phase-transition nucleation sites. Therefore, the existent of core/shell interface can significant modify the metastability of high-pressure phases of nanocrystals. Synthesis of core/shell structure through a gradient shell approach can minimize the surface defects at this interface and improve the metastability of high-pressure phases (FIGS. 48A-53D, Table 3).

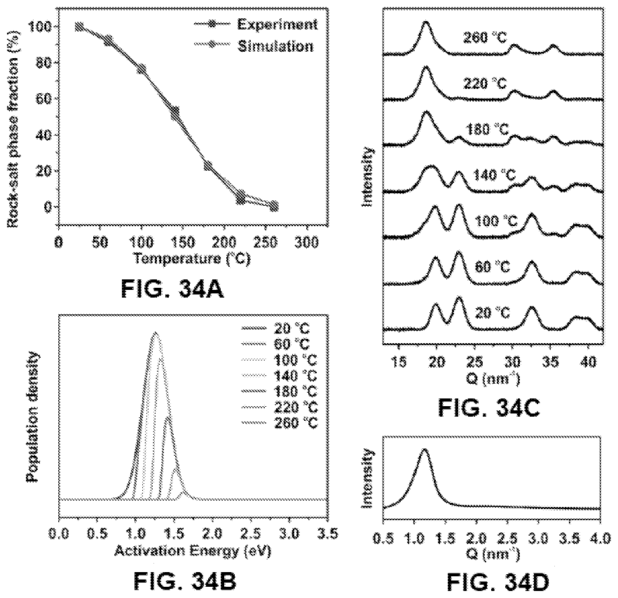

The size of nanocrystals can affect the atomic ratio between and interior (or volume). The increase of nanocrystal size can result in an increase of activation energy barrier height for directionally dependent nucleation of solid-solid phase transition, such as a sliding planes mechanism (FIGS. 34A-47D, Table 3).

On other hand, the decrease of nanocrystal size increases the atomic ratio between surface and interior. When the surface energy dominates the interior cohesive energy, upon a high pressure, interparticle sintering reaction would lead to a total fusion of neighboring nanocrystals into larger sized single crystalline domains. Therefore, there should exist a lower size limit, below which total fusion of nanocrystals takes place. The specific size limit should be dependent on the chemical composition of nanocrystals (FIGS. 22A-22E).

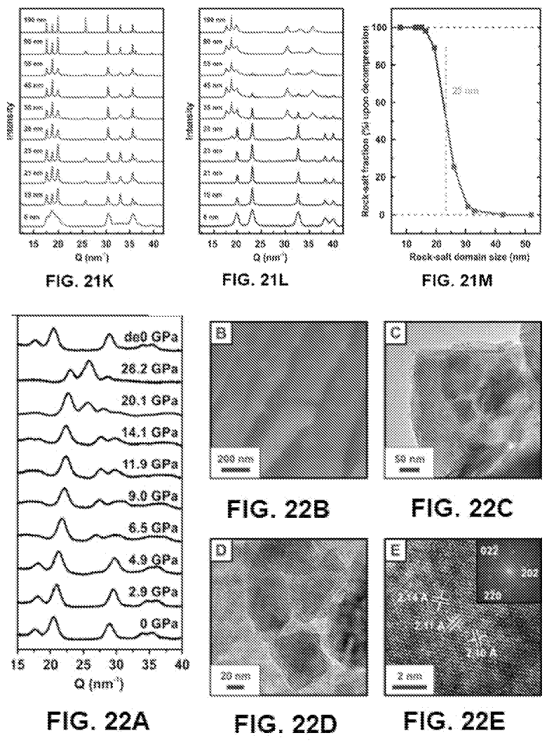

Nanocrystal size affects the grain boundary size and cross-sectional area. As the size of nanocrystals increases, there exists a crossover size, above which the inverse Hall-Petch effect is shifted to the Hall-Petch effect. In the regime where the inverse Hall-Petch effect dominates, crystalline defects are more easily eliminated compared to the larger size regime where the Hall-Petch effect dominates (FIGS. 21A-21M).

According to the classical understanding, the Hall-Petch equation predicts an increase in yield stress (σ_{y}) with decreasing grain size, given by

$${σ}_{y} = {σ}_{0} + \frac{{K}_{y}}{\sqrt{d}} ,$$

where σ₀ represents the friction stress in the absence of grain boundaries, K_{y} is the material-specific strengthening coefficient, and d is the average grain size. As the grain size decreases, the yield stress increases because materials with finer grains have fewer dislocations in pile-ups. Consequently, a larger applied stress is required to generate dislocations in adjacent grains at the tip of the pile-up.

In the size regime dominated by the Hall-Petch effect, the interaction between grain boundaries and crystalline defects/strains, as well as the interactions among crystalline defects/strains in neighboring nanodomains, is hindered because the crystalline domains can support dislocation pile-ups. However, when the domain size becomes smaller than the transition size, nanodomains are unable to support dislocation pile-ups, leading to the occurrence of the inverse Hall-Petch effect. In this size regime, grain-size dependent creep and grain-boundary shearing mechanisms would also contribute to the inverse Hall-Petch effect. Importantly, the inverse Hall-Petch effect allows for the interaction between grain boundaries and crystalline defects/strains, as well as the interactions among crystalline defects/strains in neighboring nanodomains. Consequently, it facilitates the elimination of crystalline defects/strains and their associated nucleation sites with low activation energies.

The scaling law for Coble creep indicates that the creep strain rate (grain boundary diffusion) is inversely dependent on the cube of nanocrystal size:

$$\dot{ε} = \frac{α ρ Ω δ {D}_{gb}}{{d}^{3} {k}_{B} T} ,$$

where σ is the stress, Ω is the atomic volume, δ is the grain boundary width, D_{gb} is the grain boundary diffusivity, k_{B} is the Boltzmann constant, T is the absolute temperature, and a is a constant related to the grain geometry. This scaling law of Coble creep suggests that crystalline defects/strains can be more easily eliminated in nanodomains with smaller sizes compared to larger-sized nanodomains.

Stress concentration: for stress concentration at flaws (crystal defects) at nanometer scale, there exists a critical length scale below which the fracture strength of a cracked crystal is identical to that of a perfect crystal. This stress concentration effect would limit the synthesizability of interconnected nanocrystal networks with ambient metastable crystalline phases through the high-pressure route. In the process of decreasing pressures, small local pressure fluctuations at the level 0.1 gigapascal is not avoidable. Such local pressure differences can be significant concentrate on defects on nanocrystals whose size is larger than the critical length (FIGS. 21A-21M).

The lower size limit: The decrease in nanocrystal size increases the atomic ratio between the surface and interior. When the surface energy dominates the interior cohesive energy, under high pressure, an interparticle sintering reaction would lead to the coalescence of neighboring nanocrystals into larger-sized single crystalline domains. This phenomenon can be regarded as total fusion in contrast to the partial fusion, where no significant domain size coarsen takes place. Therefore, there should be a lower size limit below which the coalescence of nanocrystals takes place. When the size of resulting nanodomains exceeding the upper size limit of this material, in turn, this total fusion process triggers the loss of ambient metastability of high-pressure crystal structures (FIGS. 22A-22E).

The specific lower size limit depends on the chemical composition of the nanocrystals, temperature and pressure. Under a given pressure, the higher the temperature, the larger the size of this lower limit, and vice versa. Additionally, the presence of dopants can either inhibit or promote grain boundary growth, resulting in a decrease or increase in the lower size limit, respectively. In other words, dopants can be utilized to control the lower size limit of a material.

Both thermodynamic and kinetic mechanisms can contribute to the establishment of the lower size limit. In a thermodynamic mechanism, the total free energy of a spherical single crystalline nanodomain can be written as:

$$Δ G = \frac{π}{2} {d}^{2} α - \frac{π}{6} {d}^{3} Δ {G}_{v} ,$$

where d represents the diameter of the nanodomain, α is the surface tension, and ΔGᵥ is the difference in average free energy per unit volume between the phase in which nucleation occurs and the thermodynamic phase. Please note that specifically speaking, a typical nanocrystal composes a crystalline core and a disorder (or amorphous sometime) shell. The ΔGᵥ of nanocrystals is the volumetric average of free energy of their core and shell parts.

When ΔG is less than zero (ΔG<0), this nanodomain can maintain its structural integrity (e.g., crystalline lattice orientation and crystalline domain size) during interparticle sintering processes with neighboring nanodomains. Conversely, when ΔG is greater than zero (ΔG>0), the interparticle sintering of neighboring nanodomain tends to increase crystalline domain size to minimize free energy, resulting in single crystalline domains with sizes larger than that of the original nanodomains. The critical nanodomain size for this transition occurs when ΔG equals zero (ΔG=0), and thus the lower size limit for a metastable nanodomain that can exist thermodynamically can be expressed as

$$d = \frac{3 α}{Δ {G}_{v}}$$

Mechanisms with both thermodynamic and kinetic aspects would also play roles in the establishment of the lower size limit. One such mechanism is domain-size dependent grain boundary growth through a grain-rotation-coalescence (or oriented attachment) mechanism. In addition, when the sizes of nanodomains approach the dynamic width of grain boundaries, nanodomain size growth can occur through Ostwald ripening under external pressure.

Taken together, these size effects are anticipated to define both the lower and upper size limits for synthesizable interconnected nanocrystal networks with ambient metastable crystalline phases (FIGS. 21A-22E). Within these two limits, the activation energy of the interconnected network initially increases to a plateau due to the directionally dependent nucleation mechanism until reaching the crossover size. Beyond this size, the Hall-Petch effect could significantly hinder the mechanisms in eliminating crystalline defects and lattice detorsions from interconnected nanodomains, and thus the activation energy would decrease with increasing size (FIGS. 34A-47D).

Once the size surpasses the critical length at which stress concentration becomes effective, the fragmentation of nanodomains triggers a transition from the metastable crystalline phase (e.g., RS) to a thermodynamically stable phase (e.g., ZB). This leads to a low “apparent” activation energy that cannot sustain the presence of metastable crystalline phases under ambient pressure. This critical length may fall within the same length range as, or exceed, the crossover size for the inverse Hall-Petch and Hall-Petch effects. Together with the crossover size, this critical length establishes the upper size limit for constituent nanodomains in synthesizable interconnected nanodomain networks capable of hosting metastable crystal phases under ambient pressure (FIGS. 21A-21M).

Supercrystalline order: the order of nanocrystal assemblies has an impact on the topology of the force-chain network under external pressure. Disorders in nanocrystal assemblies can cause variations in the local pressures experienced by individual nanocrystals within the nanocrystal networks inside a diamond anvil cell. These pressure variations lead to fluctuations in the local free energy within the nanocrystal networks, resulting in significant fluctuations in the activation energies for phase transitions (FIGS. 93A-93B).

Furthermore, disorders in nanocrystal assemblies also reduce the degree of nanocrystal network, such as the coordination number between neighboring nanocrystals. Normally, a lower degree of nanocrystal network, indicated by a smaller coordination number, corresponds to a lower activation energy for solid-solid phase transition from a metastable to a thermodynamic stable phase (FIGS. 93A-93B).

Shape: on one hand, the shape of constituent nanocrystals, along with the effects of supercrystalline order, can alter the topology of force-chain networks, leading to substantial fluctuations in the local pressure experienced within a nanocrystal sample inside a diamond anvil cell. These fluctuations result in variations in the local free energy within the nanocrystal networks, causing significant fluctuations in the activation energies for phase transitions. For instance, disordered nanorod assemblies typically yield samples that exhibit partial reversibility to the zinc-blende structure under ambient pressure (FIGS. 34A-63D, 93A-93B, Tables 3-4).

On the other hand, the shape of the constituent nanocrystals can interact with highly ordered nanocrystal assembly arrangements (such as supercrystalline structures), resulting in highly ordered and defect-free interconnected nanodomain networks where the activation energy is significantly increased. For example, with nanocubes as the building blocks, nanocrystal partial fusion can lead to the creation of three-dimensional interconnected networks of nanodomains with planar defects at boundaries between neighboring nanodomains, where planar defects can be intrinsic stacking faults, inversion domain boundaries, etc. If the size of resulting nanodomain is below the upper size limit, the RS-to-ZB phase transformation activation energy would be significantly elevated. However, if the resulting nanodomain size exceeds the upper size limit, the nanodomain network becomes unable to accommodate the metastable crystal phases under ambient pressure, leading to very small activation energy barriers for RS-to-ZB phase transition.

External pressure: external pressure acts as the driving force in the formation of interconnected nanocrystal networks. Increasing external pressure corresponds to higher Gibbs free energy in nanocrystal systems. The higher Gibbs free energy facilitates the elimination of lattice defects and strains with lower free energy, leading to the formation of interconnected nanocrystal networks with higher activation energies for solid-solid phase transitions from a metastable to a thermodynamically stable phase (FIGS. 48A-50D, 54A-59D, Tables 3-4).

Temperature: Alongside external pressure, the system temperature also significantly affects the formation of interconnected nanocrystal networks. Under constant external pressure, an increase in system temperature elevates the nanocrystals' Gibbs free energy, facilitating processes that can eliminate nucleation sites and leading to an increase in activation energy until a critical temperature is reached. Beyond this temperature, the constituent nanocrystals undergo complete fusion, resulting in a single crystalline structure with a size larger than the upper limit for hosting metastable phases. This, in turn, leads to a significant decrease in activation energy.

External physical fields. Under a given temperature and pressure, the presence of external fields can significantly modify the Gibbs free energy of the nanocrystal system, as well as the formation and elimination of lattice defects and strains associated with nucleation sites during the transition from a metastable crystal phase to thermodynamically stable ones. These fields can include electric fields, magnetic fields, and electromagnetic fields.

(1) Electric fields, generated by direct current (DC), alternating current (AC), or pulsed electric current, can induce an elevation in the field-induced Gibbs free energy of nanocrystal systems and their defects and strains. This elevation facilitates the elimination of nucleation sites for phase transitions through partial fusion of neighboring nanocrystals.

Additionally, electric fields provide novel mechanisms for local heating, such as Joule heating, electrical discharges, and high-temperature plasma, through techniques like electric current activated/assisted sintering, including electrical discharge sintering, resistive sintering, or spark plasma sintering (also known as pulsed electric current sintering or field-assisted sintering). These local heating mechanisms enable precise control of temperatures between neighboring nanocrystals, resulting in a more effective elimination of nucleation sites for phase transitions and elevated activation energy barriers for such transitions.

Moreover, electric fields can assist in the assembly and alignment of nanocrystals during pressure-assisted sintering, enabling control over the topology of interconnected nanocrystal networks. This, in turn, allows for the manipulation of the phase transition activation energies of the networks.

(2) Magnetic fields generated during electric current-assisted sintering can have significant effects on the sintering process, enabling controlled engineering of activation barrier heights in the transition from a metastable crystal phase to a thermodynamically stable one. These magnetic fields generate substantial magnetic forces, resulting in inductive electrical loads and preferential heating induced by overlapping magnetic fields due to the proximity effect. The proximity effect occurs when two or more conductors carrying alternating current are in close proximity, causing the distribution of current in each conductor to be affected by the varying magnetic field produced by the others. Consequently, eddy currents are induced in the adjacent conductors. When nearby conductors carry current in the same direction, the current is concentrated at the farthest side of the conductors. Conversely, when nearby conductors carry current in opposite directions, the current is concentrated at the nearest parts of the conductors. The effective resistance of the conductor increases due to the proximity effect, which is further amplified with an increase in the frequency of the alternating current (AC).

Strong DC magnetic fields can aid in the alignment and assembly of nanocrystals during pressure-assisted sintering. This enables control over the topological connectivity of interconnected nanocrystal networks, thereby allowing for manipulation of the activation energies for phase transitions within the networks.

(3) Electromagnetic radiations, depending on their energy, can lead to following effects on the nucleation sites of solid-solid phase transitions. First, electromagnetic radiations with specific energies can lead to electron excitations to the anti-bonding orbitals of materials, resulting in the generation or elimination of crystal defects and strains, which can facilitate the removal of nucleation sites with low activation energies, promoting metastability of high-pressure phases at ambient pressure.

Second, low-energy electromagnetic fields, such as infrared (IR) lights and microwaves, can serve as local heating mechanisms at the nanometer scale. These mechanisms aid in interparticle sintering, enabling control over the activation energy of nucleation sites and the metastability of high-pressure phases within the resulting interconnected nanocrystal networks under ambient pressure.

Sound Waves. Ultrasound serves as an additional driving force for aiding in pressure-induced interparticle partial fusion. This process can promote the ambient metastability of high-pressure crystal phases within the resulting interconnected nanocrystal networks.

Shock wave-assisted partial fusion. A shock wave is a type of propagating disturbance that moves faster than the local speed of sound in the medium. Similar to an ordinary wave, a shock wave carries energy and can propagate through a medium. However, it is characterized by an abrupt, nearly discontinuous change in pressure, temperature, and density of the medium. By controlling shock waves, it is possible to induce solid-solid phase transitions in nanocrystals and achieve partial fusion of neighboring nanocrystals. Consequently, shock wave-assisted nanocrystal partial fusion can occur even in the absence of extreme pressure, while still allowing the resulting interconnected nanocrystal networks to host ambient metastable crystal phases.

Chemical fields. Liquid solutions, in which nanocrystals are dispersed, can act as both pressure transmitting media and chemical fields to control pressure-assisted interparticle sintering. A liquid solution containing specific molecular and/or ionic species can promote interparticle sintering under pressure and facilitate the surface reorientation and reorganization of forming interconnected nanodomain networks. Consequently, precise control over the chemical composition of the liquid phase is an effective method for engineering the ambient metastability of high-pressure phases within the resulting interconnected nanocrystal/nanodomain networks.

### The Activation Energy Fluctuations of Nucleation in a Canonical Ensemble

Under the thermodynamic equilibrium of the reactions of defects/strain propagation, absorption, sink and annihilation in an interconnected nanocrystal network at a given pressure, zinc-blende nucleation sites can be seen as nucleatons (ideal gas) dispersing inside rock-salt nanocrystal network systems, which can be described using the canonical ensemble.

The degree of thermal fluctuations of Helmholtz free energy (F) of the nanocrystal network system is same as that of the fluctuations in the activation energies of nucleatons due the chemical equilibrium. The probability distribution function of nucleation activation energies in the system can be described with

$${Ψ}_{0} ( {E}_{a} ) = \frac{1}{{σ}_{T} \sqrt{2 π}} {e}^{- \frac{{( E - {E}_{0} )}^{2}}{2 {σ}_{T}^{2}}}$$

where E₀ is mean activation energy, and σ_{T}²=k_{B}T²CV, in solid each atom has six degrees-of-freedom to distribute its energy (kinetic and potential), each degree of freedom has ½ k_{B} contribution to its Cᵥ. if the value of σ_{T}², is known, the size (or at least the degrees of freedom) of nucleatons can be estimated.

Maximizing entropy of force Chain networks resulting in a fluctuation in pressure experienced by individual nanocrystals in the nanocrystal networks, which introduce additional fluctuation in Helmholtz free energy (F) of the nanocrystal networks. Thus, a fluctuation in activation energy of nucleatons is introduced du with a variance: σ to the maximizing the entropy of force chain networks, which can be described, where the weighted degree distribution (coordination number, the physical natures of grain boundaries (e.g., high angle or low angle contact and the area of cross sections).

Taking together these two variances, the probability distribution function of nucleation activation energies in the system can be described with a variance σ²=σ_{T}²+σ_{F}²

$${Ψ}_{0} ( {E}_{a} ) = \frac{1}{σ \sqrt{2 π}} {e}^{- \frac{{( E - {E}_{0} )}^{2}}{2 {σ}^{2}}}$$

If σ² is known, the maximal the size (or at least the maximal degrees of freedom) of nucleation can be estimated, because σ_{F}² is larger than 0.

### Local and Ensemble Activation Energy Fluctuations

In this canonical ensemble, the thermodynamic equilibrium is achieved through local chemical reactions among neighboring nanocrystals. The local activation energy fluctuation is likely smaller than that of the Ensemble, forming clusters where each nanocrystal displays activation energy PDF as

$$PDF ( {X}_{A} \vert {E}_{block} ) = \frac{1}{Δ \sqrt{2 π}} {e}^{- \frac{{( {X}_{A} - {E}_{block} )}^{2}}{2 {Δ}^{2}}}$$

Due to the existence of ensemble chemical equilibrium in defect annihilation among entire nanocrystal network, then distribution of E_{cluster} follows a gaussian with same mean as that of individual nanocrystals (E₀) in the network and with a variance of σ_{c}²>0:

$$PDF ( {E}_{block} ) = \frac{1}{{σ}_{c} \sqrt{2 π}} {e}^{- \frac{{( {E}_{block} - {E}_{0} )}^{2}}{2 {σ}_{b}^{2}}}$$

Ensemble activation energy distribution of individual nanocrystals can be constructed with the activation energy distribution PDF of clusters and local PDF of nanocrystals.

$$PDF ( {X}_{A} ) = {\int }_{- ∞}^{+ ∞} {dE}_{block} \times \{ PDF ( {X}_{A} \vert {E}_{block} ) \times PDF ( {E}_{block} ) \} \\ PDF ( {X}_{A} ) = {\int }_{- ∞}^{+ ∞} {dE}_{block} \times \{ [ \frac{1}{{σ}_{c} \sqrt{2 π}} {e}^{- \frac{{( {E}_{block} - {E}_{0} )}^{2}}{2 {σ}_{b}^{2}}} ] \times [ \frac{1}{Δ \sqrt{2 π}} {e}^{- \frac{{( {X}_{A} - {E}_{block} )}^{2}}{2 {Δ}^{2}}} ] \} = \frac{1}{\sqrt{2 π ( {σ}_{b}^{2} + {Δ}^{2} )}} {e}^{- \frac{{( {X}_{A} - {E}_{0} )}^{2}}{2 {σ}_{b}^{2} + 2 {Δ}^{2}}}$$

We can then obtain the relationship:

$${σ}^{2} = {σ}_{c}^{2} + {Δ}^{2} .$$

Many modifications and other embodiments disclosed herein will come to mind to one skilled in the art to which the disclosed compositions and methods pertain having the benefit of the teachings presented in the foregoing descriptions and the associated drawings. Therefore, it is to be understood that the disclosures are not to be limited to the specific embodiments disclosed and that modifications and other embodiments are intended to be included within the scope of the appended claims. The skilled artisan will recognize many variants and adaptations of the aspects described herein. These variants and adaptations are intended to be included in the teachings of this disclosure and to be encompassed by the claims herein.

Although specific terms are employed herein, they are used in a generic and descriptive sense only and not for purposes of limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates, which can require independent confirmation.

While aspects of the present disclosure can be described and claimed in a particular statutory class, such as the system statutory class, this is for convenience only and one of skill in the art will understand that each aspect of the present disclosure can be described and claimed in any statutory class.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

Prior to describing the various aspects of the present disclosure, the following definitions are provided and should be used unless otherwise indicated. Additional terms may be defined elsewhere in the present disclosure.

### Definitions

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by,” “comprising,” “comprises,” “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of” Similarly, the term “consisting essentially of” is intended to include examples encompassed by the term “consisting of.

As used in the specification and the appended claims, the singular forms “a,” “an” and “the” include plural referents unless the context clearly dictates otherwise. Thus, for example, reference to “a ligand,” “a nanocrystal,” or “a synthesis temperature,” include, but are not limited to, mixtures or combinations of two or more such ligands, nanocrystals, or synthesis temperatures, and the like.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y.’ The range can also be expressed as an upper limit, e.g. ‘about x, y, z, or less’ and should be interpreted to include the specific ranges of ‘about x,’ ‘about y’, and ‘about z’ as well as the ranges of ‘less than x’, less than ‘y’, and ‘less than z’. Likewise, the phrase ‘about x, y, z, or greater’ should be interpreted to include the specific ranges of ‘about x,’ ‘about y,’ and ‘about z’ as well as the ranges of ‘greater than x,’ greater than ‘y,’ and ‘greater than z.’ In addition, the phrase “about ‘x’ to ‘y’”, where ‘x’ and ‘y’ are numerical values, includes “about ‘x’ to about ‘y’”.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained.

In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

As used herein, the term “effective amount” refers to an amount that is sufficient to achieve the desired modification of a physical property of the composition or material. For example, an “effective amount” of a ligand refers to an amount that is sufficient to achieve the desired improvement in the property modulated by the formulation component, e.g. achieving the desired amount of metastable high-pressure phase in the nanocrystal solids disclosed herein. The specific level in terms of wt % in a composition required as an effective amount will depend upon a variety of factors including the amount and type of ligand, chemical identity of the nanocrystals, pressure and temperature employed during synthesis of the nanocrystal solid, and end use of an article incorporating the nanocrystal solid.

As used herein, the terms “optional” or “optionally” means that the subsequently described event or circumstance can or cannot occur, and that the description includes instances where said event or circumstance occurs and instances where it does not.

As used herein, “ambient conditions,” “ambient pressure,” “ambient temperature,” and the like, refer to standard atmospheric pressure (about 1 atmosphere or about 101 kPa) and room temperature (i.e. about 20 to 25° C.). These terms are intended encompass certain variations based on elevation above sea level, weather, light exposure, and the like, and are typically comfortable for humans wearing indoor clothing.

An “interconnected nanodomain network” or “interconnected nanocrystal network” as used herein refers to a network of two or more different phases or crystal structures, wherein the interconnected nanodomain network exhibits properties not evident in any component phase or crystal structure. Novel properties of interconnected nanodomain networks arise from the grain boundary network of nanodomains or nanocrystal phases, which can be a collective effect such as a lattice or interlock effect; arise from the interface of or between individual nanodomains; and arise from the volume or interior of individual nanodomains. In some aspects, formation of an interconnected nanodomain network results in the presence of or an increase in conductivity as opposed to isolated, non-interconnected crystal phases. In an aspect, interparticle sintering reactions lead to the formation of grain and/or twin boundaries (GTBs) between neighboring component particles, resulting in the creation of three-dimensionally interconnected nanocrystal networks.

In a further aspect, within these interconnected nanodomain networks, crystal defects can be delocalized through stress-driven diffusion or propagation. Without wishing to be bound by theory, this process enables two key phenomena: (1) delocalized and collective interactions between GTBs and crystal defects occur within the interconnected network, where GTBs act as sources, sinks, or both, facilitating the absorption and annihilation of crystal defects, and (2) delocalized defect annihilation takes place among interconnected nanodomains within the network. In a further aspect, these two processes, combined with the interparticle sintering reactions, give rise to the three major mechanisms for the elimination of crystal defects and lattice distortions from RS CdS and/or other nanodomains, or equivalent nanodomains in other compounds, within the networks.

Now having described the aspects of the present disclosure, in general, the following Examples describe some additional aspects of the present disclosure. While aspects of the present disclosure are described in connection with the following examples and the corresponding text and figures, there is no intent to limit aspects of the present disclosure to this description. On the contrary, the intent is to cover all alternatives, modifications, and equivalents included within the spirit and scope of the present disclosure.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the disclosure and are not intended to limit the scope of what the inventors regard as their disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### Example 1: Nanocrystals with Metastable High-Pressure Phases Under Ambient Conditions

Solids from a collection of atoms can adopt a variety of structural phases having respective physical and chemical properties, providing the foundation for materials discovery. At ambient temperature and pressure, there is often one thermodynamically stable phase for a given atomic collection, and the rest can potentially become metastable as kinetically trapped phases with positive free energy above the equilibrium state. However, a general strategy for engineering kinetic barriers has yet to be developed but is essential for the rational synthesis of new materials and for expanding the space of synthesizable metastable materials.

Phase transformations in bulk solids exhibit complex kinetics involving different microscopic pathways occurring in parallel at different locations in one crystal domain, which are thus difficult to determine experimentally. On the other hand, transition pressures measured in experiments match well with the theoretical values determined via electronic structure calculations. For instance, the thermodynamic transition in silicon from a diamond to a 0-tin structure was calculated to be 8.0 GPa, while this transformation was observed experimentally in the range 8.8-12.5 GPa. However, based on theoretical stability analysis, Mizushima, Yip, and Kaxiras (MYK) have predicted that defect- and strain-free bulk Si can remain metastable in the diamond structure up to 64 GPa, which implies a huge intrinsic activation barrier (˜0.3 eV/atom) in the structural transformation. This discrepancy indicates that the predicted intrinsic energy barrier in ideal crystals is drastically decreased by mechanisms associated with defects in real bulk solids during high-pressure experiments. Importantly, the MYK calculation predicts that most high-energy solid phases are theoretically metastable at ambient conditions if their hosting crystals are defect- and strain-free. This allows for development of a general approach for making ambient metastable materials of given chemical compositions based on further understanding of kinetic pathways in solid-phase transformations.

Because of the availability of synthetic methods, high-quality colloidal CdSe semiconductor nanocrystals have been extensively used as models to study the phase transition from a four-coordinate wurtzite (WZ) to a six-coordinate rock-salt (RS) structure. Bulk CdSe undergoes a WZ-to-RS phase transition at ˜2.5 GPa, whereas defect-free wurtzite CdSe nanocrystals can be metastable at a pressure above 6.0 GPa, which provides strong evidence for the MYK calculation. Since these nanocrystals can behave as single structural domains under high pressures, their phase transition kinetics are simpler than in bulk solids and are highly reproducible. These advantages allowed for experimental measurements of the fundamental properties (e.g., activation energy, activation volume, and activation entropy) of the WZ-to-RS transition in CdSe nanocrystals, which revealed that the transformation exhibits direction-dependent nucleation undergoing a sliding-plane mechanism. However, detailed kinetic pathways for the reverse phase transformation from the six-coordinate RS to four-coordinate zinc-blende (ZB)/WZ structure remain unclear.

There is inconclusive evidence that under some conditions, high-pressure phases can be retained in nanocrystals upon release of pressure. At ambient conditions, a sample of 11-nm CdSe nanocrystals was found to comprise ˜20% metastable rock-salt structure, and that of 13-nm PbS nanocubes contained 37.2% metastable high-pressure phase. Additionally, the rock-salt phase of CdSe/ZnS and CdS nanocrystals can fully persist in a metastable state at ambient pressure. It is hypothesized that these observations are due to the existence of some unknown mechanisms that can eliminate crystal defects from high-pressure structures. To test this hypothesis, a mechanistic study was performed on reversibility of the RS-to-ZB transformation in systems comprising spherical nanocrystals or nanorods of CdSe and/or CdS semiconductors. Taking advantages of the superior synthetic controllability in nanocrystal systems, insight is obtained into the mechanisms and microscopic processes that determine kinetic barrier height between two crystal phases.

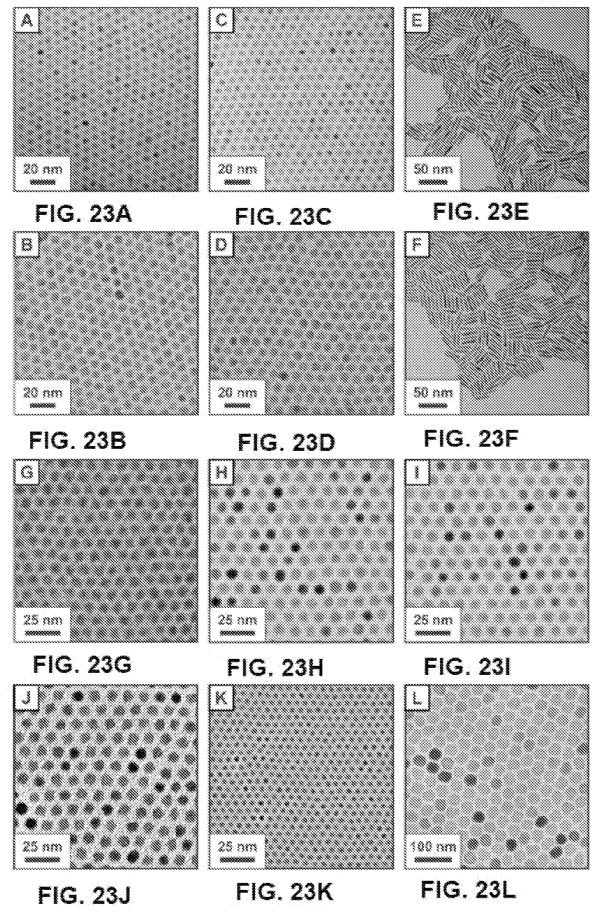

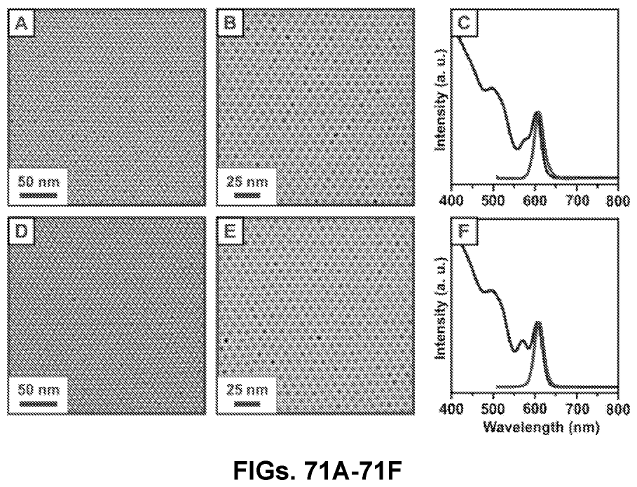

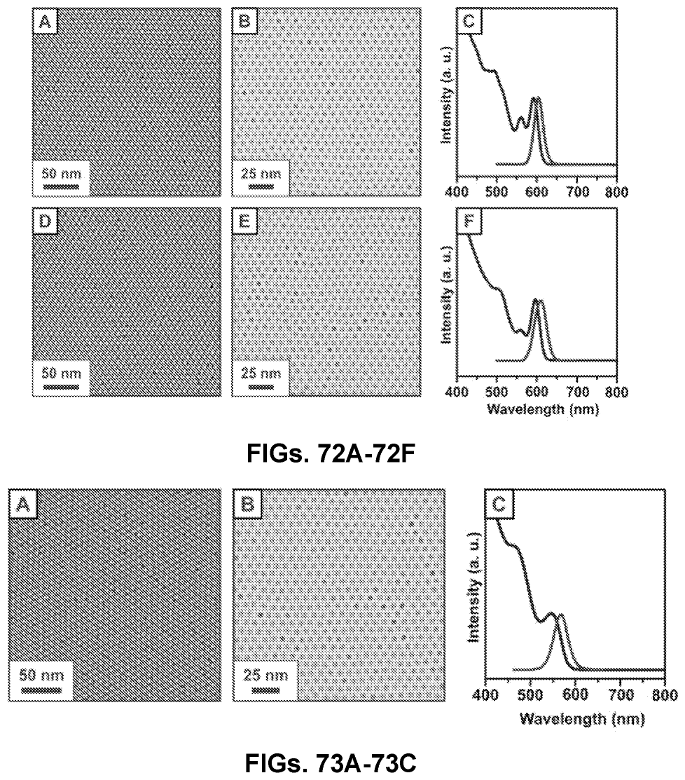

In this study, the ambient metastability of the rock-salt phase in CdSe and/or CdS nanocrystals was investigated as a function of composition, initial crystal phase, particle structure shape, surface functionalization, and order level of their assemblies. Six types of spherical nanocrystals were synthesized with nearly identical size with 4.8-nm diameter and one type of CdSe/CdS nanorods with 23.8-nm length and 4.8-nm diameter, with a narrow size distribution and high crystallinity, which were confirmed with transmission electron microscopy (TEM), UV-Vis absorption and fluorescence spectroscopy (FIGS. 23A, 23C, 23E, 71A-73C). The nanocrystal surface was precisely controlled via ligand exchange with a designed surface density. In this study, a surface density of 5 ligands per nm² is arbitrarily assigned as 100% ligand coverage. Assemblies of these nanocrystals were prepared either directly on the surface of a diamond anvil or at the air-liquid interface of diethylene glycol. The high-pressure experiments were performed with a diamond anvil cell without pressure media for introducing deviatoric stress to promote interparticle interactions. The solid-state phase structures as a function of pressure were determined with simultaneous measurements of small-angle X-ray scattering (SAXS) and wide-angle X-ray scattering (WAXS) at the Cornell High Energy Synchrotron Source.

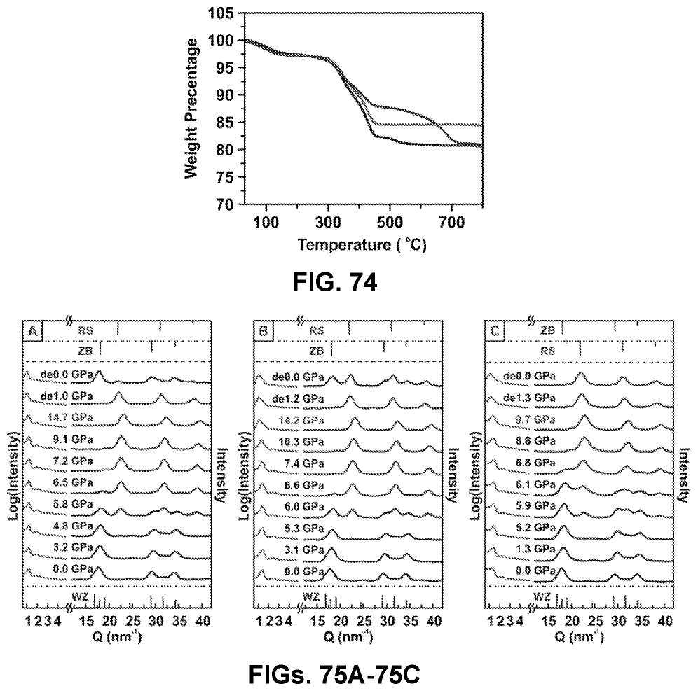

At ambient conditions, octylamine-capped wurtzite CdSe nanocrystals (92% coverage, FIG. 74) formed superlattices in a face-centered-cubic (fcc) structure with an interparticle distance of 6.76 nm (FIG. 67A). With increasing pressure, superlattice unit cell size decreased gradually until 7.2 GPa, above which the superstructure distorted, whereas the atomic wurtzite unit cell volume decreased smoothly up to a threshold pressure (6.0 GPa), at which point there was an abrupt decrease in unit cell volume due to the phase transformation to the rock-salt structure (FIG. 67A). Upon decompression, the distorted fee superlattice structure recovered in large part, while the atomic lattice system completely transformed to a four-coordinate zinc-blende structure (FIG. 67A). Solid phase transition of the atomic lattice exhibited a hysteresis of 6.0 GPa, which is very close to those measured with pressure media. In contrast, in the sample of CdSe nanocrystals capped with butylamine in 93% ligand density, 4.8% RS phase was preserved back to ambient pressure (FIG. 75A). These results suggest that ligand-shell thickness would play a major role in tailoring the reversibility of the RS-ZB phase transition in CdSe nanocrystal systems. Composition-ratio determination is provided in Table 2:

TABLE 2
Rock-Salt and Zinc-Blende Phase Percentage in
Samples Decompressed Back to Ambient Pressure

| Peak Intensity Ratio I_{RS}/I_{ZB} | | |
|---|---|---|
| When Decompressed | Rock-salt % | Zinc-blende % |
| 1.40 | 57.1 | 42.9 |
| 0.0526 | 4.8 | 95.2 |
| 1.33 | 55.9 | 44.1 |
| 0.0427 | 3.9 | 96.1 |
| 1.47 | 60.7 | 39.3 |
| 5.30 | 84.9 | 15.1 |
| 1.54 | 65.3 | 34.7 |
| 2.88 | 77.8 | 22.2 |

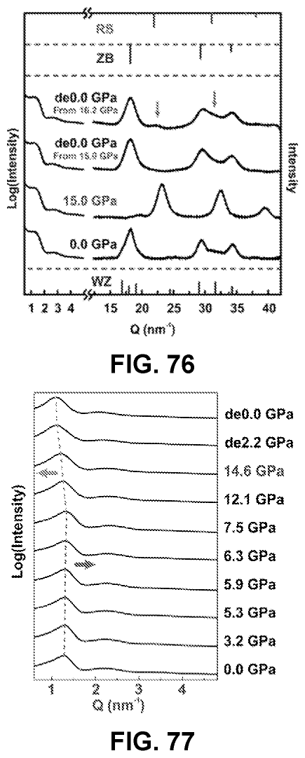

Accordingly, more than 50 beam-line experiments were performed to investigate the ambient metastability of rock-salt CdSe structures as a function of amine ligand density, the level of long-range order in nanocrystal assemblies, applied pressure (up to 22 GPa), and decompression rate. At optimized conditions, only 50-60% of the rock-salt structures were preserved in decompressed CdSe nanocrystal samples (FIGS. 67B, 75B. This result indicates that the surface binding of amine ligands might be too strong and thus minimizes effective interactions between neighboring nanocrystals. However, when pyridine (a weak-binding ligand) was used, resulting nanocrystal assemblies displayed nearly no long-range order, and no rock-salt structure was retained in the nanocrystal system decompressed from 15.0 GPa, whereas when decompression from 16.2 GPa, 3.9% of rock-salt structures were retained (FIG. 76). These results suggest that the order of nanocrystal assemblies should play a role in the preservation of the rock-salt CdSe structure at ambient conditions.

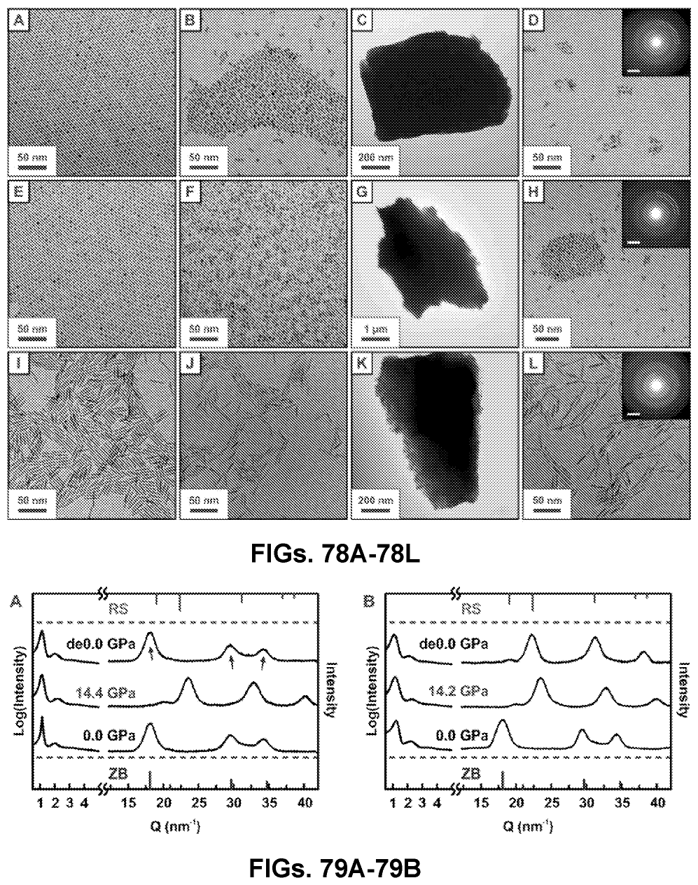

To weaken the average ligand-binding strength while retaining the nanocrystal's ability to form ordered superstructures, a dual-ligand approach was introduced with a mixture of a primary amine and cetyltrimethylammonium bromide (CTAB)—which can weakly bind to the surface of CdSe nanocrystals via electrostatic interactions. Indeed, the assembly of CdSe nanocrystals functionalized with octylamine and CTAB (5:1 with a coverage of 63%, FIG. 74) formed an fee superlattice with a (111) d-spacing of 5.03 nm (FIG. 67C). Amazingly, the RS-to-ZB transition became completely irreversible in these assemblies and the rock-salt CdSe structure was fully preserved at ambient conditions (FIG. 67C). On the superstructure side, the fee lattice constant decreased with pressure increase up to 7.5 GPa, above which point the superstructure started to distort (indicated by a continuous expansion in its dim-spacing) and then irreversibly transformed into a lamellar structure at pressures above ˜12.0 GPa (FIG. 77). Upon decompression to ambient pressure, the lamellar structure well retained its integrity and its d-spacing further increased to 5.81 nm (FIGS. 67C, 77). TEM observations showed that rock-salt CdSe nanocrystals existed only in the form of aggregates (FIG. 78C), which can be redispersed into 4.8-nm colloidal particles in chloroform under sonication, but their crystal phase transformed into the zinc-blende structure (FIG. 78D). Altogether, these results suggest that strong interparticle associations (e.g., sintering) may occur within the lamellar structures, which are associated with the ambient metastability of the rock-salt CdSe structure. Similar ligand-tailorable phenomena were observed in CdSe nanocrystals capped with butylamine and CTAB ligands (FIG. 75C).

Zinc-blende CdSe has a formation energy of 1.0 meV/atom lower than the wurtzite form, and such nanocrystals are enclosed by crystal faces different from those in wurtzite ones. However, no significant differences were observed between 4.8 nm zinc-blende and wurtzite CdSe nanocrystals in both pressure-induced transformation to the rock-salt structure and the ligand-tailorable reversibility of the RS-ZB phase transitions (FIGS. 79A-79B). Pure ambient metastable rock-salt CdSe nanocrystals can be synthesized also from zinc-blende nanocrystals (FIG. 79B), showing that the initial crystal phase is not important for the ambient metastability of the resulting rock-salt structures.

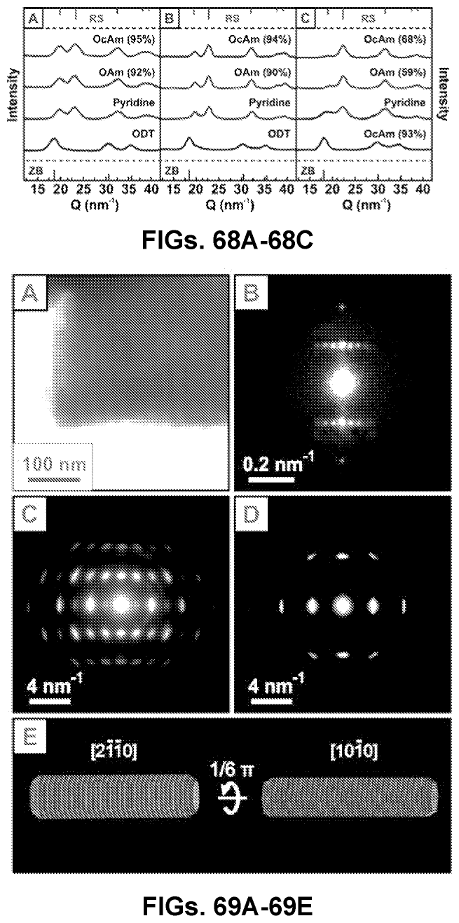

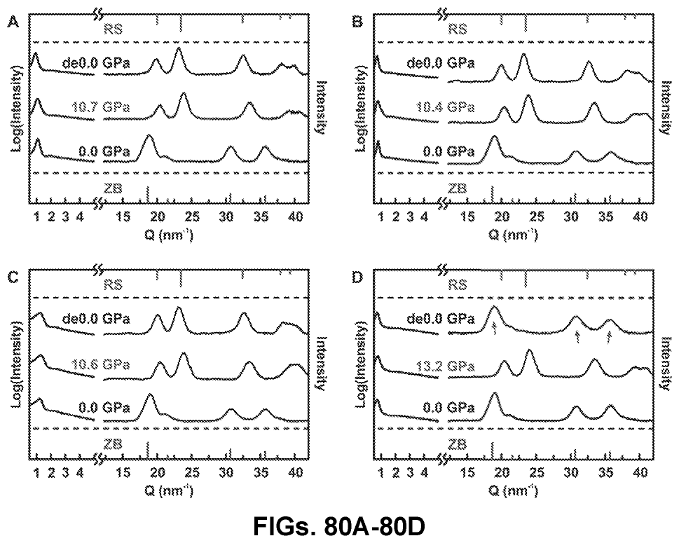

Bulk CdS, like CdSe, undergoes a reversible solid-phase transformation from a four- to six-coordinate structure at a pressure of ˜2.5 GPa. However, CdS nanocrystals exhibit significant difference in the ligand-tailorable reversibility of their RS-to-ZB phase transition as compared to their CdSe counterparts (FIG. 68A). Dual-ligand functionalization is not necessary for making ambient metastable rock-salt CdS nanocrystals. Upon decompression from a pressure above 10.4 GPa, the rock-salt CdS phase was fully preserved in assemblies made from 4.8-nm zinc-blende CdS nanocrystals capped with amine ligand coverage up to 95%, or even capped with 100% pyridine ligands, in which case nanocrystal assemblies exhibited no long-range order (FIGS. 2A, 80A-80C). In contrast, in assemblies of CdS nanocrystals functionalized with excess octadecanethiol (ODT, a stronger binding ligand than amines, for isolating CdS nanocrystals as separate particles at high pressures), the RS-ZB phase transformation was completely reversible even when decompressed from 15.2 GPa (FIGS. 68A, 80D). These results demonstrate that the rock-salt CdS phase is not intrinsically metastable at the nanometer scale, suggesting that the observed metastability in CdS nanocrystals should be also related to strong interparticle associations like in the case of rock-salt CdSe nanocrystals.

To further explore effects of chemical composition and particle structure, 4.8-nm CdSe/CdS core/shell nanocrystals were synthesized in a wurtzite or zinc-blende structure from corresponding 3.4-nm CdSe cores (FIGS. 72A-73C), and 4.8-nm wurtzite CdS/CdSe core/shell nanocrystals from 3.4-nm CdS cores. In terms of the ligand-tailorable reversibility of their RS-to-ZB phase transition, both wurtzite and zinc-blende CdSe/CdS nanocrystals exhibit a nearly identical property to CdS nanocrystals (FIGS. 68B, 81A-83B), whereas CdS/CdSe nanocrystals behaved in between CdS and CdSe nanocrystals (FIGS. 68C, 84A-84D). Together, these results demonstrate that the composition of shell and core both play important roles in maintaining the rock-salt phase at ambient conditions.

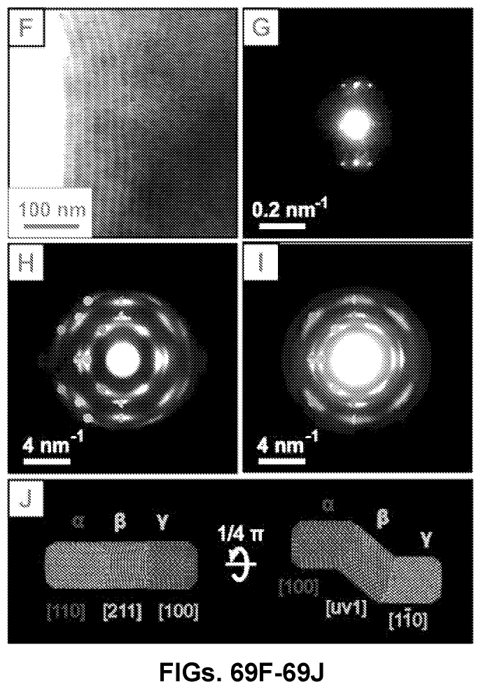

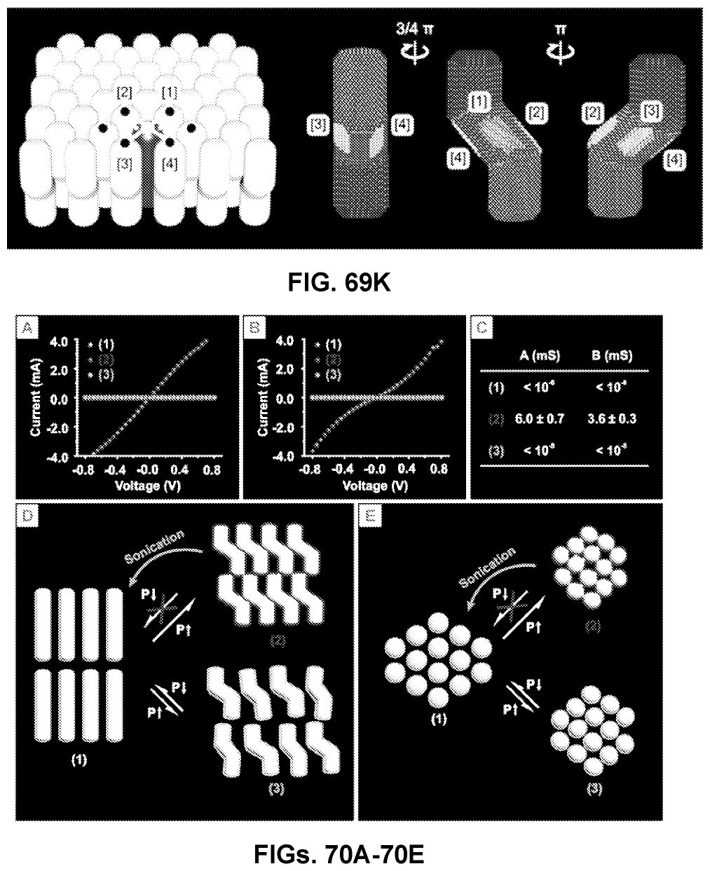

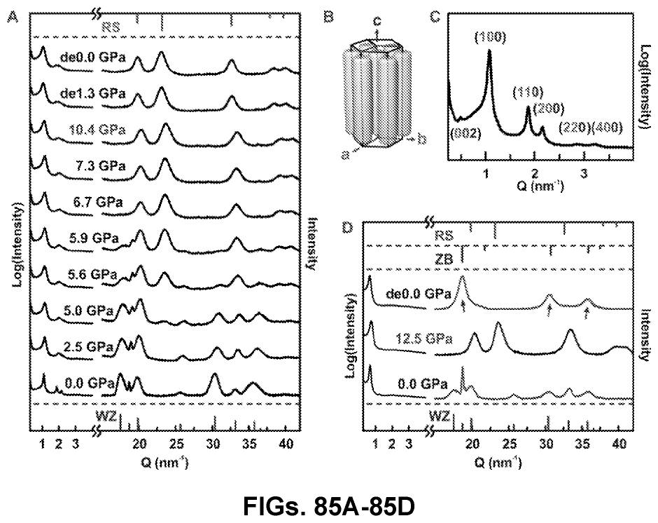

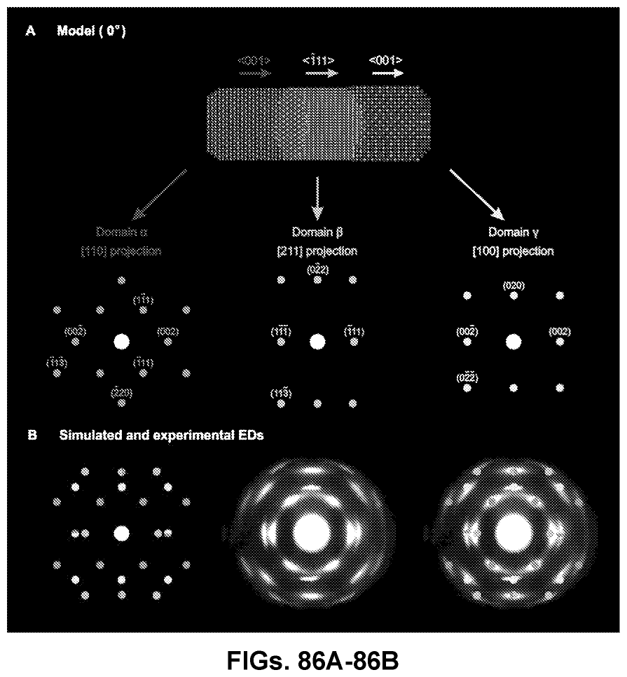

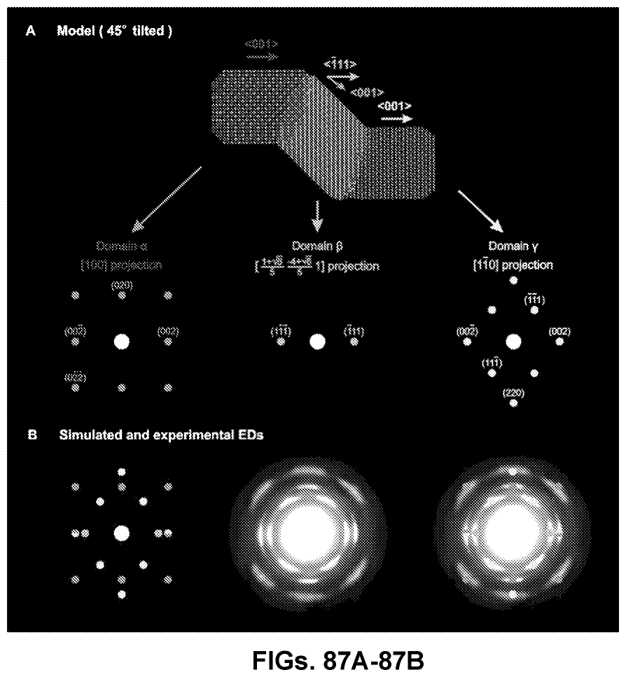

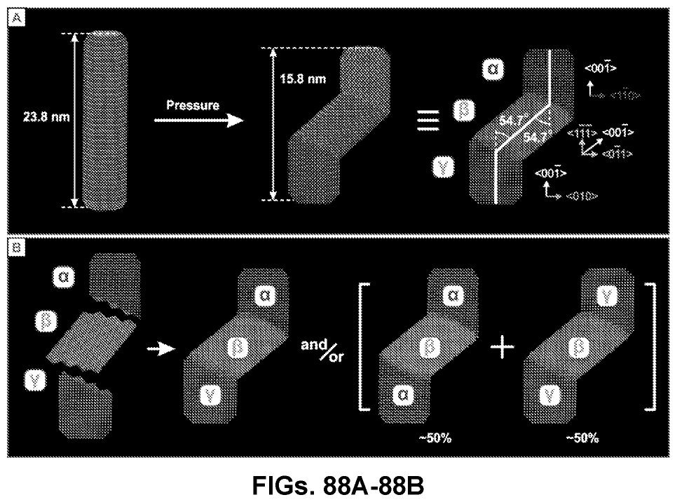

To study nanocrystal-shape effects, atomically aligned nanorod superlattices were prepared at an air/liquid interface using 23.8-nm wurtzite CdSe/CdS nanorods functionalized with octylamine in 95% coverage. These superlattices can be indexed as a simple hexagonal structure with lattice parameters of a=6.72 nm and c=26.2 nm, where the atomic wurtzite lattice of the CdSe/CdS nanorods is coaxially aligned with the superlattice (FIGS. 85A-85C, 69A-69E). With pressure increase, CdSe/CdS nanorods exhibited a WZ-RS phase transition at a pressure range slightly lower than that of those 4.8-nm nanospheres. When decompressed from a pressure above ˜10.0 GPa, the rock-salt phase was fully preserved at ambient conditions (FIG. 85A). In this process, the hexagonal superlattice structure was largely retained but was accompanied by a significant d-spacing decrease in the c-axis direction, adopting a new set of lattice parameters of a=6.97 nm and c=17.5 nm (FIGS. 69F-69G, 85A). As indicated by the dot-like electron diffraction (ED) patterns, the three-dimensionally (3D) ordered atomic alignments of CdSe/CdS nanorods well persisted in the rock-salt phase in the superlattices (FIGS. 69H-69I). Altogether, the experimental data suggest that in this process, wurtzite CdSe/CdS nanorods transformed into double-bend rock-salt nanorods with three domains, exhibiting a height of ˜15.8 nm and an angle of 54.7o between neighboring domains (FIGS. 69F-69J, 86A-88B). This shape change involves a shearing motion of the (0001) wurtzite crystal planes, which is consistent with the direction-dependent nucleation model in the WZ-to-RS transition proposed by Alivisatos and co-workers.

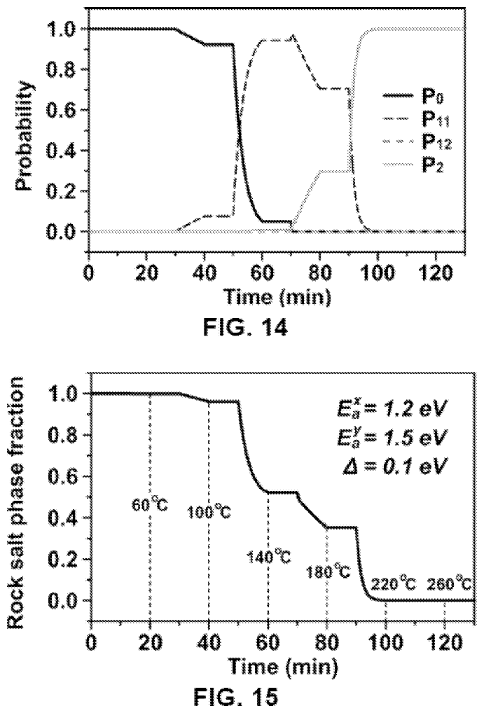

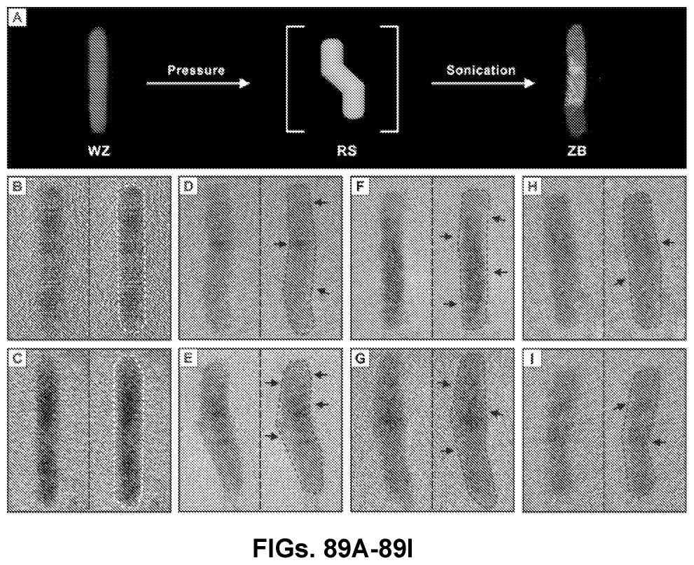

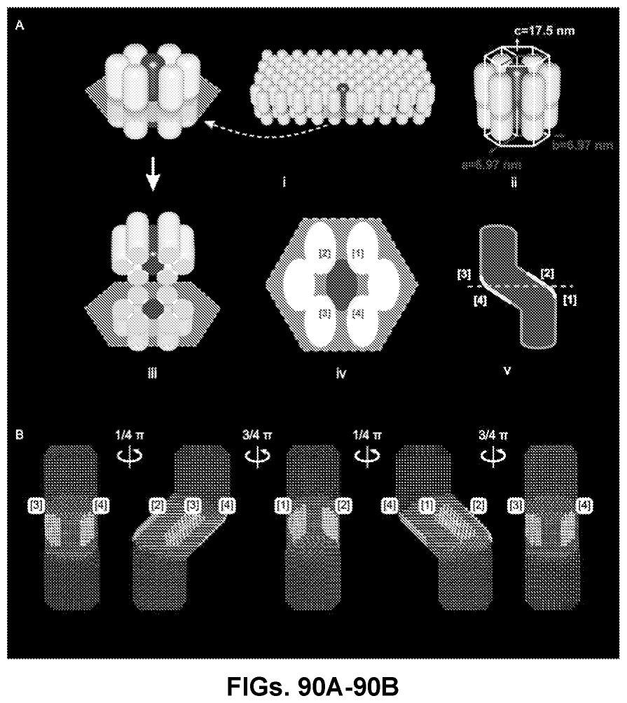

The formation of three-domain nanorods is also consistent with TEM observations of the zinc-blende nanorods recovered from rock-salt aggregates (FIGS. 78K-78L). The recovered nanorods, having sizes similar to those of the nanorods before compression, exhibit obvious traces of shape deformation and comprise multiple crystalline domains and curved lattice fringes due to strain (FIGS. 89A-89I). Based on all structural data, a reconstructed superlattice model shows that each double-bend nanorod atomically overlaps with four neighbors at the corresponding rectangular areas on the surface of their β-domains, suggesting the existence of interparticle sintering, which would be responsible for the metastability of the rock-salt phase (FIGS. 69K, 90A-90B). Indeed, in the assemblies of CdSe/CdS nanorods functionalized with excess of strong-binding ODT ligands, the RS-ZB phase transition became fully reversible, and no detectable rock-salt phase was observed when decompressed even from 12.5 GPa (FIGS. 14J, 85D).

Additional information regarding interparticle sintering was obtained from electric conductivity measurements. Films, composed of either wurtzite structures recovered before the WZ-RS transition or zinc-blende structures that transformed from the rock-salt phase, were insulating below the detection limit (<10 pS), whereas the films of rock-salt structures exhibited conductivities at least eight orders of magnitude higher—in a range of 3.0-8.0 mS (FIGS. 70A-70C). These results, together with TEM observations (FIGS. 78A=78L) provide unambiguous evidence that ambient metastable rock-salt phase exists in the form of 3D interconnected and partially fused nanocrystal networks due to interparticle sintering (FIGS. 70C-70D). This further suggests that the observed ligand-tailorable reversibility of their RS-to-ZB phase transition is a direct result of the ligand effects on the interparticle sintering process, in which surface-ligand rearrangement is the initial step for surface-atom diffusion and chemical-bond formation.

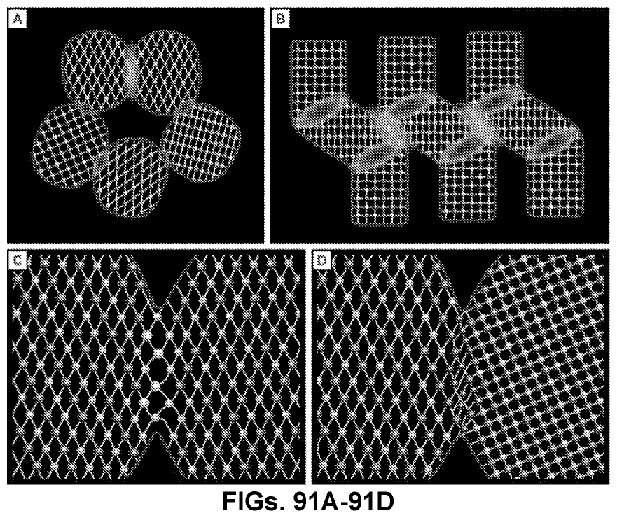

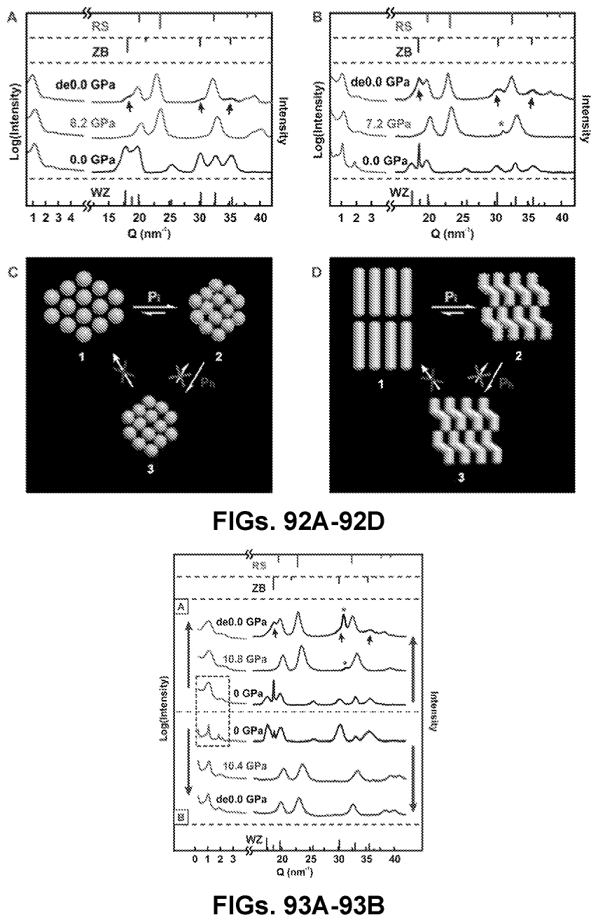

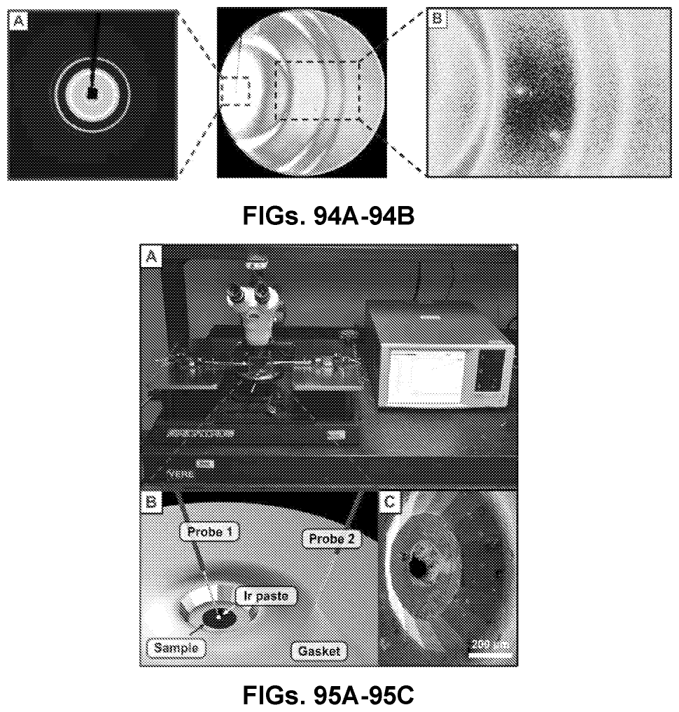

Based on these results, it is proposed that interparticle sintering is a major mechanism that eliminates crystal defects and relaxes lattice distortions from high-pressure rock-salt structures, and thus restores the intrinsic kinetic barrier in ideal crystals to some extent (as predicted by MYK) and leads to observations of ambient metastable nanostructures (FIGS. 70D-70E). It is known that the rock-salt nanocrystals formed from pressure-induced solid-phase transition comprise a large quantity of high-energy crystal defects and lattice distortions, serving as nucleation sites which are responsible for the rapid RS-to-ZB/WZ transitions observed in the systems with no or low-degrees of interparticle sintering (FIGS. 78B, 78F, 78J). In high-pressure/deviatoric-stress induced interparticle sintering, solid-state chemical reactions-driven by the minimization of Gibbs free energy-take place between surface atoms, forming effective sinks to absorb local high-energy defects and lattice distortions. These reactions, producing grain/twin boundaries (GTBs) between neighboring particles (FIGS. 91A-91B) and then forming 3D interconnected nanocrystal networks, in which crystal defects can be delocalized via stress-driven diffusion or propagation. This allows for delocalized and collective GTB/defect interactions within an interconnected network where GTBs act as sources and/or sinks to eliminate crystal defects via absorption and annihilation (note that GTBs also exist within one double-bend nanorod, FIG. 91B)). Moreover, GTBs can further act as obstacles to block/jam dislocation motions and stabilize/harden interconnected nanocrystal networks, providing additional mechanisms to raise activation barrier for the RS-to-ZB transformation. These defect-elimination/strain-relaxation mechanisms depends on the hydrostatic/deviatoric stress applied on the system, which is in consistent with experimental findings that the activation-barrier height in resulting rock-salt structures strongly depends upon the highest applied pressure, indicated by the observed partial reversibility of the RS-ZB transition in samples decompressed from lower pressures (FIGS. 81A-81B, 85A-85D, 92A-92D). These results further suggest that there exists a critical pressure for a given nanocrystal system, above which the resulting interconnected nanocrystal networks can fully retain the rock-salt phase at ambient conditions.

This interparticle sintering (or partial fusion) mechanism is in a good agreement with the entire set of experimental observations as well as the MYK predictions. Without pressure media, the formation of 3D-interconnected nanocrystal networks strongly interplays with an emergent phenomenon called force chain networks, which are created by interparticle interactions and by the topological patterns of pressure applied within the system. Therefore, the order of nanocrystal assemblies affects the degree of interparticle sintering as well as the mechanical integrity and strain uniformity of the resulting interconnected networks (FIGS. 67C, 68C, 76). In disordered systems, nanocrystal shape anisotropy promotes the formation of anisotropic force-chain-network architectures, yielding strained-nanocrystal networks and thus imposing additional effects on the ambient metastability of high-pressure phase. Indeed, the rock-salt phase was fully preserved in the aggregates of totally disordered CdSe/CdS nanospheres (FIG. 82A), but only 77.8% retained in low-level ordered hexagonal superlattices of CdSe/CdS nanorods (FIGS. 93A-93B). In addition, the observed composition dependence in ligand-tailorable reversibility of RS-to-ZB phase transition likely originate from the differences in their chemical and mechanical properties regarding interparticle-sintering reactions, the formation, elimination, propagation and annihilation of crystal defects and relaxation of lattice distortions in the interconnected nanocrystal systems.

To date, some metastable rock-salt CdSe, CdS and CdSe/CdS samples have been fully preserved under ambient conditions for more than six years. This extended lifetime is associated with an apparent activation-energy barrier of more than 1.3 eV/particle in the RS-to-ZB transformation reactions. The strategy for engineering transformation barriers established in this work is readily generalizable for making ambient metastable high-energy phases of other materials such as IV-VI and III-V semiconductors and transition-metal chalcogenides. These findings further show that interconnected nanocrystal networks are a class of “ideal” material systems that can host metastable high-energy phase at ambient conditions. It allows for rational design of synthesis methods for metastable materials via low-pressure routes, offering new design opportunities for next-generation materials.

### Example 2: Materials and Methods

### Synthesis Methods

### Chemicals

Cadmium acetate dihydrate (98%), selenium dioxide (SeO₂, 99.9+%), sulfur powder (99.999%), selenium powder (Se, 99.99%), oleic acid (OA, 90%), 1-octadecene (ODE, 90%), tributylphosphine (TBP, 97%), trioctylphosphine (TOP, 90%), trioctylphosphine oxide (TOPO, 99%), butylamine (99.5%), octylamine (OcAm, 99%), oleylamine (OAm, 70%), cetyltrimethylammonium bromide (CTAB, 99%), 2,2′-dithiobisbenzothiazole (99%), hexadecylphosphonic acid (HPA, 97%) and methanol (98%, anhydrous) were purchased from Sigma-Aldrich. Cadmium nitrate tetrahydrate (Cd(NO₃)₂·4H₂O, 99.99%), stearic acid (98%), myristic acid (99%), and octadecylphosphonic acid (ODPA) were purchased from Alfa Aesar. Sodium hydroxide (NaOH), and all the other solvents were purchased from Fisher Scientific International, Inc. All these chemicals were used without further purification.

### Cadmium Myristate Precursor Synthesis

Cadmium myristate precursor was synthesized as follows: 600 mg NaOH and 3.43 g MA were dissolved with 500 mL methanol in a 1-L flask. 1.542 g Cd(NO₃)₂·4H₂O was dissolved in 50 mL methanol and transferred into a dropping funnel. The cadmium nitrate solution was slowly added dropwise into the sodium myristate solution over 30 min. During this process, cadmium myristate formed as white precipitates. Stirring was continued for additional 30 min after cadmium nitrate solution was completely dropped into the sodium myristate solution. The precipitates were separated by filtration, then washed by methanol for three times, and finally dried under vacuum overnight.

### CdS Shell Growth Precursor Synthesis

Cadmium oleate-octanethiol precursor (CdOA-OCT) was prepared as follows: 513.6 mg CdO was added to a mixture of 10 mL OA and 40 mL ODE in a three-neck flask. The mixture was degassed under vacuum for 30 min at room temperature before being heated to 240° C. under Ar flow and kept for 2 h. The mixture was then cooled to 80° C. and degassed under vacuum for 30 min. 0.832 mL octanethiol was injected into the flask and the solution was heated to 100° C. under Ar flow forming a colorless solution. The CdOA-OCT precursor was kept under inert gas and used without further treatment.

### Spherical 8.2 nm PbS Nanocrystals in Rock-Salt Phase

8.2-nm PbS spherical nanocrystals in rock-salt phase were synthesized as follows: A solution of S-precursor was prepared in a glove box by dissolving 1.0 mL TMS₂S in 5 mL ODE. 379 mg Pb(Ac)₂ 3H₂O was added in a three-neck flask containing 9.00 mL OA and 1.00 mL ODE. The solution was degassed under vacuum at 110° C. for 30 min. The temperature was then raised to 145° C. under Ar flow before an injection of 0.63 mL S-precursor. The heating mantle was removed after 3 min, and 5.00 mL toluene was injected to quench the reaction. The synthesized PbS nanocrystals were washed with ethanol and toluene for three times and kept in toluene for further usage. The final size was confirmed by TEM.

### Spherical 8.2 nm PbSe Nanocrystals in Rock-Salt Phase

8.2-nm PbSe nanocrystals were synthesized as follows: Pb(Ac)₂·3H₂O (240 mg, 0.788 mmol) was dissolved in squalane (5.00 mL) in the presence of OA (0.82 mL, 2.55 mmol). The resulting solution was degassed at 80° C. for 1 hour, and then heated up to 170° C. A TOP solution of tri-n-octylphosphine selenide (2 mL, 1 M) was injected into the solution. After the injection, the solution was cooled to 145° C., and the temperature was maintained until the nanoparticles reached a desirable size. The reaction solution was cooled to room temperature and the resulting nanoparticles were isolated from the solution by adding ethanol in a glove box and kept in toluene for further usage. The final size was confirmed by TEM.

### Spherical 8.0 nm PbTe Nanocrystals in Zinc-Blende Phase

Lead oleate (Pb(OA)₂) precursor was synthesized by dissolving 5.00 g of PbO in 10.0 mL acetonitrile with 0.35 mL trifluoroacetic acid and 3.20 mL trifluoracetic acid anhydride, then mixed with 14.2 mL oleic acid dissolved in 90.0 mL isopropanol. The mixture was heated and refluxed for 1 h, yielding a clear solution. Then the solution was cooled to room temperature at 1° C./min, and further freeze at −20° C. for 3 h. During the freezing process, white precipitation of Pb(OA)₂ was formed. The product was washed with methanol for three times, then dried under vacuum for overnight.

For PbTe nanoparticles synthesis, 1.00 mmol Pb(OA)₂, 1.50 mL oleic acid, and 4.00 mL diphenyl ether was loaded in a 3-neck flask. The mixture was vacuumed at room temperature for 3 times and heated to 220° C. After the temperature reached 220° C., 1.00 mL of 1.00 M TOP-Te was injected into the flask. The reaction was quenched 6 min after the injection and was cooled to room temperature. The resulting nanoparticles were isolated from the solution by adding ethanol in a glove box and kept in toluene for further usage. The final size was confirmed by TEM.

### Spherical 4.8 nm InP Nanocrystals in Zinc-Blende Phase

1.2 g InCl₃, and 10 mL TOP were loaded into a three-neck flask in a glove box and then connected to a Schlenk line. The system was vacuumed three times and then heated to 230° C. under Ar flow to obtain a clear solution. This In-TOP solution was cooled to room temperature and stored under inert gas for further usage. 930 mg TMS3P was dissolved in 7.8 mL TOP in a glove box forming a clear P-TOP solution. In a separate three-neck flask connected to a Schlenk line, 6 mL TOP was degassed under vacuum for three times before being heated to 280° C. under Ar flow, and a mixture solution of 0.5 mL In-TOP and 0.5 mL P-TOP was swiftly injected. The reaction was kept at 260° C. for 8 min before secondary injection of 0.5 mL In-TOP/P-TOP solution at 1.2:1 molar ratio. The reaction was monitored by UV-Vis spectroscopy and stopped by removing the heating mantle when the nanocrystals reached the desired size. The resulting InP nanocrystals were precipitated by adding ethanol, and then redispersed in hexane. The nanocrystals were further purified by precipitation-redispersion for two times. The purified nanocrystals were dispersed in toluene and stored under inert gas for further usage.

### 35 nm MnS Nanocrystals in Rock-Salt Phase

5-nm MnS nanocrystals were synthesized as follows: 34.6 mg Mn(Ac)₂, 1.0 mL OA, and 5.0 mL ODE were loaded into a three-neck flask. The solution was degassed under vacuum at 110° C. for 60 min before being heated up to 250° C. under Ar flow. Sulfur precursor containing 0.18 mL TMS₂S and 5.0 mL TOP was injected and the reaction was kept at 250° C. for 40 min before quenching by removing heating mantle. The synthesized MnS nanocrystals were purified with ethanol and toluene twice and kept in toluene for further usage. The final size was confirmed by TEM.

Spherical CdSe Nanocrystals with Wurtzite Structure

4.8-nm CdSe nanocrystals with a wurtzite crystal structure were synthesized based on a modified literature method: in a typical synthesis, cadmium oxide (76.8 mg, 0.600 mmol), decanoic acid (900 mg, 5.23 mmol), and ODE (9.00 g) were loaded in a three-neck flask and degassed under vacuum at room temperature. The solution was then heated to 240° C. under Ar flow for 1 hour, resulting in a clear, colorless solution. After cooling down to room temperature, TOPO (6.00 g, 15.5 mmol) and octadecylamine (6.00 g, 22.3 mmol) were added to the flask and degassed under vacuum at 100° C. for 1 hour. Then, the solution was heated to 290° C. when a TBP-Se/ODE solution was injected (Se: 360 mg, 4.56 mmol, TBP: 1.80 g, 7.19 mmol, ODE: 1.80 g, 7.13 mmol). After the injection, the reaction temperature dropped to 260° C., and was kept at 260° C. during the particle growth. The reaction was monitored by UV-Vis spectroscopy and was stopped by removing the heating mantle when the nanocrystals reached the desired size. The resulting nanocrystals were precipitated by adding acetone, and then redispersed in hexane. The nanocrystals were further purified by precipitation-redispersion three more times. The purified nanocrystals were dispersed in toluene for further usage.

Spherical CdSe Nanocrystals with Zinc-Blende Structure

4.8-nm CdSe nanocrystals with a zinc-blende crystal structure were prepared according to a modified literature method. In general, SeO₂ (11.0 mg, 0.100 mmol), cadmium myristate (56.7 mg, 0.100 mmol), and ODE (5.00 g) were loaded into a three-neck flask. The mixture was degassed under vacuum for 10 min at room temperature. Then the solution was heated to 240° C. at a rate of 25° C./min under Ar flow. The time was counted as zero when the temperature reached 240° C. After 2 minutes of growth, 1 mL of OA was added dropwise into the reaction solution to stabilize the growth of the nanocrystals. The reaction was monitored by UV-Vis spectroscopy and stopped by removing the heating mantle when the nanocrystals reached the desired size. The resulting nanocrystals were precipitated by adding acetone, and redispersed in hexane. The nanocrystals were further purified by precipitation-redispersion three more times. The purified nanocrystals were dispersed in toluene for further usage.

### Spherical 4.8 nm CdS Nanocrystals in Zinc-Blende Phase

4.8-nm CdS nanocrystals were synthesized as follows: 113.4 mg cadmium myristate, 9.0 mg Cd(Ac)₂ 2H₂O, 3.2 mg S, 5.0 mg 2,2′-dithiobisbenzothiazole, and 10 g ODE were loaded into a three-neck flask. The mixture was degassed for 10 min at room temperature. Under Ar flow, the solution was stirred and heated to 240° C. at a rate of 25° C./min. After 20 min, S-ODE solution (0.1 M) was dropped into the reaction flask at a rate of 40 μL/min. The reaction was monitored by UV-Vis spectroscopy and stopped by removing the heating mantle when the nanocrystals reached the desired size. The resulting particles were precipitated by adding acetone, and then redispersed in hexane. The particles were further purified by precipitation-redispersion three more times. The purified nanocrystals were dispersed in toluene for further usage.

### Spherical 8.0 nm CdS Nanocrystals in Wurtzite Phase

8.0-nm wurtzite CdS nanocrytals were synthesized by a core-shell growth approach as follows. A hexane solution containing 100 nmol of 4.8-nm CdS nanocrystals was loaded into a three-neck flask containing 3 mL ODE and 3 mL OlAm. The reaction solution was degassed under vacuum at room temperature for 1 hour and at 120° C. for 20 min before being heated up to 310° C. with a heating rate of 15° C./min under Ar flow. When the temperature of reaction solution reached 240° C., a desired amount of CdOA-OCT precursor was added dropwise into the growth solution using a syringe pump at 40 μL/min accompanied by the infusion of OAm at 20 μL/min. After precursor infusion, the reaction solution was allowed to cool to room temperature. The resulting CdS nanocrystals were precipitated by adding acetone, and then redispersed in hexane. The nanocrystals were further purified by precipitation-redispersion for three more times. The purified nanocrystals were dispersed in toluene for further usage.

### Synthesis of CdS Nanocrystals up to 190 nm

CdS nanocrystals up to 190 nm were synthesized by a multiple-step core-shell growth method. In each shell growth step, a toluene solution containing the desired amount of CdS nanocrystals was loaded into a three-neck flask containing 3 mL ODE and 3 ml OAm. The reaction solution was degassed under vacuum at room temperature for 1 hour and at 120° C. for 20 min before being heated up to 310° C. with a heating rate of 15° C./min under Ar flow. When the temperature of reaction solution reached 240° C., a desired amount of CdOA-OCT precursor was added dropwise into the growth solution using a syringe pump at 40 μL/min accompanied by the infusion of OAm at 20 μL/min. After precursor infusion, the reaction solution was allowed to cool to room temperature. The resulting CdS nanocrystals were precipitated by centrifuge, and then redispersed in hexane. The nanocrystals were further purified by precipitation-redispersion for three more times. The purified nanocrystals were dispersed in toluene for further characterization, or as the core-crystal for core-shell growth. The sizes of synthesized CdS nanocrystals were confirmed by TEM.

### Spherical 4.8 nm and 8.0 nm CdSe CdS Core Shell Nanocrystals in Wurtzite Phase

4.8-nm and 8.0-nm wurtzite CdSe/CdS nanocrytals was synthesized by a core-shell growth approach as follows: A hexane solution containing 100 nmol of 4.8-nm CdS nanocrystals was loaded in a three-neck flask containing 3 mL ODE and 3 ml OAm. The reaction solution was degassed under vacuum at room temperature for 1 hour and at 120° C. for 20 min before being heated to 310° C. with a heating rate of 15° C./min under Ar flow. When the temperature of reaction solution reached 240° C., a desired amount of CdOA-OCT precursor was added dropwise into the growth solution using a syringe pump at 40 μL/min accompanied by the infusion of OAm at 20 μL/min. After precursor infusion, the reaction solution was allowed to cool to room temperature. The resulting CdS nanocrystals were precipitated by adding acetone, and then redispersed in hexane. The nanocrystals were further purified by precipitation-redispersion for three more times. The purified nanocrystals were dispersed in toluene for further usage.

### 23.8 nm CdSe CdS Core Shell Nanorods in Wurtzite Phase

23.8-nm CdSe/CdS nanorods were synthesis via a seeding growth method as follows: In a typical synthesis, CdSe nanocrystal seeds were synthesized as follows: 3.0 g TOPO, 280 mg ODPA, and 60 mg CdO were mixed in a three-neck flask and degassed under vacuum for 1 hour at 150° C. The resulting solution was heated to 300° C. and 1.5 g TOP was added. The solution was heated to 350-370° C. and 0.43 mL of 1.7 M TOP-selenide solution was injected into the solution. The heating mantle was removed immediately after the injection, and then the solution was cooled to room temperature. Resulting nanocrystals were purified through three cycles of precipitation and redispersion using methanol and toluene, respectively. Then the CdSe nanocrystal seeds were dissolved in TOP and the concentration was adjusted to 400 μM.

CdSe/CdS nanorods were synthesized as follows: 60 mg CdO, 3.0 g TOPO, 190 mg ODPA, and 80 mg HPA were mixed and degassed under vacuum for 1 hour at 150° C. The solution was then heated to 380° C. under argon, and 1.5 g TOP was added. After the temperature recovered to 380° C., a TOP solution with sulfur and CdSe nanocrystal seeds (120 mg of sulfur and 80.0 nmol of CdSe nanocrystal seeds in 1.9 mL TOP) was injected into the solution. The reaction was maintained at 350° C. for the growth of CdSe/CdS nanorods for 8 min, and then cooled to room temperature. The resulting CdSe/CdS nanorods were isolated from the reaction solution using ethanol. The nanocrystals were further purified by precipitation-redispersion using hexane and acetone for two times and redispersed in toluene. The purified nanocrystals were dispersed in toluene for further usage, and the size and shape were confirmed by TEM.

### 24.5 nm CdS Nanorods in Wurtzite Phase

4.5-nm CdS nanorods were synthesized via a seeding growth method identical to the CdSe/CdS core/shell nanorods but using a wurtzite CdS seed. Wurtzite CdS seed was synthesized as follows: 100 mg CdO, 600 mg ODPA, and 3.2 g TOPO was loaded into a three-neck flask and degassed under vacuum at 150° C. for 1 h. The mixture was heated to 320° C. to dissolve CdO which resulted in a colorless solution. TMS2S/TBP solution (0.2 mL TMS2S in 3.7 mL TBP) was injected into the flask, and the reaction was kept at 250° C. for 7 min. The reaction was then quenched by removing heating mantle, and the resulting nanocrystals were purified by a precipitation/redispersion cycle using methanol and toluene for three times and redispersed in toluene as seed for CdS nanorods synthesis.

Spherical CdSe CdS Core Shell Nanocrystals with Zinc-Blende Structure

4.8-nm CdSe/CdS core/shell nanocrystals with zinc-blende structure were synthesized with a similar protocol as wurtzite CdSe/CdS core/shell nanospheres. Typical synthesis started with preparing 3.4 nm core CdSe nanocrystals with a zinc-blende structure: SeO₂ (11.0 mg, 0.1 mmol), cadmium myristate (56.7 mg, 0.1 mmol), and ODE (5.0 g) were loaded into a three-neck flask. The mixture was degassed under vacuum for 10 min at room temperature. Then the solution was stirred and heated to 240° C. at a rate of 25° C./min under Ar flow. After two minutes of growth, 1 mL of OA was added dropwise into the reaction solution to stabilize the growth of the nanocrystals. The reaction was monitored by UV-Vis spectroscopy and stopped by removing the heating mantle when the nanocrystals reached the desired size. Shell growth was done in a similar method as for synthesizing wurtzite CdSe/CdS core/shell nanocrystals. The resulting CdSe/CdS core/shell nanocrystals were precipitated by adding acetone, and then redispersed in hexane. The nanocrystals were further purified by precipitation-redispersion for two more rounds and finally suspended in toluene. The final size and shape were confirmed by TEM.

Spherical CdS CdSe Core Shell Nanocrystals with Wurtzite Structure

Typical synthesis started with preparing core CdS nanocrystals with a diameter of 3.4 nm. Cadmium myristate (113 mg, 0.200 mmol), sulfur powder (3.2 mg, 0.10 mmol), and ODE (10.0 g) were loaded into a three-neck flask. The mixture was degassed for 10 min at room temperature. Under Ar flow, the solution was stirred and heated to 240° C. at a rate of 25° C./min. The reaction was monitored by UV-Vis spectroscopy and stopped by removing the heating mantle when the nanocrystals reached the desired size. The resulting nanocrystals were precipitated by adding acetone, and then re-dispersed in hexane. The nanocrystals were further purified by precipitation-redispersion three more times. The purified CdS nanocrystals were dispersed in hexane for further usage.

For the shell growth reaction, a hexane solution containing 100 nmol of CdS nanocrystals was loaded into a three-neck flask containing ODE (3.00 mL) and OAm (3.00 mL). The reaction solution was degassed under vacuum at room temperature for 1 hour and at 120° C. for 20 min to completely remove the hexane, water, and oxygen in the reaction solution. After that, the reaction solution was heated up to 240° C. with a heating rate of 18° C./min under Ar flow. After the temperature reached 240° C., a desired amount of cadmium (II) oleate (Cd-oleate, diluted to 40 mM in ODE) and TOP-Se (diluted to 40 mM in TOP) was added dropwise into the growth solution. The reaction was monitored by UV-Vis spectroscopy and stopped by removing the heating mantle when the nanocrystals reached the desired size. The resulting CdS/CdSe core/shell nanocrystals were precipitated by adding acetone, and then redispersed in hexane. The nanocrystals were further purified by precipitation-redispersion three more times. The purified nanocrystals were dispersed in toluene for further usage.

Cdse CdS Core Shell Nanorods with Wurtzite Structure

CdSe/CdS nanorods were prepared via a seeded growth method according to a literature protocol. In a typical synthesis, CdSe nanocrystal seeds were synthesized as follows: TOPO (3.00 g), ODPA (280 mg), and CdO (60.0 mg) were mixed in a three-neck flask and degassed under vacuum for 1 hour at 150° C. The resulting solution was heated to 300° C. and TOP (1.50 g) was added. The solution was heated to 350-370° C. and a TOP solution of tri-n-octylphosphine selenide (0.43 mL, 1.70 M Se concentration) was injected into the solution. The heating mantle was removed immediately after the injection, and then the solution was cooled to room temperature. Resulting nanocrystals were purified through three cycles of precipitation and redispersion using methanol and toluene, respectively. Then the CdSe nanocrystal seeds were dissolved in TOP and the concentration was adjusted to 400 M.

CdSe/CdS nanorods were synthesized as follows: CdO (60.0 mg), TOPO (3.00 g), ODPA (190 mg), and HPA (80.0 mg) were mixed and degassed under vacuum for 1 hour at 150° C. The solution was then heated to 350-380° C. under argon, and TOP (1.50 g) was added. After reaching a desired temperature, a TOP solution with sulfur and CdSe nanocrystal seeds (1.90 mL, 120 mg of sulfur, and 80.0 nmol of CdSe nanocrystal seeds) was injected into the solution. The reaction temperature was maintained at growth temperature for the growth of CdSe/CdS nanorods, and then the reaction solution was cooled to room temperature. The resulting CdSe/CdS nanorods were isolated from the reaction solution using ethanol. The nanocrystals were further purified by precipitation-redispersion using hexane and acetone for an additional two rounds and finally suspended in toluene. The final size and shape were confirmed by TEM.

### Organic Ligand Surface Functionalization

Nanocrystals surface functionalization was achieved via ligand exchange. The ligands used in this study are butylamine, OcAm, OAm, pyridine, ODT, and a mixture of amine with CTAB. Different ligand coverages were achieved as follows:

Ligand functionalization involves two steps: the first step is ligand exchange. The as-synthesized nanocrystals were washed for seven times via precipitation/redispersion using toluene/acetone as good/bad solvent, to remove as much original surface ligand as possible. The purified nanocrystals were dispersed in toluene containing the desired surface ligand molecules (2% w/w). The solution was heated under Ar to 80° C. and kept for 15 min. The process was repeated twice to ensure that the surface was fully covered by desired ligand molecules.

The second step is to control ligand density. Nanocrystals from the ligand exchange step were washed seven times using methanol and toluene. Then the nanocrystals were dispersed in toluene, and a desired amount of ligand molecules were added into the solution. The solution was kept under room temperature for at least three hours before further analysis. The ligand coverage percentage was confirmed by thermogravimetric analysis (TGA).

Amine ligand functionalization involves two steps: the first step is ligand exchange. The as-synthesized nanocrystals were washed for seven times via precipitation/redispersion using toluene/acetone as good/bad solvent, to remove as much original surface ligand as possible. The purified nanocrystals were dispersed in toluene containing the desired surface ligand molecules (2% w/w). The solution was heated under Ar to 80° C. and kept for 15 min. The process was repeated twice to ensure the surface was fully covered by desired ligand molecules.

The second step is to control ligand density. Nanocrystals from the ligand exchange step were washed seven times using methanol and toluene. Then the nanocrystals were dispersed in toluene, and a desired amount of ligand molecules were added into the solution. The solution was kept under room temperature for at least three hours before further analysis. The ligand coverage percentage was confirmed by TGA.

For ODT functionalization, the nanocrystals were washed seven times via precipitation/redispersion before being loaded into a flask. After evaporating the solvent, 10.0 mL of 10.0 mM octadecanethiol-toluene solution was added. After three times of a “freeze-pump-thaw” method to remove oxygen in the system, the solution was heated up to 100° C. and kept for 30 min. The solution was then cooled down and the nanocrystals were collected by centrifugation after ethanol addition. The nanocrystals were dispersed and stored in toluene for further use. An excess amount of ODT was added as experimentally required.

For pyridine functionalization, the nanocrystals were washed seven times via precipitation/redispersion before being loaded into a vial. Pyridine was added as solvent, and the mixture was sonicated at room temperature for one hour to achieve a clear solution. The nanocrystals were separated by adding hexanes before centrifuging. The resulting nanocrystals were redispersed in pyridine for further analysis.

### Inorganic Ligand Synthesis and Nanocrystal Surface Functionalization

Inorganic ligand used in this study, (N₂H₅)₄Sn₂S₆, were as follows (N₂H₅)₄Sn₂S₆ was synthesized as follows: 1.00 M S—N₂H₄ stock solution was prepared by dissolving S powder (3.00 mmol, 96.0 mg) in 4.00 mL N₂H₄ at room temperature to achieve a clear solution. Then, Sn powder (1.00 mmol, 118.7 mg) was added to the S—N₂H₄ solution and kept at 130° C. for 3 days under Ar flow forming a clear light-yellow solution. The solution was stored under inert gas and used without further treatment.

Nanocrystal surface functionalization by inorganic ligands were conducted as follows: This process was carried out in a glove box under inert gas atmosphere with anhydrous solvents. 2.00 mg nanocrystals in hexane solution (10 mg/mL) was mixed with a 2.00 mL N₂H₄ with 20 μL (N₂H₅)₄Sn₂S₆ solution. The mixture was stirred at room temperature for 4 h, until the organic phase turned colorless and the N₂H₄ phase turned colored. The organic phase was carefully removed, and the hydrazine phase was further purified by hexane for three times. The N₂H₄ phase was filtered through a 200-nm PTFE filter to remove any insoluble particles. Then, 1.00 mL of anhydrous acetonitrile was added to the nanocrystal solution, and nanocrystals were collected by centrifuge and then redispersed in N2H4 to form a clear solution for further usage.

### Superlattices Synthesis on Air/Liquid Interface

In a typical synthesis, toluene solution of the ligand functionalized nanocrystals (5 mg/mL, 2 mL) was carefully dropped in a glass vial with 1 mL of di-ethylene glycol. The vial was covered with a glass slide, and the solution was allowed to sit under room temperature for 24 hours until toluene layer was complete evaporated. The resulting nanocrystal superlattices was collected, then washed carefully with methanol for 3 times and dried under Ar flow. The purified superlattices were stored under Ar for further analysis.

### Characterization Methods

UV-VIS: Absorption spectra were collected on a Shimadzu UV-1800 UV-Vis Spectrometer operating from 1100 nm to 200 nm with a 1.00 cm optical path length quartz cuvette.

Fluorescence: Fluorescence spectra were collected on a Fluorolog-3, Horiba Jobin Yvon fluorometer with a quartz cuvette.

In-Situ High-Pressure X-Ray Diffraction: The high-pressure diamond anvil cell (DAC) used in this research was developed at Cornell High Energy Synchrotron Source (CHESS) and the instrumentation was reported in literature. Here, a brief explanation on this setting was described below.

A 200 m hole was drilled on a stainless-steel gasket and the gasket was used as the sample chamber. Samples (˜1 mg) were loaded into the hole and several ruby chips were placed on top of the sample for monitoring the pressure. Afterwards, the samples were sandwiched between two diamond anvils as shown below. In this work, we did not use any pressure medium unless otherwise mentioned.

Synchrotron SAXS and WAXS measurements were performed at the B1 station in CHESS. Two-dimensional X-ray scattering patterns were measured with a large area MAR345 detector. The distances between the sample and the detector were calibrated by CeO2 and behenate for WAXS and SAXS, respectively. White synchrotron X-rays were tuned to a monochromatic wavelength using a double-crystal monochromator (Ge 111 plane) and the diameter of the X-ray beam was reduced to 100 m using a double-pinhole collimator tube for the illumination of the samples. A typical X-ray scattering pattern was shown in FIG., and the Fit2D program (www.esrfeu/computing/scientific/FIT2D) was used to integrate a collected circular pattern into a one-dimensional X-ray scattering spectrum. Baseline subtraction of diffraction patterns were performed on Origin 8.5 according to the background exposures.

TEM: TEM imaging and electron diffraction (ED) pattern were collected on a JEOL 200CX TEM or a Thermo Scientific Talos F200i S/TEM. Both systems were operated at 200 kV.

SEM: SEM measurements were performed on a Hitachi S-4000 Field-Emission SEM operated at 6 kV.

### Stepwise Thermo-Induced Phase Transformation

The steel gasket containing rock-salt sample was removed from the DAC and placed in a glass petri dish, and the petri dish was placed in a Thermo Fisher Precision™ 605 oven pre-heated to the designated temperature. In this study, the treatment time for each step was 10 min, after which point the petri dish was removed from the oven and cooled to room temperature. The steel gasket was then mounted on a sample holder for synchrotron SAXS and WAXS measurement. The RS-to-ZB phase transformation was monitored by synchrotron, and the stepwise heating treatment was repeated at different temperatures until the phase transformation was complete.

### Electron Beam Damage

Electron beam damage to rock salt samples were studied with a JEOL 200CX TEM. Electron density of TEM beam was carefully adjusted by controlling the beam diameter illuminated on the sample. When collecting TEM images, the electron beam was spread to a ˜1 μm diameter circle to reduce electron beam density. To introduce beam damage, the beam size was reduced to ˜200 nm to achieve a high-density electron beam.

### Electrical Conductivity

Conductivity measurements (I-V measurements) were carried out using a Keithley 4200 Parameter Analyzer with a two-probe setup (FIG. 95A). Nanocrystal assemblies were molded as films in a DAC upon decompression from different pressures, resulting in a sample film attached in the hole of the gasket. We used iridium paste as contacting glue to ensure Ohmic contact between the probe and the sample (FIG. 95B). On the other side of the sample, iridium paste was also applied to ensure Ohmic contact between the sample and gasket. The other probe was directly put on the gasket to measure the overall conductivity of the sample (FIG. 95B).

### Thermogravimetric Analysis (TGA)

TGA measurements were performed on a Mettler Toledo Thermogravimetric Analyzer TGA/DSC 1 equipped with ceramic crucibles operating from room temperature to 800° C.

Composition Analysis from WAXS Patterns

Diffraction intensities can be calculated based on equation 1:

$${I}_{( hkl ) α} = \frac{{I}_{0} {λ}^{3}}{64 π r} {( \frac{{e}^{2}}{{m}_{e} {c}^{2}} )}^{2} \frac{{M}_{( hkl )}}{{V}_{α}^{2}} {\vert {F}_{( hkl ) α} \vert}^{2} {( \frac{1 + {cos}^{2} ( 2 θ ) {cos}^{2} ( 2 {θ}_{m} ) )}{{sin}^{2} θ cos θ} )}_{( hkl )} \frac{{v}_{α}}{{μ}_{s}} \qquad Eq . 1$$

where I₀ is the initial intensity of irradiating X-ray beam, λ is the wavelength of X-ray (0.485946 nm), r is distance from specimen to detector, e²/mₑc² is the classical electron radius, M(hkl) is the multiplicity of reflection hkl of phase α, Vα is the volume of the unit cell of phase α, θm is diffraction angle of the monochromator (diffraction from of Ge(111) plane, of 3.136 Å), μs is the linear absorption coefficient of the specimen, and vα is the amount of phase α. F(hkl)α, the structure factor for reflection of the hkl of phase, is given by the following equation:

$${F}_{( hkl )} = {\sum }_{1}^{N} {f}_{n} {e}^{2 π i ( {hu}_{n} + {kv}_{n} + {lw}_{n} )} \qquad Eq . 2$$

where un vn wn are atomic coordinates, and fn is atomic scattering factors. The term hun+kvn+lwn, is dependent on diffraction planes and atomic coordinates in the crystal unit cell.

In the case of rock-salt crystals with formula of AB, in one unit cell, A is located at (0,0,0), (½, ½, 0), (½, 0, ½), and (0, ½, ½) locations, while B is located at (½, ½, ½), (0, 0, ½), (0, ½, 0), and (½, 0, 0) locations. The structure factor, F(hkl), is deduced from equation (2) and is calculated as below:

$${F}_{( hkl )} = 4 {f}_{A} + {f}_{B} [ {e}^{π i ( h + k + l )} + {e}^{π il} + {e}^{π ik} + {e}^{π ih} ] \qquad Eq . 3$$

Thus, |Fₕₖₗ|², which directly determines the scattering intensity in Eqn. 1, can be developed as:

|Fₕₖₗ|²=16[f_{A}+f_{B}]² when hkl are all even numbers

|Fₕₖₗ|²=16[f_{A}−f_{B}]² when hkl are all odd numbers

In the case of zinc-blende crystals with formula of AB, A is located at (0,0,0), (½, ½, 0), (½, 0, ½), and (0, ½, ½) locations, while B is located at (¼, ¾, ¼), (¾, ¼, ¼), (¼, ¼, ¾), and (¾, ¾, ¾) locations. Again, F₍ₕₖₗ₎ is calculated as below:

$${F}_{( hkl )} = 4 {f}_{A} + 4 {f}_{B} {e}^{\frac{π i}{2} ( h + k + l )} \qquad Eq . 4$$

Thus, |Fₕₖₗ|² is expressed as below,

$${\vert {F}_{hkl} \vert}^{2} = 16 [ {f}_{A}^{2} + {f}_{B}^{2} ] when h + k + l = 2 n - 1 \\ {\vert {F}_{hkl} \vert}^{2} = 1 {6 [ {f}_{A} + {f}_{B} ]}^{2} when h + k + l = 4 n \\ {\vert {F}_{hkl} \vert}^{2} = 1 {6 [ {f}_{A} - {f}_{B} ]}^{2} when h + k + l = 4 n - 2$$

where n∈N. The volume of phase α, vα, can be expressed as equation 5 by a simple derivation from equation 1.

$${v}_{α} = \frac{{I}_{( hkl ) α} {μ}_{s}}{\frac{{I}_{0} {λ}^{3}}{64 π r} {( \frac{{e}^{2}}{{m}_{e} {c}^{2}} )}^{2} \frac{{M}_{( hkl )}}{{V}_{α}^{2}} {\vert {F}_{( hkl ) α} \vert}^{2} {( \frac{1 + {cos}^{2} ( 2 θ ) {cos}^{2} ( 2 {θ}_{m} )}{{sin}^{2} θ cos θ} )}_{( hkl )}} \qquad Eq . 5$$

To calculate the ratio between high-pressure an ow-pressure phases from the mixed WAXS, the diffraction pattern was deconvoluted by peak fitting as shown below, and the peak area corresponding to rock-salt and zinc-blende phase was integrated and used as peak intensity I₍ₕₖₗ₎ in equation 5.

The material molar ratio is determined using strong diffraction peaks (typically (111) peak for zinc-blende phase and (200) peak for rock-salt phase). With all the results from above, the molar ratio of the corresponding unit cell could be calculated using the following equation:

$${ratio}_{\frac{RS}{ZB}} = \frac{{( {v}_{hkl} )}_{RS} \cdot {ρ}_{RS}}{{( {v}_{hkl} )}_{ZB} \cdot {ρ}_{ZB}} \qquad Eq . 6$$

and RS or ZB phase percentage in the sample could be calculated as:

$${pct}_{RS} = \frac{{ratio}_{\frac{RS}{ZB}}}{( {ratio}_{\frac{RS}{ZB}} + 1 )} and {pct}_{ZB} = \frac{1}{( {ratio}_{\frac{RS}{ZB}} + 1 )} \qquad Eq . 7$$

### Calculation of Ligand Coverages on Nanocrystal Surface

The surface ligand coverages were calculated as grafting density (σ, ligands/nm²) according to TGA measurement results. For single-ligand configurations, the grafting density was calculated using the following:

$$σ = \frac{V \cdot {ρ}_{core} ( 1 - wt \% ) \cdot {N}_{A}}{S \cdot M {W}_{ligand}} \qquad Eq . 8$$

where ρ_{core} is the density of inorganic nanocrystals (ρ_{CdS}=4.82 g·cm⁻³, P_{CdSe}=5.17 g·cm⁻³), wt % is the remaining weight fraction, N_{A} is Avogadro's constant, MW_{ligand} is the molar weight for ligand molecules, and the volume and total surface area of nanocrystals is V and S, respectively. In the case of spherical nanocrystals,

$$V = \frac{1}{3} π {d}_{s}^{3} and S = π {d}_{s}^{2} ,$$

in which dₛ is the diameters of spherical nanocrystals; in the case of nanorods,

$$V = \frac{1}{4} π {d}_{r}^{2} \cdot {l}_{r} , and S = π d ( \frac{1}{2} {d}_{r} + {l}_{r} ) ,$$

in which dᵣ and lᵣ are the diameter and length of nanorods.

For dual-ligand configuration, the grafting density of each ligand (σ₁ and σ₂) was calculated using the following set of equations:

$$\frac{S \cdot {σ}_{1} \cdot M {W}_{1}}{V \cdot {ρ}_{core} + S ( {σ}_{1} \cdot M {W}_{1} + {σ}_{2} \cdot M {W}_{2} )} = 1 - {wt}_{1} \% \qquad Eq . 9$$

$$\frac{S \cdot {σ}_{2} \cdot M {W}_{2}}{V \cdot {ρ}_{core} + S ( {σ}_{1} \cdot M {W}_{1} + {σ}_{2} \cdot M {W}_{2} )} = {wt}_{1} \% - {wt}_{2} \% \qquad Eq . 10$$

where wt₁% and wt₂% are the remaining weight fractions after the first and second weight loss. In the case of amine-CTAB dual-ligand configuration, wt₁% was measured at 500° C. for amine ligand decomposition, and wt₂% is the final remaining weight fraction with only inorganic cores remaining.

In this study, a grafting density of σ₀=5 ligands/nm² (or 20 Å/ligand) was arbitrarily assigned as 100% surface ligand coverage. The surface ligand coverage percentages were further calculated as follows:

$$pct \% = σ / {σ}_{0} \times 100 \% \qquad Eq . 11$$

### Calculation of Zone Axes of Double-Bend Nanorods

In a double-bend rock-salt nanorod, the zone axis of segment I, II, and III can be described in 3×1 matrices Z_{I}, Z_{II}, and Z_{III}, for which:

$${Z}_{I} = ( \begin{matrix}{u}_{I} \\ {v}_{I} \\ {w}_{I}\end{matrix} ) \\ {Z}_{II} = ( \begin{matrix}{u}_{II} \\ {v}_{II} \\ {w}_{II}\end{matrix} ) \\ {Z}_{III} = ( \begin{matrix}{u}_{III} \\ {v}_{III} \\ {w}_{III}\end{matrix} ) \qquad Eq . 12$$

Using segment III as base orientation, there exist 3×3 transformation matrices T_{III-I} and T_{III-II}, which rotate segment III to align with segment I and II, respectively. From segment III to segment I, the transformation involves a counterclockwise 45-degree rotation along z-axis, expressed as following:

$${T}_{III - I} = ( \begin{matrix}cos 45 ° & - s in 45 ° & 0 \\ sin 45 ° & cos 45 ° & 0 \\ 0 & 0 & 1\end{matrix} ) = ( \begin{matrix}\frac{\sqrt{2}}{2} & - \frac{\sqrt{2}}{2} & 0 \\ \frac{\sqrt{2}}{2} & \frac{\sqrt{2}}{2} & 0 \\ 0 & 0 & 1\end{matrix} ) \qquad Eq . 13$$

From segment III to segment II, the transformation involves a clockwise 35.26-degree

$$( arcsin \frac{\sqrt{3}}{3} )$$

rotation along y-axis followed by a clockwise 45-degree rotation along x-axis, expressed as following:

$$\begin{matrix}{T}_{III - II} = ( \begin{matrix}1 & 0 & 0 \\ 0 & cos - 45 ° & - sin - 45 ° \\ 0 & sin - 45 ° & cos - 45 °\end{matrix} ) \times \\ ( \begin{matrix}cos - 35.26 ° & 0 & sin - 35.26 ° \\ 0 & 1 & 0 \\ - sin - 35.26 ° & 0 & cos - 35.26 °\end{matrix} ) \\ = ( \begin{matrix}\frac{\sqrt{6}}{3} & 0 & - \frac{\sqrt{3}}{3} \\ \frac{\sqrt{6}}{6} & \frac{\sqrt{2}}{2} & \frac{\sqrt{3}}{3} \\ \frac{\sqrt{6}}{6} & - \frac{\sqrt{2}}{2} & \frac{\sqrt{3}}{3}\end{matrix} )\end{matrix} \qquad Eq . 14$$

The transformation operation from segment III to segment I and II can be described as Z_{I}=T_{III-I}×Z_{III}, and Z_{II}=T_{III-1}×Z_{III}, zone axes of segment I and II can be calculated as follows:

$$( \begin{matrix}{u}_{I} \\ {v}_{I} \\ {w}_{I}\end{matrix} ) = ( \begin{matrix}\frac{\sqrt{2}}{2} & - \frac{\sqrt{2}}{2} & 0 \\ \frac{\sqrt{2}}{2} & \frac{\sqrt{2}}{2} & 0 \\ 0 & 0 & 1\end{matrix} ) \times ( \begin{matrix}{u}_{III} \\ {v}_{III} \\ {w}_{III}\end{matrix} ) \qquad Eq . 15$$

$$( \begin{matrix}{u}_{II} \\ {v}_{II} \\ {w}_{II}\end{matrix} ) = ( \begin{matrix}\frac{\sqrt{6}}{3} & 0 & - \frac{\sqrt{3}}{3} \\ \frac{\sqrt{6}}{6} & \frac{\sqrt{2}}{2} & \frac{\sqrt{3}}{3} \\ \frac{\sqrt{6}}{6} & - \frac{\sqrt{2}}{2} & \frac{\sqrt{3}}{3}\end{matrix} ) \times ( \begin{matrix}{u}_{III} \\ {v}_{III} \\ {w}_{III}\end{matrix} ) \qquad Eq . 16$$

During electron diffraction measurements, the rotation angle of θ along the z-axis of nanorods ([001] direction of segment I and segment III) can be described in the following rotation matrix R, which

$$R = ( \begin{matrix}cos θ & - sin θ & 0 \\ sin θ & cos θ & 0 \\ 0 & 0 & 1\end{matrix} ) \qquad Eq . 17$$

Therefore, the zone axis after rotation for base segment III can be calculated as:

$${Z}_{III}^{′} = ( \begin{matrix}{u}_{III}^{′} \\ {v}_{III}^{′} \\ {w}_{III}^{′}\end{matrix} ) = ( \begin{matrix}cos θ & - s in θ & 0 \\ sin θ & cos θ & 0 \\ 0 & 0 & 1\end{matrix} ) \times ( \begin{matrix}{u}_{III} \\ {v}_{III} \\ {w}_{III}\end{matrix} ) \qquad Eq . 18$$

And the zone axes of segment I and II can be calculated as:

$${Z}_{I}^{′} = ( \begin{matrix}{u}_{I}^{′} \\ {v}_{I}^{′} \\ {w}_{I}^{′}\end{matrix} ) = ( \begin{matrix}\frac{\sqrt{2}}{2} & - \frac{\sqrt{2}}{2} & 0 \\ \frac{\sqrt{2}}{2} & \frac{\sqrt{2}}{2} & 0 \\ 0 & 0 & 1\end{matrix} ) \times ( \begin{matrix}{u}_{III}^{′} \\ {v}_{III}^{′} \\ {w}_{III}^{′}\end{matrix} ) \qquad Eq . 19$$

$${Z}_{II}^{′} = ( \begin{matrix}{u}_{II}^{′} \\ {v}_{II}^{′} \\ {w}_{II}^{′}\end{matrix} ) = ( \begin{matrix}\frac{\sqrt{6}}{3} & 0 & - \frac{\sqrt{3}}{3} \\ \frac{\sqrt{6}}{6} & \frac{\sqrt{2}}{2} & \frac{\sqrt{3}}{3} \\ \frac{\sqrt{6}}{6} & - \frac{\sqrt{2}}{2} & \frac{\sqrt{3}}{3}\end{matrix} ) \times ( \begin{matrix}{u}_{III}^{′} \\ {v}_{III}^{′} \\ {w}_{III}^{′}\end{matrix} ) \qquad Eq . 20$$

With the above equations, in our experiment, the zone axis of segment III is assigned as

$${Z}_{III} = ( \begin{matrix}1 \\ 0 \\ 0\end{matrix} )$$

under 0-degree tilting condition, therefore, the zone axes of segment I and II can be calculated as follows:

$${Z}_{I} = ( \begin{matrix}{u}_{I} \\ {v}_{I} \\ {w}_{I}\end{matrix} ) = ( \begin{matrix}\frac{\sqrt{2}}{2} & - \frac{\sqrt{2}}{2} & 0 \\ \frac{\sqrt{2}}{2} & \frac{\sqrt{2}}{2} & 0 \\ 0 & 0 & 1\end{matrix} ) \times ( \begin{matrix}1 \\ 0 \\ 0\end{matrix} ) = ( \begin{matrix}\frac{\sqrt{2}}{2} \\ \frac{\sqrt{2}}{2} \\ 0\end{matrix} ) ‖ ( \begin{matrix}1 \\ 1 \\ 0\end{matrix} )$$

$${Z}_{II} = ( \begin{matrix}{u}_{II} \\ {v}_{II} \\ {w}_{II}\end{matrix} ) = ( \begin{matrix}\frac{\sqrt{6}}{3} & 0 & - \frac{\sqrt{3}}{3} \\ \frac{\sqrt{6}}{6} & \frac{\sqrt{2}}{2} & \frac{\sqrt{3}}{3} \\ \frac{\sqrt{6}}{6} & - \frac{\sqrt{2}}{2} & \frac{\sqrt{3}}{3}\end{matrix} ) \times ( \begin{matrix}1 \\ 0 \\ 0\end{matrix} ) = ( \begin{matrix}\frac{\sqrt{6}}{3} \\ \frac{\sqrt{6}}{6} \\ \frac{\sqrt{6}}{6}\end{matrix} ) ‖ ( \begin{matrix}2 \\ 1 \\ 1\end{matrix} )$$

With the above equations, in our experiment, the zone axis of segment III is assigned as

$${Z}_{III} = ( \begin{matrix}1 \\ 0 \\ 0\end{matrix} )$$

under 0-degree tilting condition, therefore, the zone axes of segment I and II can be calculated as follows:

$${Z}_{I} = ( \begin{matrix}{u}_{I} \\ {v}_{I} \\ {w}_{I}\end{matrix} ) = ( \begin{matrix}\frac{\sqrt{2}}{2} & - \frac{\sqrt{2}}{2} & 0 \\ \frac{\sqrt{2}}{2} & \frac{\sqrt{2}}{2} & 0 \\ 0 & 0 & 1\end{matrix} ) \times ( \begin{matrix}1 \\ 0 \\ 0\end{matrix} ) = ( \begin{matrix}\frac{\sqrt{2}}{2} \\ \frac{\sqrt{2}}{2} \\ 0\end{matrix} ) ‖ ( \begin{matrix}1 \\ 1 \\ 0\end{matrix} )$$

$${Z}_{II} = ( \begin{matrix}{u}_{II} \\ {v}_{II} \\ {w}_{II}\end{matrix} ) = ( \begin{matrix}\frac{\sqrt{6}}{3} & 0 & - \frac{\sqrt{3}}{3} \\ \frac{\sqrt{6}}{6} & \frac{\sqrt{2}}{2} & \frac{\sqrt{3}}{3} \\ \frac{\sqrt{6}}{6} & - \frac{\sqrt{2}}{2} & \frac{\sqrt{3}}{3}\end{matrix} ) \times ( \begin{matrix}1 \\ 0 \\ 0\end{matrix} ) = ( \begin{matrix}\frac{\sqrt{6}}{3} \\ \frac{\sqrt{6}}{6} \\ \frac{\sqrt{6}}{6}\end{matrix} ) ‖ ( \begin{matrix}2 \\ 1 \\ 1\end{matrix} )$$

### Example 3: Conclusions

Chemical Composition is Important: Certain chemical compositions require different treatment to retain metastable phase. CdSe and InP require secondary weak-bonding ligand to fully retain metastable phase; PbS, PbSe require significant higher pressure to fully retain metastable phase; while as synthesized CdS, MnS can retain metastable phase but require excess amount of ligand to trigger reverse phase transition under ambient conditions (FIGS. 1A-4B, 12, 34A-63D, 67A-68C, 74A-85D).

Size Matters: From the result of stepwise heating treatment, CdS showing higher apparent activation energy for 8-nm size than 4.8-nm size when capped with either organic or inorganic ligands (FIGS. 34A-47D, Table 3). Similar phenomenon was found with CdSe/CdS core-shell nanocrystals, that 8-nm building blocks showing a higher apparent activation energy than their 4.8-nm counterparts when capped with organic ligand; while capped with inorganic ligand, 4.8-nm building block cannot fully retain metastable high-pressure phase under ambient conditions (FIGS. 48A-53D, Table 3).

Shape Matters: The apparent activation energy is associated with the topological information of the superstructure. From the experimental result, it can be found that nanorods exhibit a wider activation energy distribution compared to spherical nanocrystals. (FIGS. 34A-63D, 93A-93B, Tables 3-4).

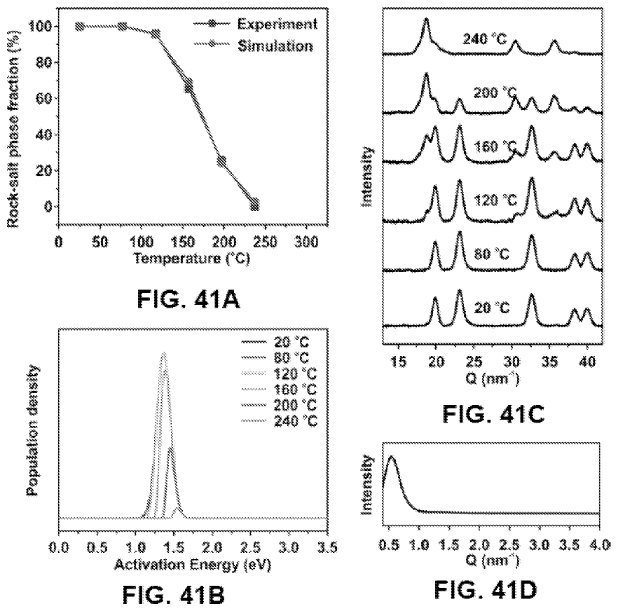

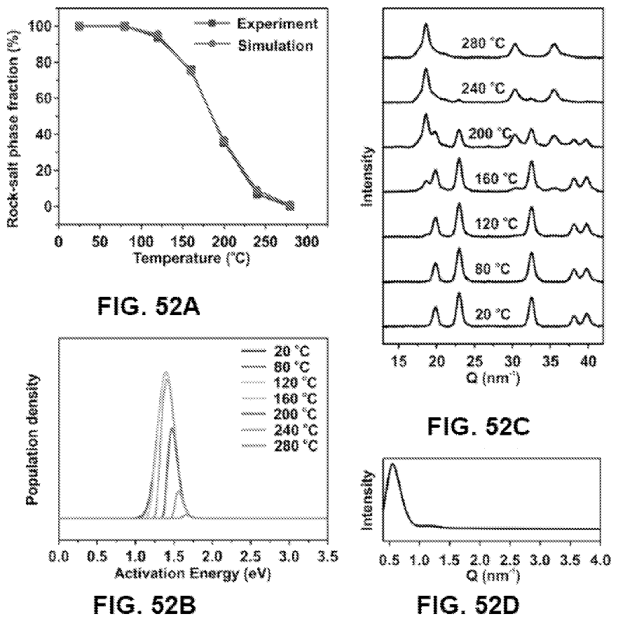

Core/Shell Interfaces Matter: The core/shell interfaces can couple with surface nucleation sites and significantly lower the activation energy for reverse phase transition. From experimental result, 4.8-nm CdSe/CdS showing a 31.56% undefined phase transition process at ˜45° C., while such undefined transition was not observed for 4.8-nm CdS nanocrystal (FIGS. 34A-34D, 48A-48D, Table 3). When the shell thickness increases, 8-nm CdSe/CdS exhibited identical activation energy distribution compared to 8-nm CdS nanocrystals when capped with octylamine; when capped with inorganic ligand, 8-nm CdSe/CdS nanocrystals exhibited lower activation energy compared to 8-nm CdS nanocrystals (FIGS. 41A-41D, 52A-52D, Table 3). 4.8-nm CdS/CdSe coreshell nanocrystals exhibit ambient metastability of rock-salt crystal phase in between CdS and CdSe materials (FIGS. 67A-67C, 75A-75C, 80A-80D, 84A-84D)

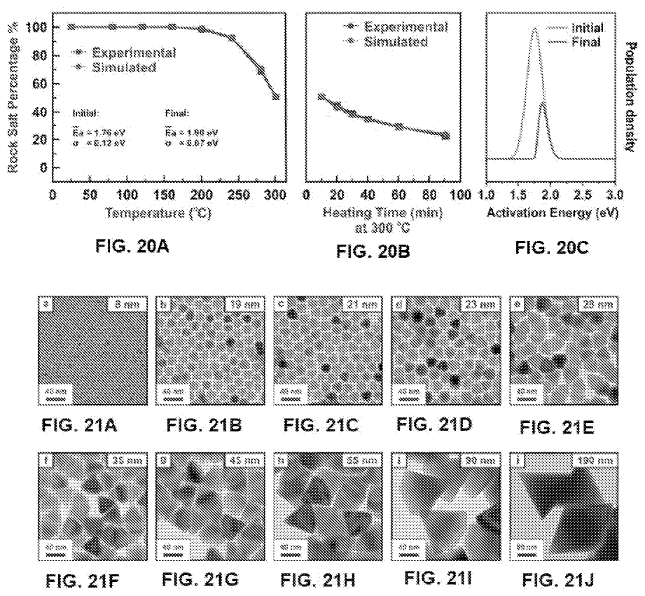

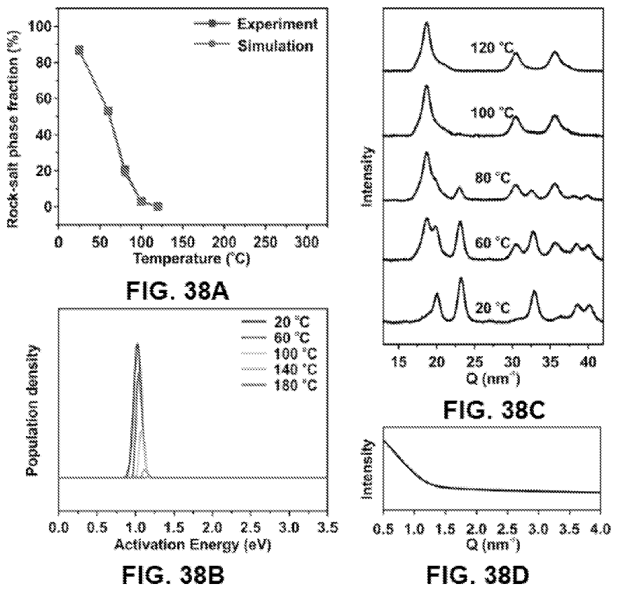

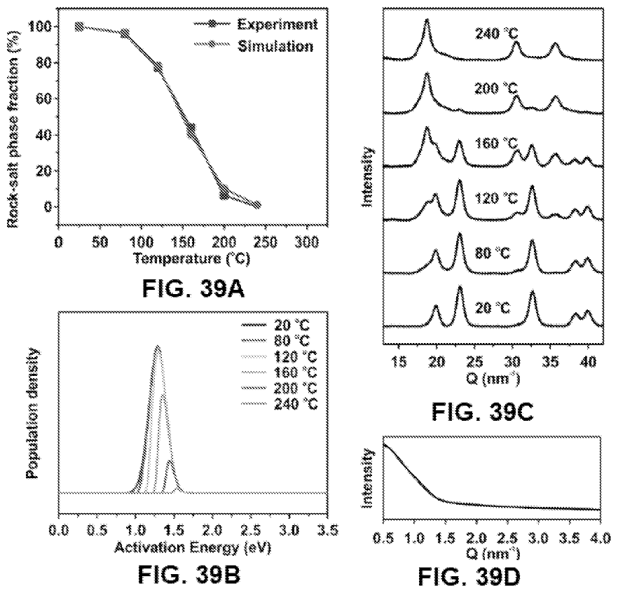

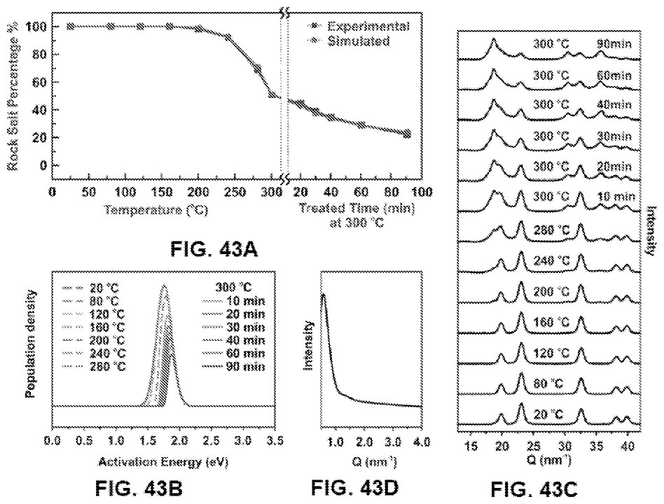

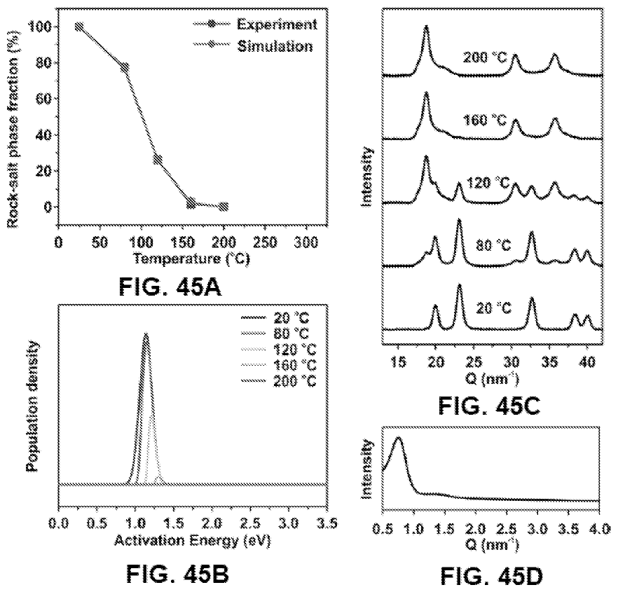

Surface Chemistry Matters: For spherical nanocrystals, when capped with stable inorganic ligands, such as (N₂H₅)₄SnS₆, the apparent activation energy increases (FIGS. 20A-20C, 34A-34D, 37A-37D, 41A-41D 42A-42D, 43A-43D, Table 3). The highest apparent activation energy distribution achieved in this work exhibited a mean of 1.76 eV (FIGS. 20A-20C, 43A-43D, Table 3). After heating at 300° C. for 90 minutes, the remaining RS phase sample exhibited a mean activation energy of 1.90 eV, which can preserve 99.5% of high-pressure phase for 1 billion years under ambient conditions (FIGS. 20C, 43B). For spherical CdS nanocrystals, when capped with unstable inorganic ligands such as (NH₄)₂S, the apparent activation energy decreases (FIGS. 38A-38D, 45A-45D, Table 3).

TABLE 3
Simulated activation energy distribution of spherical samples discussed in this work.

| | | Highest | | Percentages (%) | | | Gaussian | | |
|---|---|---|---|---|---|---|---|---|---|
| | | applied | | Total | | | distribution | | |
| Nanocrystal | Surface | pressure | | RS | | | parameters | | |
| core | ligand | (GPa) | Special note | phase | Undefined | Gaussian | Ēₐ (eV) | σ (ev) | R² |
| 4.8-nm CdS | Octylamine | 14.3 | | 100 | 0 | 100 | 1.26 | 0.16 | 0.9983 |
| nanospheres | (N₂H₅)₄Sn₂S₆ | 15.8 | | 100 | 0 | 100 | 1.46 | 0.15 | 0.9976 |
| | (NH₄)₂S | 14.7 | | 88.53 | 0 | 88.53 | 1.03 | 0.05 | 0.9999 |
| | (NH₄)₂S | 14.9 | +Cd(NO₃)₂ | 100 | 0 | 100 | 1.29 | 0.11 | 0.9985 |
| | (NH₄)₂S | 15.2 | +Ca(NO₃)₂ | 86.34 | 0 | 86.34 | 1.24 | 0.14 | 0.9993 |
| 8-nm CdS | Octylamine | 15.5 | | 100 | 0 | 100 | 1.37 | 0.09 | 0.9985 |
| nanospheres | (N₂H₅)₄Sn₂S₆ | 21.0 | | 100 | 0 | 100 | 1.76 | 0.12 | 0.9985 |
| | (N₂H₅)₄Sn₂S₆ | 15.3 | | 100 | 0 | 100 | 1.66 | 0.14 | 0.9967 |
| | (N₂H₅)₄Sn₂S₆ | 15.7 | +C8-SH | 100 | 0 | 27.70 | 1.09 | 0.05 | 0.9997 |
| | | | | | | 72.30 | 1.40 | 0.09 | |
| | (NH₄)₂S | 15.6 | | 100 | 0 | 100 | 1.14 | 0.08 | 0.9999 |
| | (NH₄)₂S | 15.9 | +Cd(NO₃)₂ | 100 | 0 | 100 | 1.40 | 0.07 | 0.9996 |
| | (NH₄)₂S | 15.8 | +Ca(NO₃)₂ | 100 | 0 | 100 | 1.22 | 0.07 | 0.9951 |
| 4.8-nm | Octylamine | 10.5 | | 100 | 40.21 | 59.79 | 1.29 | 0.14 | 0.9972 |
| CdSe/CdS | Octylamine | 10.8 | Detailed | 100 | 39.67 | 60.33 | 1.28 | 0.16 | 0.9978 |
| nanopheres | | | heating | | | | | | |
| | Octylamine | 15.1 | | 100 | 31.56 | 68.44 | 1.29 | 0.13 | 0.9993 |
| | (N₂H₅)₄Sn₂S₆ | 14.8 | | 86.05 | 0 | 86.06 | 1.10 | 0.07 | 0.9997 |
| 8-nm | Octylamine | 14.1 | | 100 | 0 | 100 | 1.40 | 0.11 | 0.9992 |
| CdSe/CdS | (N₂H₅)₄Sn₂S₆ | 14.4 | | 100 | 0 | 100 | 1.34 | 0.10 | 0.9991 |
| nanospheres | | | | | | | | | |

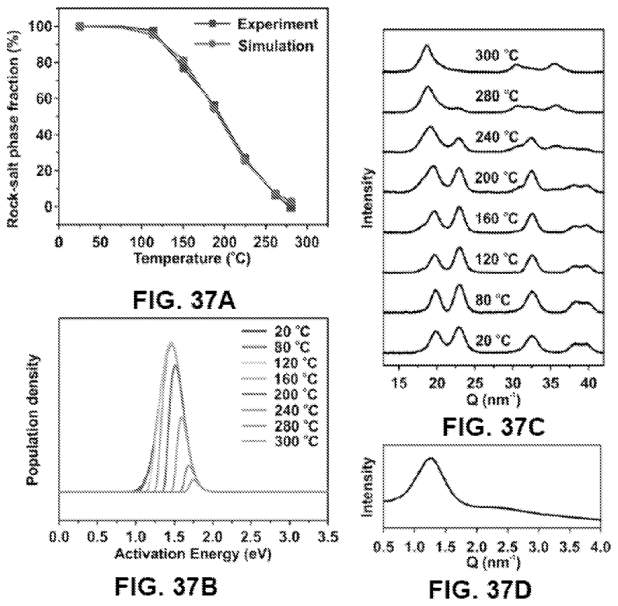

Supercrystalline Order Matters: The order of nanocrystal assemblies plays a significant role in the metastability of high-pressure phase. It can be found when capped with inorganic ligand, 4.8-nm spherical CdS nanocrystals exhibit a much higher activation energy distribution compared to 24.5-nm CdS nanorods, and with similar RS phase domain size (˜3.5 nm). From SAXS, the supercrystalline order level is much higher for spherical nanocrystals compared to nanorods (FIGS. 37A-37D, 63A-63D, 93A-93B, Tables 3-4)

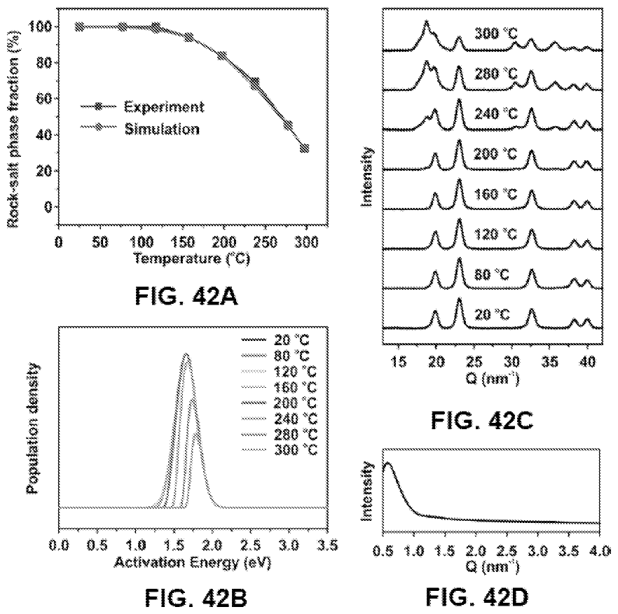

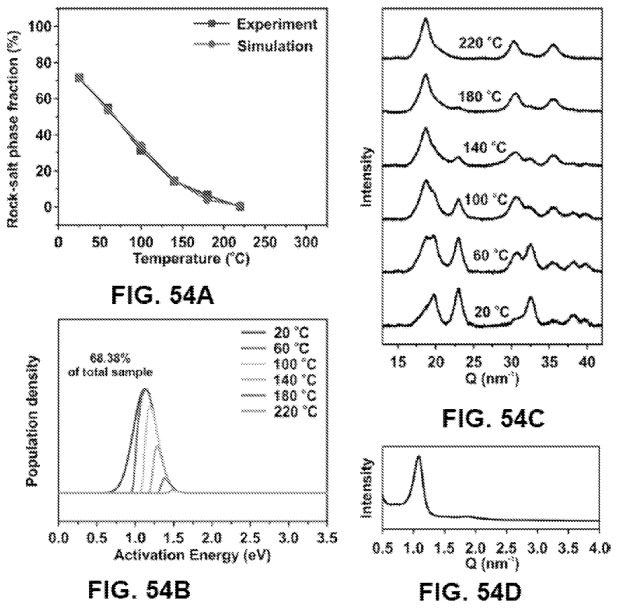

External Pressure Matters: The highest pressure applied during the pressurization process is critical to the activation energy distribution of the final product. 23.8-nm CdSe/CdS nanorods capped with octylamine show a systematic increase of activation energy distribution as highest applied pressure increases (FIGS. 54A-59D, Table 4). Similar effect was observed with 24.5-nm CdS nanorods and 4.8-nm CdSe/CdS nanospheres capped with octylamine, as well as 8-nm CdS capped with inorganic ligand (N₂H₅)₄Sn₂S₆(FIGS. 42A-43D, 48A-50D, Table 4).

### Upper and Lower Size Limits

Both lower and upper size limits for nanodomains within which the high-pressure crystal phase can remain metastable at ambient pressure have been identified. The specific lower and upper size limits depend on the chemical compositions of the nanodomains. For CdS nanodomains, the upper size limit is approximately 23 nm when capped with octylamine (FIGS. 21A-21M). For PbSe nanodomains, the lower size limit is about 5.5 nm when capped with octylamine (FIGS. 22A-22E).

TABLE 4
Simulated activation energy distribution of nanorod samples discussed in this work.

| | | Highest | Percentages (%) | | | Gaussian | | |
|---|---|---|---|---|---|---|---|---|
| | | applied | Total | | | distribution | | |
| Nanocrystal | Surface | pressure | RS | | | parameters | | |
| core | ligand | (GPa) | phase | Undefined | Gaussian | Ēₐ (eV) | σ (eV) | R² |
| 23.8-nm | Octylamine | 7.3 | 71.49 | 3.11 | 68.38 | 1.13 | 0.15 | 0.9976 |
| CdSe/CdS | Octylamine | 8.3 | 100 | 22.6 | 77.64 | 1.29 | 0.18 | 0.9999 |
| nanorods | Octylamine | 10.5 | 100 | 16.20 | 83.60 | 1.28 | 0.19 | 0.9993 |
| | Octylamine | 13.5 | 100 | 8.33 | 91.67 | 1.28 | 0.20 | 0.9994 |
| | Octylamine | 14.5 | 100 | 0 | 100 | 1.30 | 0.23 | 0.9973 |
| | Octylamine | 18.2 | 100 | 0 | 100 | 1.36 | 0.15 | 0.9984 |
| | (N₂H₅)₄Sn₂S₆ | 16.8 | 100 | 0 | 100 | 1.13 | 0.06 | 0.9977 |
| 24.5-nm | Octylamine | 10.8 | 100 | 0 | 100 | 1.27 | 0.15 | 0.9945 |
| CdS/CdS | Octylamine | 15.1 | 100 | 0 | 100 | 1.34 | 0.17 | 0.9978 |
| nanorods | (N₂H₅)₄Sn₂S₆ | 15.5 | 100 | 0 | 100 | 1.14 | 0.06 | 0.9965 |

### Example 4: Stepwise Heating Methodology

### Experimental Method

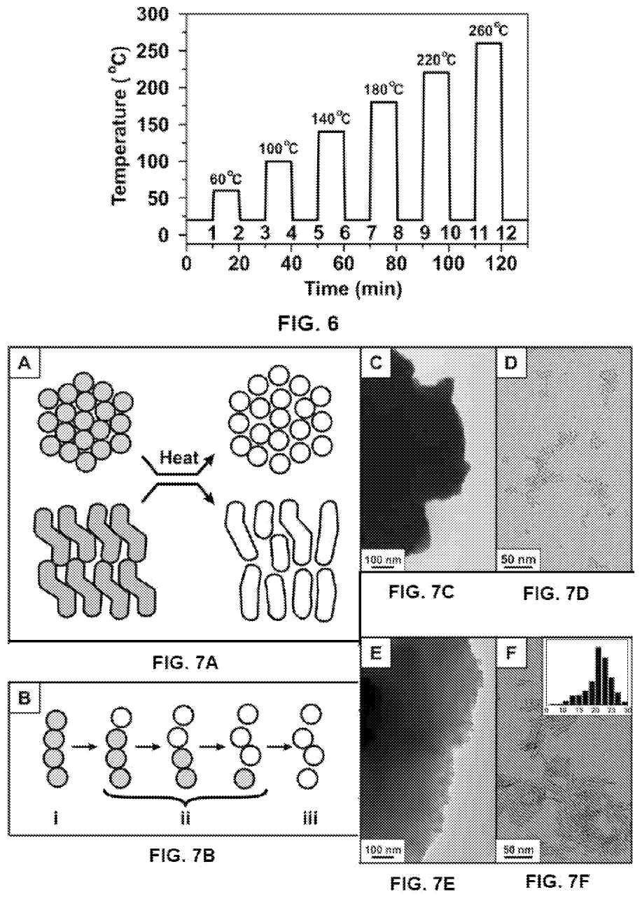

The steel gasket containing rock-salt sample was removed from the DAC and placed in a glass petri dish, and the petri dish was placed in a Thermo Fisher Precision™ 605 oven pre-heated to the designated temperature. In this study, the treatment time for each step was 10 min, after which point the petri dish was removed from the oven and cooled to room temperature with a fan. An example of an experimental heating profile is shown in FIG. 6, where the temperature achieves equilibrium within 60 seconds at each treatment step. The steel gasket was then mounted on a sample holder for synchrotron SAXS and WAXS measurement. The RS-to-ZB phase transformation was monitored by synchrotron, and the stepwise heating treatment was repeated at different temperatures until the RS-to-ZB phase transformation was complete.

### The Impact of Phase-Transition Enthalpy on Local Sample Temperatures

The rock-salt to zincblende phase transition is an exothermic process. The enthalpy of this process (AH) is −0.132 eV/atom for CdS, and the enthalpy of 4.8 nm CdS nanocrystals (ΔHNC) is −308.88 eV/NC. This exothermic process can potentially have an impact on the local temperatures of our samples. We will estimate this impact as follows:

The heat flux (q_{PT}) due to nanocrystal RS-ZB phase transition (PT) in a sample of an interconnected nanocrystal network can be calculated using the formula: q_{PT}=k×ΔH_{NC}×M, where q is the heat flux, k is the reaction rate, and M is the number of nanocrystals in the sample.

By using the maximal phase transition rate of 1.5×10⁻⁴/s and a typical sample size of ˜10¹³ nanocrystals, we estimated the value of q_{PT} to be:

$${q}_{PT} = 1.5 \times 1 {0}^{- 4} / s \times 30 8.88 eV / NC \times 1 {0}^{13} NC = 4.63 \times 1011 eV / s = 7 \text{.41} \times {10}^{- 8} W$$

With a diameter of 150 micrometers for a typical sample, the local heat flux density (q_{RS-ZB}) is calculated to be 4.19×10⁻⁴ W/cm².

According to the differential form of Fourier's law of thermal conduction, the local heat flux density q is equal to the product of the thermal conductivity x of a material and the negative local temperature gradient −ΔT: q=−κ×ΔT/L. The thermal conductivity of CdS and air is 0.20 WK⁻¹ cm⁻¹ and 0.04 WK⁻¹ cm⁻¹, respectively.

To create a 0.1 K temperature difference, the local flux density for CdS and air would be 8 W/cm² (q_{CdS}) and 1.6 W/cm² (qₐᵢᵣ), respectively. Both values are about 4 orders of magnitude larger than the local heat flux density created by the RS-ZB phase transition in our samples. Therefore, the impact of phase-transition enthalpy is negligible in our experiments.

Using the maximal phase transition rate of 1.5×10⁻⁴/s and a typical sample size of 10¹³ nanocrystals, we obtained an estimated value of q_{PT}:

$${q}_{PT} = 1.5 \times 1 {0}^{- 4} / s \times 308.88 eV / NC \times 1 {0}^{13} NC = 4.63 \times 1 {0}^{11} eV / s = 7.41 \times 1 {0}^{- 8} W$$

The diameter of a typical sample is 150 micrometers and therefore the local heat flux density (q_{RS-ZB})=4.19×10⁻⁴ W/cm².

The differential form of Fourier's law of thermal conduction shows that the local heat flux density q is equal to the product of thermal conductivity κ of a material and the negative local temperature gradient −ΔT: q=−κ·ΔT/L. The thermal conducitivities of CdS and air are 0.20 WK⁻¹ cm⁻¹ and 0.04 WK⁻¹ cm⁻¹, respectively.

To create a 0.1 K temperature difference, the local flux densities for CdS and air are 8 W/cm² (q_{CdS}) and 1.6 W/cm² (qₐᵢᵣ), respectively. Both are much larger than the local heat flux density (q_{RS-ZB}) created by the RS-ZB phase transition in our samples. Therefore, phase transition enthalpy has a negligible impact on temperature measurements in our experiments.

### Numerical Simulation of the Apparent Activation Energy Distribution Determined by Heating Treatments

An interconnected nanocrystal network is represented as an interconnected nanodomain network. Each interconnected nanodomains can originate directly from a building block nanocrystal or from the fragmentation of a building block nanocrystal (e.g., a 24-nm CdSe/CdS nanorod can fragment into three interconnected nanodomains under high pressure). In the afterwards discussion, a single nanodomain, instead of a single nanocrystal, is regarded as the basic structural unit where a RS-to-ZB phase transition event can take place.

The nucleation of ZB phase in a RS nanodomain follows an Arrhenius mechanism where phonons (lattice vibrations with Bose-Einstein distribution) provide thermal energies to a nucleation site (located at one of DS complexes) and thus resulting phase transition event with a rate constant: k=Ae^{-Ea/kBT}, where Eₐ is an effective activation energy for the RS-to-ZB phase transition in a single nanodomain, where exist multiple nucleation sites from which the transition can initiate overcoming a specific activation energy, but only one nucleation event occurs per nanodomain transformation. The relationship between the effective activation (Eₐ) and the specific activation energies associated with different nucleation sites (Eₐᵢ) can be written as:

$${Ae}^{- \frac{{E}_{a}}{{k}_{B} T}} = {\sum }_{i}^{n} ( {Ae}^{- \frac{{E}_{ai}}{{k}_{B} T}} )$$

where, A is attempting frequency, k_{B}: Boltzmann constant, and T is temperature. Eₐᵢ is the activation energy of phase transition initiated at nucleation site i, and n is the total number of nucleation sites in this nanodomain. This equation can be arranged in the expression of Eₐ:

$${E}_{a} = - {k}_{B} Tln [ {\sum }_{i}^{n} ( {e}^{- \frac{{E}_{ai}}{{k}_{B} T}} ) ]$$

Impact energy (Δ) is the change in effective activation energy of a nanodomain induced by one of its neighboring nanodomains through a non-Arrhenius mechanism. In a X-Y pair, impact energy is denoted as Δ_{X→Y} or Δ_{Y→X} for the first RS-ZB phase-transition event occurring in the nanodomain X or Y, respectively.

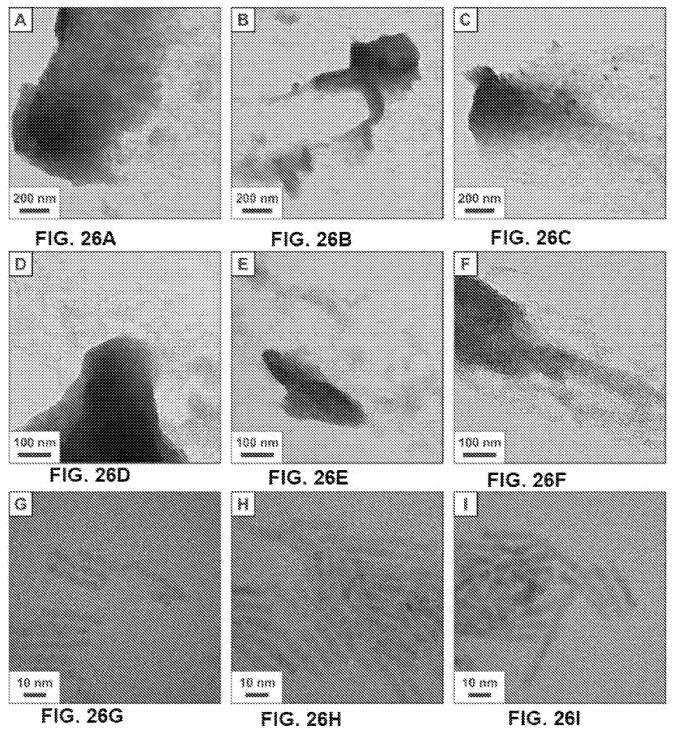

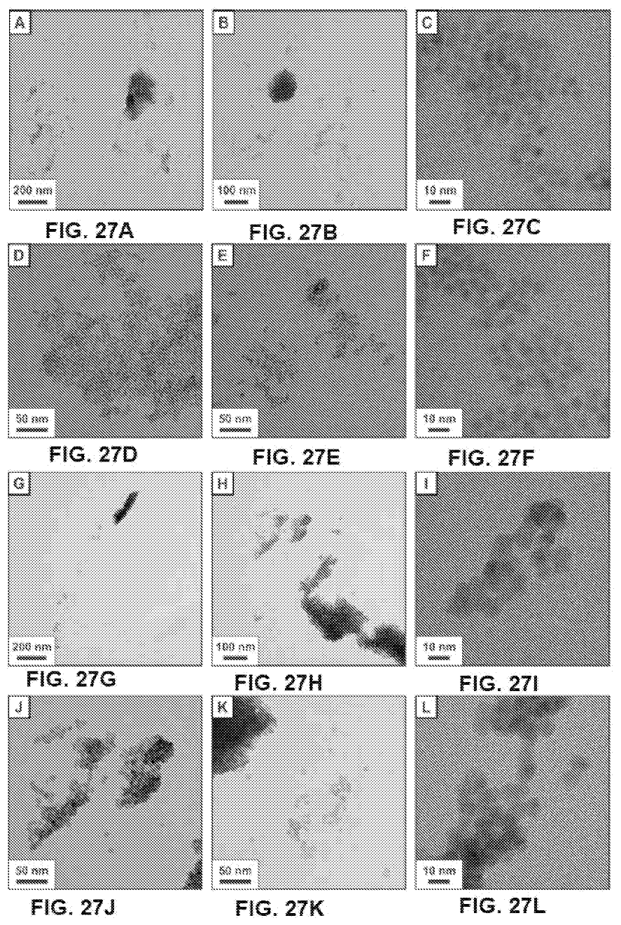

The sample cannot retain interconnected network after stepwise heating treatment, which is caused by the link breakage between nanodomains accompanied by RS-to-ZB phase transition shown by TEM measurement (FIGS. 7A-7F, 25A-27L). If the RS-ZB phase transition of nanodomain X occur first, this event would lead to the link breakage of the pair, which is associated with intraparticle-grain-boundary fracture between the X and Y nanodomain due to the large lattice stains introduced by the large lattice mismatch between the ZB and RS crystal phases and the significant shape change of nanodomain X. This non-Arrhenius process leads to the formation of one (or more) new nucleation site(s) at the fractured grain boundary on the surface of nanodomain Y (which remains the RS phase). Before the link breakage, nanodomain Y undergoes a phase transformation pathway with an effective activation energy of E_{aY}. The nucleation site(s) generated by link breakage introduces a new RS-ZB phase-transformation pathway exhibiting an effective activation energy of E_{aX→}.

$${Ae}^{- \frac{{E}_{a}^{Y *}}{{k}_{B} T}} = {Ae}^{- \frac{{E}_{a}^{Y}}{{k}_{B} T}} + {Ae}^{- \frac{{E}_{a}^{X \to Y}}{{k}_{B} T}}$$

In the case when the new RS-ZB phase transformation pathway(s) couple with existing pathways, this coupling will instantly trigger a RS-ZB phase transition of nanocrystal Y with a reaction rate constant of extremely large (approaching to infinity), where a new effective activation energy of nanocrystal Y (E_{A}^{Y*}) approaches to zero and the value of Δ approaching to that of Eₐ^{Y}.

In the case when the new RS-ZB phase transformation pathway(s) is statistically independent to the original phase transition pathway, and based to the equal a priori probability postulate, E_{A}^{Y}* (after link breakage can be given as follows:

$${e}^{\frac{{Δ}_{X \to Y}}{{k}_{B} T}} = {e}^{\frac{{E}_{A}^{Y} - {E}_{A}^{Y *}}{{k}_{B} T}} = 1 + {e}^{\frac{{E}_{A}^{Y} - {E}_{a}^{X \to Y}}{{k}_{B} T}}$$

The impact energy has a non-negative value with directional anisotropy, where Δ_{X→Y} is not necessarily equal to Δ_{Y→X}.

An interconnected nanodomain network is represented as a weighted graph, where nodes represent individual single nanodomains, links represent grain boundaries formed due to partial fusion (or intraparticle crystal-domain fragmentation, such as, in the case of nanorods) between neighboring single nanodomains. Directional link weight is represented as W_{i,j}=Δ_{i→j}.

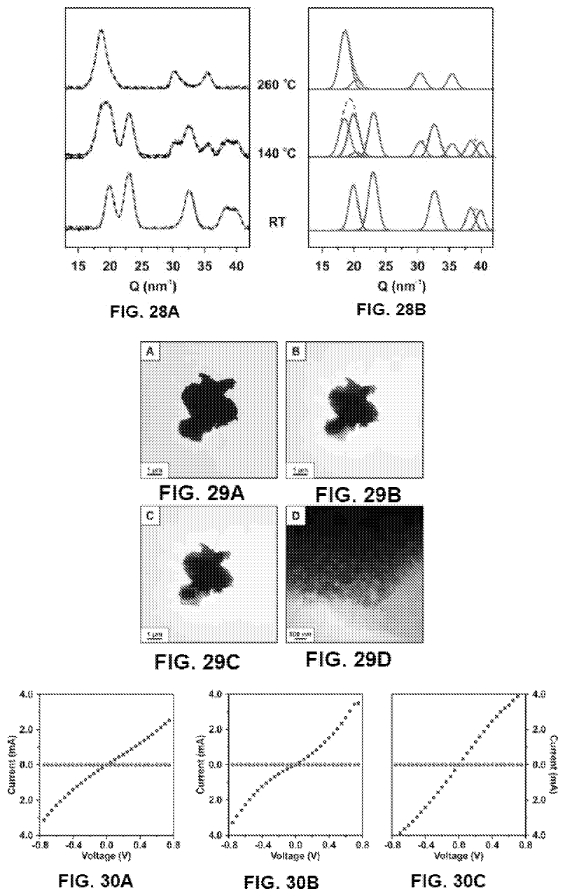

The RS-to-ZB phase transition event in a nanodomain is determined by the nucleation rate of ZB phase in the RS nanodomain. The ZB phase propagation inside a crystal takes place at a speed close to the speed of sound in the materials, thus the duration of phase transition in a nanocrystal is normally at the level of ˜1×10⁻¹¹ s. Under our experimental resolutions, the crystal phases of individual single nanodomains were observed in either a rock-salt (RS) or a zincblende (ZB) phase (FIGS. 28A-28B). This result is consistent with the definition of single nanodomains as basic structural units for a RS-ZB phase transition event.

The RS-to-ZB phase transition events in an interconnected nanodomain network occur at different contiguous clusters of nanodomains. The RS-to-ZB phase transition events are statistically dependent inside a cluster, while the phase transition events are statistically independent between clusters in the network. In our samples, there existed a large amount of super-crystalline defects (see Table 5), which further limited the size of clusters.

TABLE 5
Scherrer domain size of RS nanodomain superstructure
calculated by SAXS pattern

| Inorganic core | Surface ligand | Scherrer size (nm) |
|---|---|---|
| 4.8-nm CdS | Octylamine | 20.29 |
| nanosphere | (N₂H₅)₄Sn₂S₆ | 9.89 |
| | (NH₄)₂S | No peak (<5 nm) |
| 8-nm CdS | Octylamine | 16.60 |
| nanosphere | (N₂H₅)₄Sn₂S₆ | 12.29 |
| | (NH₄)₂S | 8.31 |
| 4.8-nm CdSe/CdS | Octylamine | 14.59 |
| nanosphere | (N₂H₅)₄Sn₂S₆ | 10.63 |
| 8-nm CdSe/CdS | Octylamine | 18.26 |
| nanosphere | (N₂H₅)₄Sn₂S₆ | 10.83 |
| 23.8-pm | Octylamin | 35.60 |
| CdSe/CdS | (N₂H₅)₄Sn₂S₆ | No peak (<5 nm) |
| nanorod | | |
| 24.5-nm CdS/CdS | Octylamine | 23.60 |
| nanorod | (N₂H₅)₄Sn₂S₆ | No peak (<5 nm) |

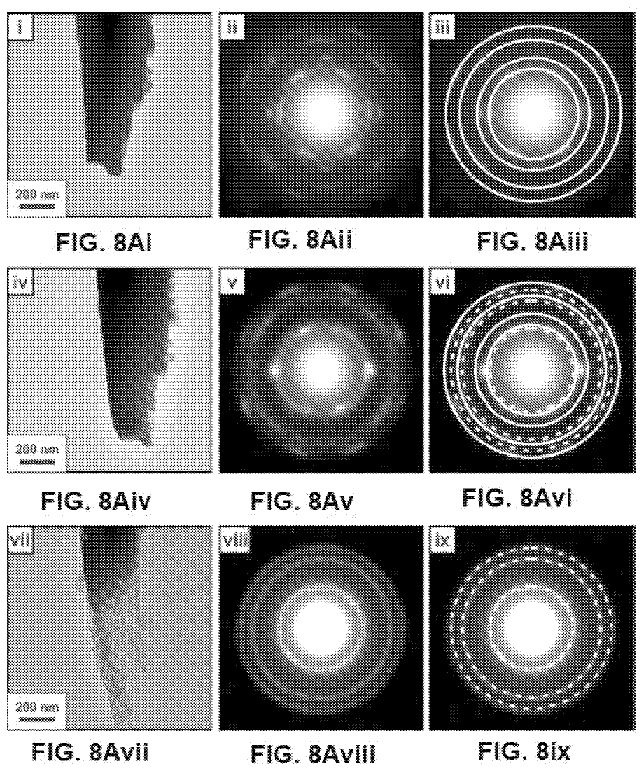

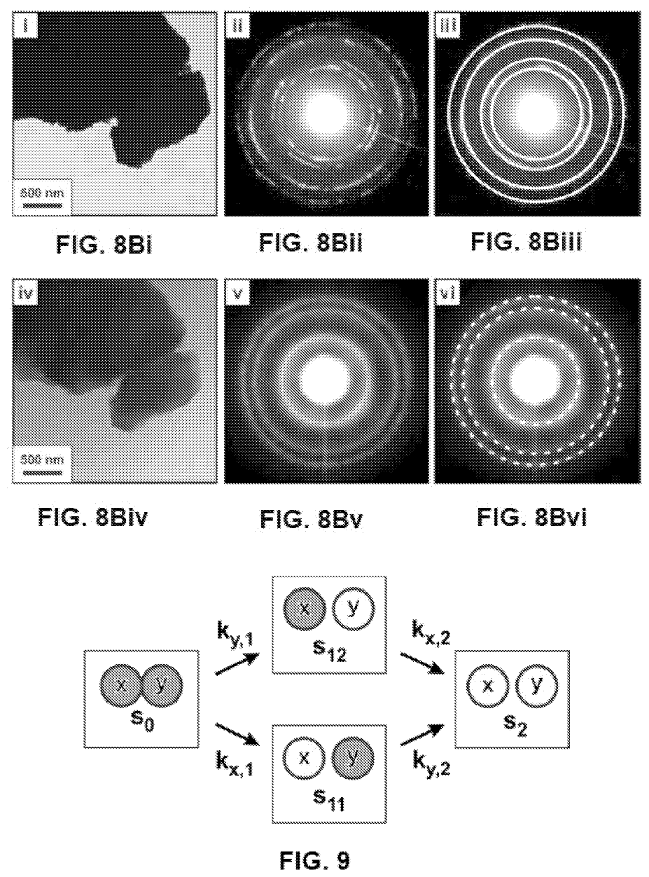

The definition of clusters is consistent with our TEM observations on the electron-beam triggered RS-to-ZB phase-transition events in blocks of interconnected nanodomain networks. TEM observations showed that the RS-to-ZB phase-transition transition in rock salt nanodomain networks prepared from 4.8-nm zinc blende CdS nanocrystals took place clusterwise and non-uniformly at length scale of 20-30 nm (FIGS. 8Ai-8Bvi, 29A-D). This result suggests there exists cluster-size associated effective distances for the spreading (or growth) of solid-solid phase transformation events in an interconnected nanodomain network, and thus there should exist “network isolators” to limit the cluster sizes.

Network isolators are located at links, where both Δ_{t→j}=Δ_{t→j}≤k_{B}Tln2.

In a system of a pair of X-Y nanocrystals with a grain boundary, there exists 4 states as shown in FIG. 9, which so with both nanocrystals retain in RS phase, s₁₁ with only nanocrystal X in ZB phase, s₁₂ only nanocrystal Y in ZB phase, and s₃ with both nanocrystals in ZB phase. The transition rate constant of the system is labeled as k_{x,1}, k_{y,1}, k_{x,2}, and k_{y,2}.

With the above state space, the probability of system exhibits each state can be calculated by the following equations:

$$\frac{{dP}_{0}}{dt} = - ( {k}_{x , 1} + {k}_{y , 1} ) {P}_{0}$$

$$\frac{{dP}_{1 , 1}}{dt} = {k}_{x , 1} {P}_{0} - {k}_{y , 2} {P}_{1 , 1}$$

$$\frac{{dP}_{1 , 2}}{dt} = {k}_{y , 1} {P}_{0} - {k}_{x , 2} {P}_{1 , 2}$$

$$\frac{{dP}_{2}}{dt} = {k}_{x , 2} {P}_{1 , 2} + {k}_{y , 2} {P}_{1 , 1}$$

Resulting in:

$${P}_{0} = {e}^{- ( {k}_{x , 1} + {k}_{x , 1} ) t}$$

$${P}_{1 , 1} = \frac{{k}_{x , 1}}{{k}_{y , 2} - {k}_{x , 1} - {k}_{y , 1}} [ {e}^{- ( {k}_{x , 1} + {k}_{y , 1} ) t} - {e}^{- {k}_{y , 2} t} ]$$

$${P}_{1 , 2} = \frac{{k}_{y , 1}}{{k}_{x , 2} - {k}_{x , 1} - {k}_{y , 1}} [ {e}^{- ( {k}_{x , 1} + {k}_{y , 1} ) t} - {e}^{- {k}_{x , 2} t} ]$$

$${P}_{2} = 1 - {P}_{0} - {P}_{1 , 1} - {P}_{1 , 2}$$

The expectation value of nanocrystal retaining RS phase in this A-B nanocrystal pair can be calculated as:

$$< N > = 2 {e}^{- ( {k}_{x , 1} + {k}_{x , 1} ) t} + \frac{{k}_{x , 1}}{{k}_{y , 2} - {k}_{x , 1} - {k}_{y , 1}} [ {e}^{- ( {k}_{x , 1} + {k}_{y , 1} ) t} - {e}^{- {k}_{y , 2} t} ] + \frac{{k}_{y , 1}}{{k}_{x , 2} - {k}_{x , 1} - {k}_{y , 1}} [ {e}^{- ( {k}_{x , 1} + {k}_{y , 1} ) t} - {e}^{- {k}_{x , 2} t} ]$$

When k_{x,1}=k_{x,2}=kₓ and k_{y,1}=k_{y,2}=k_{y}, <N>=e^{-kxt}+e^{-kyt}, that the reactions of nanocrystal A and B are independent from each other. Otherwise, the reactions of nanocrystal A and B are dependent on each other. When the reactions are independent, the interparticle-grain-boundary between nanocrystal X and Y is defined as a network isolator in the 3D interconnected nanodomain network.

### Assumptions on the Kinetics of RS-to-ZB Phase Transition in Nanodomains Inside Interconnected Nanocrystal Networks

The crystal phases of individual nanodomains are described with a binary random variable, which is either RS or ZB phase.

At time t, the probability of a nanodomain adopting the RS phase is P(t) and that with the ZB phase is 1−P(t). P(0)=1 at time 0.

The rate of RS-to-ZB phase transition in a single nanodomain is described with the change in the probability of this nanodomain in the RS phase from time t to t+dt is (kP)dt, where k=Ae^{-Ea/kBT}. The K\kinetic equation of the RS-to-ZB phase transformation can be written as:

$$\frac{dP}{dt} = kP$$

Inside a cluster, the occurrence of phase-transition events is statistically dependent, but no two RS-to-ZB phase-transition events can occur at exactly the same instant.

Among the clusters in an interconnected nanodomain network, the occurrence of phase-transition events is statistically independent, and only one initial RS-to-ZB phase-transition event among the clusters can occur at exactly the same instant. The very first phase-transition event taking place in a cluster is defined as the initial phase-transition event in this cluster.

### Coarse-Grained Analysis

Set that the contiguous clusters in an interconnected nanodomain network prepared under a given pressure form a statistically stable population. In this population, there are the total number of RS clusters ( [symbol] ), and there exist a mean (μ_{B}) and a standard deviation (σ_{B}) of the numbers of RS nanodomains in clusters. Bi is the number of RS-phased nanodomains in cluster i. Nₘ is the number of nanodomains in the RS crystal phase can be measured experimentally. Upon heating treatments as a function of time, RS nanodomains transform into ZB ones through RS-ZB solid-solid phase transition, and [symbol] , Bᵢ and Nₘ become variables as a function of time in the following relationship

$${N}_{m , i} ( t ) = {\sum }_{j = 1}^{{M}_{i}} ( {B}_{i , j} ( t ) )$$

And the average cluster size is calculated as:

$${\overline{B}}_{i} ( t ) = \frac{{N}_{m , i} ( t )}{{ℳ}_{i} ( t )}$$

Cluster mean size B(t) as the mean number of RS nanodomains n clusters at time t is given by

$${\overline{B}}_{i} ( t ) ∼ ℕ ( {μ}_{B} , \frac{{σ}_{B}^{2}}{{ℳ}_{i} ( t )} )$$

As shown in TEM observations, nearly all RS-ZB phase transition events are accompanied by interparticle grain boundary fracture, which is consistent with the loss of electric conductivity due to heating treatments (FIGS. 7A-7F, 25A-27L, 30A-30C). This non-Arrhenius grain-boundary fracture leads to the formation of one (or more) new nucleation site(s) at the fractured grain boundary on the surface of neighboring nanodomains. It is reasonable to assume that the impact energy (Δ) is either very large at the low-angle or coincidence-site-lattice boundaries or very small (approaching to zero) at amorphous high-angle grain boundaries. Under this assumption, the phase RS-ZB phase transition kinetics inside clusters follow a “winner-take-all” mechanism, which nanodomains with low phase-transition-activation energies determine the phase transition kinetics of this cluster. In this end, each cluster exhibits an effective activation energy called cluster activation energy (Eₐ^{C}).

Based on the winner-take-all mechanism and in accordance with Assumption 5, the probability for the existence of an exact number [symbol] ᵢ(t) of RS clusters at a given time t follows a binomial distribution:

$$Pr ( {ℳ}_{i} ( t ) ; {ℳ}_{i} ( 0 ) ) = ( \begin{matrix}{ℳ}_{i} ( 0 ) \\ {ℳ}_{i} ( t )\end{matrix} ) {{P}_{i} ( t )}^{{ℳ}_{i} ( t )} {( 1 - {P}_{i} ( t ) )}^{{ℳ}_{i} ( 0 ) - {ℳ}_{i} ( t )}$$

$$where {P}_{i} ( t ) = {e}^{- {k}_{i} t} and {k}_{i} = {Ae}^{- \frac{{E}_{a , i}^{C}}{{k}_{B} T}}$$

The mean number of RS clusters ( [symbol] ᵢ(t)) can be expressed by:

$$\overline{{ℳ}_{i} ( t )} = {\sum }_{j = 0}^{{M}_{i} ( 0 )} [ j \times Pr ( j ; {ℳ}_{i} ( 0 ) ) ] = {ℳ}_{i} ( 0 ) {P}_{i} ( t )$$

and its standard deviation is:

$${σ}_{ℳ , i} ( t ) = {\sum }_{j = 0}^{{M}_{i} ( 0 )} [ {( j - \overline{{ℳ}_{i} ( t )} )}^{2} Pr ( j ; {ℳ}_{i} ( 0 ) ) ] = \sqrt{{ℳ}_{i} ( 0 ) {P}_{i} ( t ) ( 1 - {P}_{i} ( t ) )}$$

The number of RS nanodomains can be calculated as:

$${N}_{m , i} ( t ) = {M}_{i} ( t ) \times {\overline{B}}_{i} ( t )$$

Since B̅ᵢ(t) and Mᵢ(t) are weakly dependent variables, we can use the rule of prorogation of uncertainties to determine the relative standard deviation of N_{m,i}(t):

$${( \frac{{σ}_{Nm , i} ( t )}{{N}_{m , i} tr )} )}^{2} \approx \frac{{σ}_{{ℳ}_{i} ( t )}^{2}}{{{ℳ}_{i} ( t )}^{2}} + \frac{{σ}_{\overline{B} ( t )}^{2}}{{\overline{B} ( t )}^{2}} + \frac{2 {σ}_{ℳ \overline{B} ( t )}}{ℳ ( t ) \cdot \overline{B} ( t )}$$

$${σ}_{ℳ \overline{B} ( t )} = cov ( ℳ ( t ) , \overline{B} ( t ) ) = 𝔼 [ ℳ ( t ) \cdot \overline{B} ( t ) ] - 𝔼 [ ℳ ( t ) ] \times 𝔼 [ \overline{B} ( t ) ] \approx 0 .$$

The number distribution of RS nanodomains can be approximated by a Gaussian distribution:

$${N}_{m , i} ( t ) ∼ ℕ ( {M}_{i} ( 0 ) {p}_{i} ( t ) {μ}_{B} , [ \frac{{σ}_{{ℳ}_{i} ( t )}^{2}}{{{ℳ}_{i} ( t )}^{2}} + \frac{{σ}_{\overline{B} ( r )}^{2}}{{μ}_{B}^{2}} ] {{N}_{m , i} ( t )}^{2} )$$

Combining with the above, we have

$${N}_{m , i} ( t ) ∼ ℕ ( {N}_{m , i} ( 0 ) {P}_{i} ( t ) , {P}_{i} ( t ) ( 1 - {P}_{i} ( t ) ) {μ}_{B} {N}_{m , i} ( 0 ) + \frac{{σ}_{B}^{2}}{{μ}_{B}} {N}_{m , i} ( 0 ) {P}_{i} ( t ) )$$

The total number of RS nanodomains at time t can be calculated as:

$${N}_{m} ( t ) = \sum {N}_{m , i} ∼ ℕ ( \sum {N}_{m , i} ( 0 ) {P}_{i} ( t ) , \sum [ {P}_{i} ( t ) ( 1 - {P}_{i} ( t ) ) {μ}_{B} {N}_{m , i} ( 0 ) + \frac{{σ}_{B}^{2}}{{μ}_{B}} {N}_{m , i} ( 0 ) {P}_{i} ( t ) ] )$$

The fraction of RS nanodomains in a sample, denoted as FR, can be calculated using the equation:

$$FR ( t ) = \frac{{N}_{m} ( t )}{{N}_{m} ( 0 )}$$

According to the above, the distribution of FR(t) follows a Gaussian distribution expressed as:

$$FR ( t ) ∼ ℕ ( \frac{\sum {N}_{m , i} ( 0 ) {P}_{i} ( t )}{{N}_{m} ( 0 )} , \frac{\sum [ {P}_{i} ( t ) ( 1 - {P}_{i} ( t ) ) {μ}_{B} {N}_{m , i} ( 0 ) + \frac{{σ}_{B}^{2}}{{μ}_{B}} {N}_{m , i} ( 0 ) {P}_{i} ( t ) ]}{{{N}_{m} ( 0 )}^{2}} )$$

During experiments, this random-cluster-based phase transformation results in intrinsic fluctuations in the measurement of FR as a function of time. This intrinsic experimental error can be quantified as |FR(t)−F̅R̅(̅t̅)̅|)|, where FR(t) represents the ergodic mean of FR(t).

Our experimental setup has a detection limit of 0.1%. The probability of detecting intrinsic experimental errors caused by random cluster reactions using our setup can be expressed as:

$$Pr ( \vert FR ( t ) - \overline{FR ( t )} \vert > 0. 001 ) = 1 - {\int }_{\overline{FR ( T )} - 0.001}^{\overline{FR ( T )} + 0.001} \frac{1}{{σ}_{Frct} \sqrt{2 π}} {e}^{- \frac{1}{2} {( \frac{x - \overline{FR ( t )}}{{σ}_{Frct}} )}^{2}} dx = erfc ( \frac{0.001}{\sqrt{2} {σ}_{FR}} )$$

Because 0≤Pᵢ(t)≤1 thus

$$0 \leq {σ}_{FR} \leq \sqrt{\frac{0.25 {μ}_{B} + \frac{{σ}_{B}^{2}}{{μ}_{B}}}{{N}_{m} ( 0 )}} ,$$

and then we have

$$Pr ( \vert FR ( t ) - \overline{FR ( t )} \vert > 0. 001 ) = erfc ( \frac{0.001}{\sqrt{2} {σ}_{Frct}} ) < erfc ( \frac{0.001}{\sqrt{2}} \sqrt{\frac{{N}_{m} ( 0 )}{0.25 {μ}_{B} + \frac{{σ}_{B}^{2}}{{μ}_{B}}}} )$$

In our experiments, Nₘ(0)˜10¹³, 0≤P(t)≤1, and μ_{B}≤800. Using exaggerated values of μ_{B}=800 and σ_{B}=800, we have Pr(|FR(t)−F̅R̅(̅t̅)̅|≥0.001)=2.95×10⁻²¹⁷⁴, or about 1 in 3.39×10²¹⁷³

This p-value corresponds to a statistical significance of approximately 100 σ, indicating that it is statistically impossible to detect the intrinsic experimental errors (i.e., fluctuations of FR(t) over the detection limit of 0.1%). This suggests that the intrinsic experimental standard deviation in our measurements is negligible. It is worth noting that a result with a statistical significance of 5 σ is widely accepted as indicating a high likelihood that a bump in the data is caused by a new phenomenon rather than a statistical fluctuation. In our experiments, the statistical significance of detecting intrinsic experimental errors far exceeds 5 σ, further confirming the exceptionally high statistical robustness and reliability of our methodology.

Then, we have:

$$FR ( t ) = \sum [ {P}_{i} ( t ) ( \frac{{N}_{m , i} ( 0 )}{{N}_{m} ( 0 )} ) ]$$

According to assumption 5, the occurrence of inter-cluster phase-transition events is statistically independent of each other. We can define a heat operator to describe the evolution of clusters with varying activation energies during the heating treatment at each step:

H(Eₐ,Tₓ,tₓ)=e^{-k}^{ₓ}^{t}^{ₓ}: the heat operator at Step x
where

$${k}_{X} = ( {Ae}^{- \frac{{E}_{a}}{{k}_{B} {T}_{x}}} ) [ {( {e}^{- \frac{{E}_{sw}}{{k}_{B} {T}_{x}}} )}^{S ( {T}_{x} )} ] and S ( {T}_{x} ) = \frac{1 - erf ( K * ε \text{*)}}{1 + erf ( K * ε \text{*)}}$$

Tₓ: Temperature at step x, tₓ: heating treatment time, k_{B}: Boltzmann constant, Eₐ: activation energy for phase transition, A: pre-exponential factor for the phase transformation constant; E_{sw}: switching energy; ε*: reduced Temperature

$$( ε *= \frac{{T}_{i} - T *}{T *} ) ,$$

where T* switching temperature; K*: a proportionality constant.

The exponential of the switch term, S(T), exhibits extreme sensitivity to temperature as the system temperature approaches the switch temperature. At this switch temperature, S(T) undergoes a sharp transition from infinity to 0, causing the switch term to transition from 0 to 1. Below the switch temperature, the thermally triggered Arrhenius solid-solid phase transition is “frozen” (or halted) as the reaction constant, k, becomes zero. Above the switch temperature, the switch term becomes 1, and the reaction constant, k, is determined solely by the Arrhenius term of the solid-solid phase transformation.

One potential candidate for this switch effect is the brittle-ductile transition. When the temperature exceeds the brittle-ductile transition point, the material's atoms can undergo collective movements and rearrangements facilitated by slip systems. Slip occurs when atomic planes in the crystal lattice shift relative to each other, enabling plastic deformation. This, in turn, activates thermally activated Arrhenius nucleation pathways.

Before heating treatments, the cluster activation energy (Eₐ^{C}) would follow some distribution: Ψ₀(Eₐ). After n (from 1 to n) heating treatments, the original distribution function Ψ₀(Eₐ) becomes Ψₙ(Eₐ), and can be calculated as:

$${Ψ}_{1} ( {E}_{a} ) = H ( {E}_{a} , {T}_{1} , Δ {t}_{1} ) \times {Ψ}_{0} ( {E}_{a} )$$

$${Ψ}_{2} ( {E}_{a} ) = H ( {E}_{a} , {T}_{2} , Δ {t}_{2} ) \times {Ψ}_{1} ( {E}_{a} )$$

$${Ψ}_{i} ( {E}_{a} ) = H ( {E}_{a} , {T}_{i} , Δ {t}_{i} ) \times {Ψ}_{i - 1} ( {E}_{a} )$$

$${Ψ}_{n} ( {E}_{a} ) = {\prod }_{i = 1}^{n} [ H ( {E}_{a} , {T}_{i} , {t}_{i} ) ] \times {Ψ}_{0} ( {E}_{a} )$$

The molar fraction of retained RS nanodomain after each heating treatments could be calculated as:

$${FR}_{n} = 〈 {\hat{H}}_{N} {Ψ}_{0} ( {E}_{a} ) 〉 = \frac{{\int }_{0}^{∞} {Ψ}_{n} ( {E}_{a} ) {dE}_{a}}{{\int }_{0}^{∞} {Ψ}_{0} ( {E}_{a} ) {dE}_{a}}$$

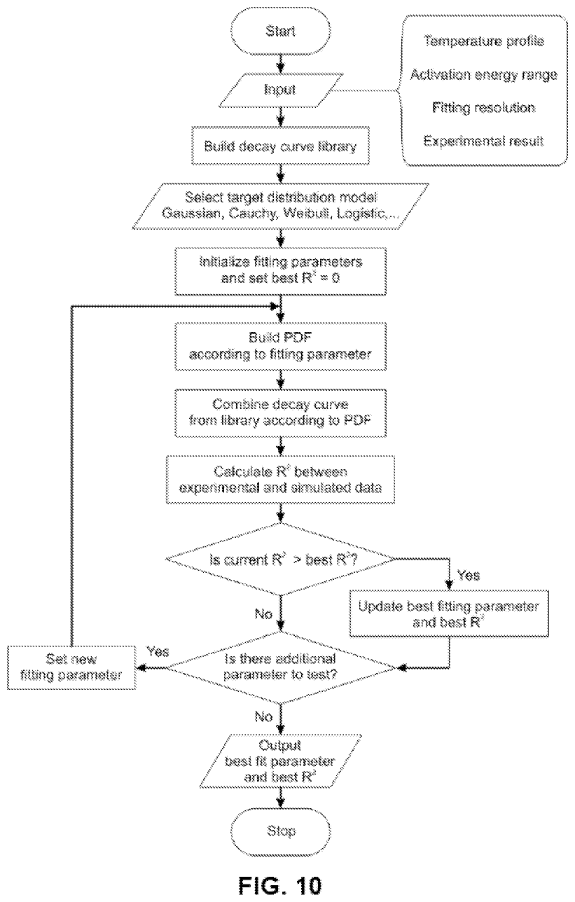

Based on the coarse-grained analysis, a computer program was developed to simulate the activation energy distribution of experimental results. The flow chart is shown in FIG. 10. A fitting coefficient R² is used to determine the fitting level, and is calculated as:

$${R}^{2} = 1 - \frac{{SS}_{res}}{{SS}_{tot}}$$

where SSᵣₑₛ=Σ(FR_{x,exp}−FR_{x,sim})², and SSₜₒₜ=Z(FR_{x,exp}−F̅R̅_{x,exp})². With the program, different distribution models were tested, and found for most of experimental data, Gaussian distribution exhibited the best R² among the four target distribution models tested (Table 7). The simulated Gaussian distribution parameters are displayed in Tables 3-4.

TABLE 6
Simulated R² for different samples with different target distribution model.

| | | Highest | | | | |
|---|---|---|---|---|---|---|
| | | pressure | | R² | | |
| | Surface | applied | | Gaussian | Cauchy | Logistic |
| Nanocrystal | ligand | (GPa) | Special note | distribution | distribution | distribution |
| 4.8-nm CdS | Octylamine | 14.3 | | 0.9983 | 0.9866 | 0.9967 |
| nanosphere | (N₂H₅)₄Sn₂S₆ | 15.8 | | 0.9976 | 0.9837 | 0.9955 |
| | (NH₄)₂S | 14.7 | | 0.9999 | 0.9983 | 0.9999 |
| | (NH₄)₂S | 14.9 | +Cd(NO₃)₂ | 0.9985 | 0.9866 | 0.9964 |
| | (NH₄)₂S | 15.2 | +Ca(NO₃)₂ | 0.9993 | 0.9913 | 0.9977 |
| 8-nm CdS | Octylamine | 15.5 | | 0.9985 | 0.9866 | 0.9962 |
| nanosphere | (N₂H₅)₄Sn₂S₆ | 21.0 | | 0.9985 | 0.9925 | 0.9987 |
| | (N₂H₅)₄Sn₂S₆ | 15.3 | | 0.9967 | 0.9835 | 0.9933 |
| | (N₂H₅)₄Sn₂S₆ | 15.7 | +C8-SH | 0.9997 | 0.9923 | 0.9992 |
| | (NH₄)₂S | 15.6 | | 0.9999 | 0.9910 | 0.9995 |
| | (NH₄)₂S | 15.9 | +Cd(NO₃)₂ | 0.9996 | 0.9965 | 0.9994 |
| | (NH₄)₂S | 15.8 | +Ca(NO₃)₂ | 0.9951 | 0.9903 | 0.9922 |
| 4.8-nm | Octylamine | 10.5 | | 0.9979 | 0.9890 | 0.9970 |
| CdSe/CdS | Octylamine | 10.8 | Detailed | 0.9978 | 0.9722 | 0.9953 |
| nanosphere | | | heating | | | |
| | Octylamine | 15.1 | | 0.9993 | 0.9705 | 0.9994 |
| | (N₂H₅)₄Sn₂S₆ | 14.8 | | 0.9997 | 0.9979 | 0.9996 |
| 8-nm | Octylamine | 14.1 | | 0.9992 | 0.9949 | 0.9994 |
| CdSe/CdS | (N₂H₅)₄Sn₂S₆ | 14.4 | | 0.9991 | 0.9970 | 0.9991 |
| nanosphere | | | | | | |
| 23.8-nm | Octylamine | 7.3 | | 0.9976 | 0.9919 | 0.9953 |
| CdSe/CdS | Octylamine | 8.3 | | 0.9999 | 0.9942 | 0.9967 |
| nanorods | Octylamine | 10.5 | | 0.9993 | 0.9907 | 0.9958 |
| | Octylamine | 13.5 | | 0.9994 | 0.9893 | 0.9937 |
| | Octylamine | 14.5 | | 0.9973 | 0.9928 | 0.9932 |
| | Octylamine | 18.2 | | 0.9984 | 0.9885 | 0.9943 |
| | (N₂H₅)₄Sn₂S₆ | 16.8 | | 0.9977 | 0.9932 | 0.9959 |
| 24.5-nm | Octylamine | 10.8 | | 0.9968 | 0.9888 | 0.9962 |
| CdS/CdS | Octylamine | 15.1 | | 0.9978 | 0.9911 | 0.9976 |
| nanorods | (N₂H₅)₄Sn₂S₆ | 15.5 | | 0.9965 | 0.9991 | 0.9967 |

highlighted are the R² best fit distribution model.

### Fine-Grained Analysis

### Continuous Time Markov Chain

Fine-grained analysis was performed with Continuous Time Markov Chain process (CTMC). A system of n nanocrystals undergo RS-to-ZB phase transition can be described by CTMC. In the system, the probability that each nanocrystal undergoes a RS-to-ZB phase transformation reaction from time t→t+Δt follows the first postulate of statistical mechanics, specifically that the probability is solely dependent on the activation energy Ea of each nanocrystal and the temperature T at time t. Each particle exists in only two possible states: RS or ZB, therefore, there exists a total of 2ⁿ states in a n-nanocrystal system. We can label the state as s_{i,j}, where i describes the number of nanocrystals in the ZB phase (0<i<n), and j describes the configuration of this combination

$$( 1 \leq j \leq ( \begin{matrix}n \\ i\end{matrix} ) ) .$$

The state probability vector at time t can be written as:

$$π ( t ) = [ \begin{matrix}{P}_{0 , 1} ( t ) & {P}_{1 , 1} ( t ) & … & {P}_{n , 1} ( t )\end{matrix} ]$$

where P_{i,j}(t)≡P(S(t)=s_{i,j}) is the probability that the system exhibits state S=s_{i,j} at time t, and

$${\sum }_{i = 0}^{n} {\sum }_{j = 1}^{( \begin{matrix}n \\ i\end{matrix} )} {P}_{i , j} ( t ) = 1.$$

At time t+Δt, the probability of the system exhibiting state S=s_{i,j} can be written as:

$${P}_{i , j} ( t + Δ t ) = P ( S ( t + Δ t ) = {s}_{i , j} ) = {\sum }_{α = 0}^{i} {\sum }_{β = 1}^{{(}_{α}^{n} )} P ( S ( t ) = {s}_{α , β} ) {P}_{α , β \vert i , j} ( S ( t ) = {s}_{α , β} \vert S ( t ) = {s}_{i , j} )$$

where P_{α,β|i,j}(S(t)=s_{α,β}|S(t)=s_{i,j}) is the probability of transition from state s_{α,β} to s_{i,j} from time t→t+Δt, and

$${\sum }_{i = 0}^{n} {\sum }_{j = 1}^{( \begin{matrix}n \\ i\end{matrix} )} {P}_{α , β \vert i , j} ( S ( t ) = {s}_{α , β} \vert S ( t ) = {s}_{i , j} ) = 1 .$$

The above equation can be written in the form of a matrix equation:

$$π ( t ) = π ( 0 ) \cdot P ( t )$$

where the transition probability matrix P(t) has dimensions of 2ⁿ×2ⁿ.

$$P ( t ) = [ \begin{matrix}{P}_{0 , 1 \vert 0 , 1} & {P}_{0 , 1 \vert 1 , 1} & ⋯ & {P}_{0 , 1 \vert n , 1} \\ {P}_{1 , 1 \vert 0 , 1} & {P}_{1 , 1 \vert 1 , 1} & ⋯ & {P}_{1 , 1 \vert n , 1} \\ ⋯ & ⋯ & ⋯ & ⋯ \\ {P}_{n , 1 \vert 0 , 1} & {P}_{n , 1 \vert 1 , 1} & ⋯ & {P}_{n , 1 \vert n , 1}\end{matrix} ]$$

The transition probability matrix could be solved by the following equation, a first-order differential equation:

$$\frac{dP}{dt} = P \cdot Q$$

where Q is the transition rate matrix with a dimension of 2ⁿ×2ⁿ, Qij is the transition rate constant from state xᵢ to xⱼ, and

$${\sum }_{i = 0}^{n} {\sum }_{j = 1}^{( \begin{matrix}n \\ i\end{matrix} )} {k}_{α , β \vert i , j} = 0.$$

$$Q = [ \begin{matrix}{k}_{0 , 1 \vert 0 , 1} & {k}_{0 , 1 \vert 1 , 1} & ⋯ & {k}_{0 , 1 \vert n , 1} \\ {k}_{1 , 1 \vert 0 , 1} & {k}_{1 , 1 \vert 1 , 1} & ⋯ & {k}_{1 , 1 \vert n , 1} \\ ⋯ & ⋯ & ⋯ & ⋯ \\ {k}_{n , 1 \vert 0 , 1} & {k}_{n , 1 \vert 1 , 1} & ⋯ & {k}_{n , 1 \vert n , 1}\end{matrix} ]$$

To be noted, in an irreversible RS-to-ZB reaction system, k_{α,β|i,j}=0 when α+1≠i; k_{α,β|i,j}≥0 when α+1=i; and k_{α,β|i,j}<0 when α=i and β≠j. Therefore, transition rate matrix Q can be simplified as follows:

$$Q = [ \begin{matrix}- {\sum }_{i = 2}^{{2}^{n}} {\sum }_{j = 1}^{( \begin{matrix}n \\ i\end{matrix} )} {k}_{0 , 1 \vert i , j} & {k}_{0 , 1 \vert 1 , 1} & ⋯ & 0 \\ 0 & - {\sum }_{i = 2}^{{2}^{n}} {\sum }_{j = 1}^{( \begin{matrix}n \\ i\end{matrix} )} {k}_{1 , 1 \vert i , j} & ⋯ & 0 \\ ⋯ & ⋯ & ⋯ & ⋯ \\ 0 & 0 & ⋯ & 0\end{matrix} ]$$

The elements in transition rate matrix Q, k_{α,β|i,j}, are the reaction rate constants from state s_{α,β} to s_{i,j}, which can be calculated by the activation energy of transition

$$( {E}_{{a}_{α , β \vert i , j}} ) :$$

$${k}_{i \vert j} = {Ae}^{- \frac{{E}_{{a}_{α , β \vert i , j}}}{{k}_{B} T}}$$

From the previous definition:

$$π ( t ) = π ( 0 ) \cdot P ( t )$$

We can derive that:

$$\frac{d π ( t )}{dt} = π ( 0 ) \frac{dP}{dt} = π ( 0 ) \cdot P \cdot Q = π ( t ) \cdot Q$$

$$Or$$

$$\frac{d [ \begin{matrix}{P}_{0 , 1} ( t ) & {P}_{1 , 1} ( t ) & … & {P}_{n , 1} ( t )\end{matrix} ]}{d r} = [ \begin{matrix}{P}_{0 , 1} ( t ) & {P}_{1 , 1} ( t ) & … & {P}_{n , 1} ( t )\end{matrix} ] \cdot [ \begin{matrix}- {\sum }_{i = 2}^{{2}^{n}} {\sum }_{j = 1}^{( \begin{matrix}n \\ i\end{matrix} )} {k}_{0 , 1 \vert i , j} & {k}_{0 , 1 \vert 1 , 1} & ⋯ & 0 \\ 0 & - {\sum }_{i = 2}^{{2}^{n}} {\sum }_{j = 1}^{( \begin{matrix}n \\ i\end{matrix} )} {k}_{1 , 1 \vert i , j} & ⋯ & 0 \\ ⋯ & ⋯ & ⋯ & ⋯ \\ 0 & 0 & ⋯ & 0\end{matrix} ]$$

With the state probability matrix, the expected number of nanocrystals retained in RS phase at time t can be calculated as:

$$< n > ( t ) = {\sum }_{i = 0}^{n} [ ( n - i ) {\sum }_{j = 1}^{( \begin{matrix}n \\ i\end{matrix} )} {P}_{i , j} ]$$

Where N_{i,j}=n−i is the number of nanocrystals retained in RS phase for state s_{i,j}. The fraction of nanocrystals retained in RS phase can be calculated as:

$$Frct ( t ) = \frac{< n > ( r )}{n} = {\sum }_{i = 0}^{n} [ \frac{n - i}{n} {\sum }_{j = 1}^{( \begin{matrix}n \\ i\end{matrix} )} {P}_{i , j} ]$$

### Topology Expression in State-Space

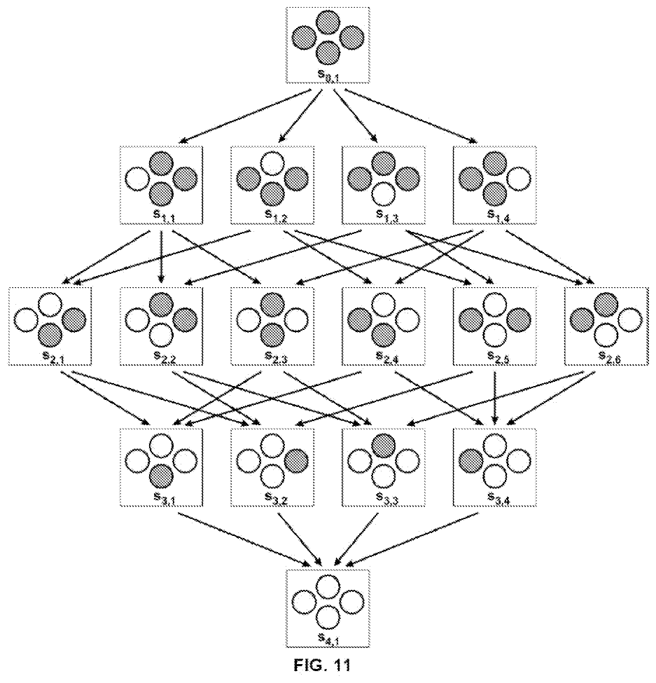

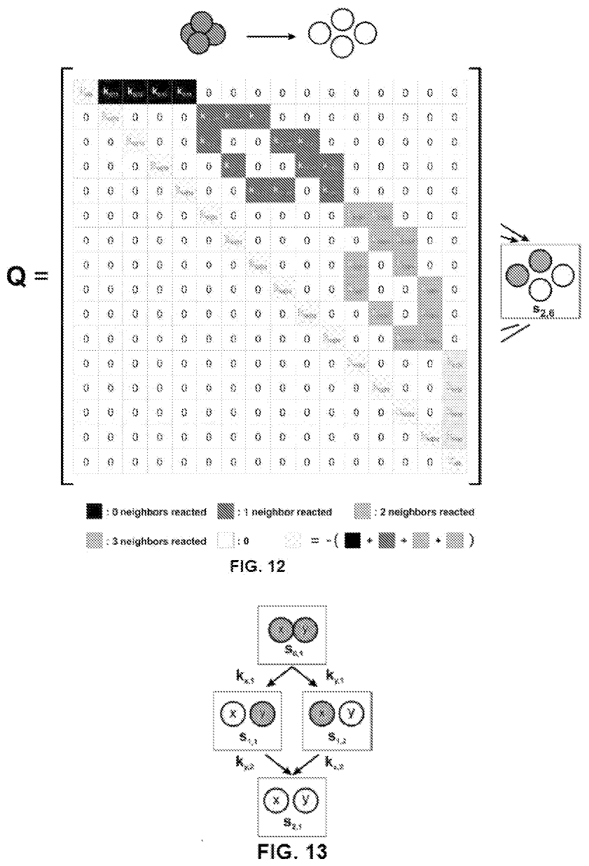

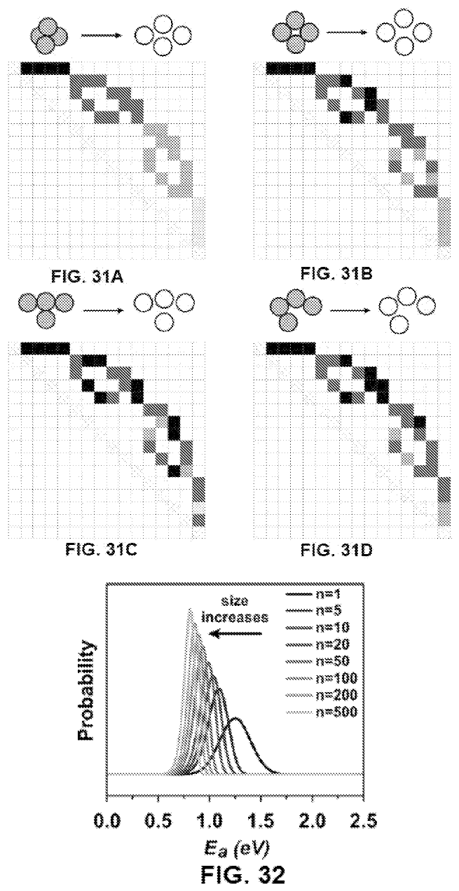

The discussion of the previous CTMC model is based on a “state-space” of a nanodomain cluster, that the topology of the cluster would significantly affect the CTMC transition rate matrix Q. Here is an example of the conversion from real-space to state-space. FIG. 11 is a state space of a 4-nanodomain system, exhibiting a total of 16 states and 32 transitions. When considering the reaction impact from neighboring nanodomains, in FIG. 12 representing the transition rate matrix of this configuration in a graph. When the topology of these four nanodomains changes, the transition rate matrix Q change accordingly (FIGS. 31A-31D).

### The Effect of Reaction Impact Δ

There exists reaction impact between neighboring nanocrystals, defined as Δ. For reaction from one state to another state, A is a random variable depending on the topology of the nanocrystal network inside the cluster. The apparent reaction impact Δu can be calculated by the geometric mean of all Δ in the cluster:

$${Δ}_{u} = {( {\prod }_{i = 1}^{ε} {Δ}_{i} )}^{\frac{1}{ε}}$$

where ε is the total number of GTBs, and Δi is the reaction impact for each GTBs on one direction (the reaction impact is not symmetric on the two domains on the two side of GTBs). To be noted, Δ has a distribution related the topology of the cluster in its real space. When the distribution of Δ is narrow, Δᵤ is a good approximation to the system; when the distribution of Δ is wide, Δu might introduce some systematic error in the following calculations.

In the Markov chain, at the beginning of the reaction (t=0), all nanocrystals are in RS phase and the boundary condition for above is π(0)=[1 0 . . . 0]. During the transition, only the first step of the reactions follows the initial activation energy of each nanocrystal, while the following steps follow the post-impact activation energy.

From a previous equation, P_{0,1}(t) can be described by the following differential equation:

$$\frac{{dP}_{0 , 1}}{dt} = - ( {\sum }_{i = 1}^{n} {k}_{0 , 1 \vert 1 , i} ) {P}_{0 , 1}$$

Solving this results in:

$${P}_{0 , 1} = {e}^{- ( {\sum }_{i = 1}^{n} {k}_{0 , 1 \vert 1 , i} ) t}$$

where

$${k}_{0 , 1 \vert 1 , i} = {Ae}^{- \frac{{E}_{{a}_{i}}}{{k}_{B} T}} ,$$

and Eaⁱ is the activation energy for the i-th nanodomain. Since there is no Δ term in k_{0,1|1,i} we get:

$$\frac{{dk}_{0 , 1 \vert 1 , i}}{d {Δ}_{u}} = 0$$

The elements P_{1,1}(t) to P_{n-1,n}(t) in the state probability matrix can be solved by the differential equation:

$$\frac{{dP}_{x , y}}{dt} = {\sum }_{j = 1}^{( \begin{matrix}n \\ x - 1\end{matrix} )} ( {k}_{x - 1 , f \vert x , y} \cdot {P}_{x - 1 , j} ) - [ {\sum }_{j = 1}^{( \begin{matrix}n \\ x + 1\end{matrix} )} {k}_{x , y \vert x + 1 , j} ] {P}_{x , y}$$

where

$$( \begin{matrix}n \\ x\end{matrix} )$$

is the number of total possible configurations with x nanodomains in ZB phase. Note that when x>2, k_{x-1,r|x,s} is a function of Δu, and can be written as

$${k}_{x - 1 , r \vert x , s} = {Ae}^{- \frac{{E}_{{a}_{α , β \vert i , j}^{*}}}{{k}_{B} T}} = {Ae}^{- \frac{{E}_{{a}_{α , β \vert i , j}^{0} - {Δ}^{*}}}{{k}_{B} T}} = {k}_{x - 1 , r \vert x , s}^{0} {e}^{\frac{{Δ}^{*}}{{k}_{B} T}}$$

where Δ*=f(Δᵤ) is the combined reaction k_{x-1,r|x,s} monotonically increases as Au increases, or:

$$\frac{{dk}_{x - 1 , r \vert x , s}}{d {Δ}_{u}} > 0$$

And the last element in the state probability vector, P_{n,1}(t) can be calculated by probability conservation:

$${P}_{n , 1} = 1 - {\sum }_{i = 0}^{n} {\sum }_{j = 1}^{( \begin{matrix}n \\ i\end{matrix} )} {P}_{i , j}$$

An earlier equation can be simplified as:

$$\frac{{dP}_{x , y}}{dt} = m ( t ) - {k}_{x , y}^{*} {P}_{x , y}$$

$$where m ( t ) = {\sum }_{i = 1}^{( \begin{matrix}n \\ x - 1\end{matrix} )} ( {k}_{x - 1 , i \vert x , y} \cdot {P}_{x - 1 , i} ) , and {k}_{x , y}^{*} = {\sum }_{j = 1}^{( \begin{matrix}n \\ x + 1\end{matrix} )} {k}_{x , y \vert x + 1 , j} .$$

This equation can be solved as:

$${P}_{x , y} ( t ) = {P}_{x , y} ( 0 ) {e}^{- {k}_{x , y}^{*} t} + {\int }_{0}^{t} {e}^{- {k}_{x , y}^{*} ( t - u )} m ( u ) du$$

Since the probability of the s0,1 state can be calculated as P_{0,1}=e−(Σᵢ₌₁ⁿk_{0,1|1,i})^{t}, therefore the probability of states with only one nanocrystal in ZB phase (s_{1,α}) can be calculated as

$${P}_{1 , α} ( t ) = \frac{{\sum }_{i = 1}^{( \begin{matrix}n \\ 2\end{matrix} )} {k}_{1 , α \vert 2 , i}}{{\sum }_{i = 1}^{( \begin{matrix}n \\ 2\end{matrix} )} {k}_{1 , α \vert 2 , i} - {\sum }_{i = 1}^{n} {k}_{0 , 1 \vert 1 , i}} [ {e}^{- ( {\sum }_{i = 1}^{n} {k}_{0 , 1 \vert 1 , i} ) t} - {e}^{- ( {\sum }_{i = 1}^{( \begin{matrix}n \\ 2\end{matrix} )} {k}_{1 , α \vert 2 , i} ) t} ]$$

where

$$1 \leq α \leq ( \begin{matrix}n \\ 1\end{matrix} ) .$$

We can thus conclude that when

$$1 \leq α \leq ( \begin{matrix}n \\ 1\end{matrix} )$$

$$\frac{{dP}_{1 , α}}{d Δ} < 0$$

Assuming for P_{β,s}, where

$$1 < s < ( \begin{matrix}n \\ β\end{matrix} ) , that \frac{{dP}_{β , s}}{d Δ} < 0 ,$$

P_{β+1,r} can be calculated by the differential equation:

$$\frac{{dP}_{β + 1 , r}}{dt} = {\sum }_{i = 1}^{( \begin{matrix}n \\ β\end{matrix} )} ( {k}_{β , i \vert β + 1 , r} \cdot {P}_{β , i} ) - [ {\sum }_{j = 1}^{( \begin{matrix}n \\ β + 2\end{matrix} )} {k}_{β , r \vert β + 1 , j} ] {P}_{β + 1 , r}$$

As described previously,

$${P}_{β + 1 , r} ( t ) = {P}_{β + 1 , r} ( 0 ) {e}^{- {k}_{β + 1 , r}^{*} t} + {\int }_{0}^{t} {e}^{- {k}_{β + 1 , r}^{*} ( t - u )} m ( u ) du$$

$$Since m ( t ) = {\sum }_{i = 1}^{( \begin{matrix}n \\ β\end{matrix} )} ( {k}_{β , i \vert β + 1 , r} \cdot {P}_{β , i} ) and {k}_{β + 1 , r}^{*} = {\sum }_{j = 1}^{( \begin{matrix}n \\ β + 2\end{matrix} )} {k}_{β , r \vert β + 1 , j} ,$$

$$then \frac{dm ( t )}{d {Δ}_{u}} < 0 and \frac{{k}_{β + 1 , r}^{*}}{d {Δ}_{u}} > 0.$$

Therefore we have

$$\frac{{dP}_{β + 1 , r} ( t )}{d {Δ}_{u}} < 0.$$

By mathematical induction, we can conclude that when

$$1 \leq x \leq n$$

$$\frac{{dP}_{x , y} ( t )}{d {Δ}_{u}} < 0$$

With above equations, the fraction of nanocrystals retained in RS phase monotonically decreases as reaction impact Δᵤ increases:

$$\frac{d ( Frct )}{d {Δ}_{u}} < 0$$

Then, the fraction of RS phase retained also monotonically decreases as the reaction impact Δi increases:

$$\frac{d ( Frct )}{d {Δ}_{i}} < 0$$

When Δu=0, the reaction system can be simplified by a collection of multiple first-order reactions happening independently, that:

$$Frct ( t , {Δ}_{u} = 0 ) = \frac{1}{n} {\sum }_{i = 1}^{n} {e}^{- \frac{{E}_{a}}{{k}_{B} T}}$$

Additionally, by equations above, we can find that for 0<x<n, when Δᵤ=∞:

$${P}_{x , y} ( t ) = 0 and \frac{d {P}_{x , y} ( t )}{d {Δ}_{u}} = 0$$

Under such conditions, the CTMC system is a winner-take-all (WTA) system, that only one nanocrystal can initiate the reaction, and instantly propagate through the whole cluster. The fraction of nanocrystals retained in RS phase can be calculated as:

$$Frct ( t , {Δ}_{u} = ∞ ) = {P}_{0 , 1} = {e}^{- ( {\sum }_{i = 1}^{n} {k}_{0 , 1 \vert 1 , i} ) t}$$

Which can be described as a first-order reaction system with parallel reaction pathway, and the apparent activation energy of this system is:

$${E}_{a , apparent} = {k}_{B} T \times ln ( {\sum }_{i = 1}^{n} {e}^{- \frac{{E}_{a , i}}{{k}_{B} T}} )$$

In our experiment, the sample undergoes a stepwise heating treatment, and the RS phase percentage was measured after each heating. In such treatment, temperature can be considered as a function of time, T(t), and universal for a sample in simulation an example is shown in FIGS. 5A-5B). Since the transition rate constant

$${k}_{α , β \vert i , j} = {Ae}^{- \frac{{{E}_{a}}_{α , β \text{?}}^{*}}{{k}_{B} T}} ,$$

$$\text{?} \text{indicates text missing or illegible when filed}$$

therefore, as the increase of A from zero to infinite leads to the converging of each datapoint from independent model a WTA model monotonically, uniformly, continually. Both independent model and WTA model can be described as a group of first-order reaction systems giving an apparent activation energy distribution. Uniform convergence is a special class of convergence that preserves the continuity, integrability, and differentiability of the constituent function. Therefore, for any reaction impact Δ, the decay curve can be fitted by a first-order reaction system with activation energy distribution, and such activation energy distribution is the apparent activation energy distribution of this cluster. It can be found that the coupled WTA model shows a lower apparent activation energy distribution mean and standard deviation compared to an independent reaction system. Therefore, the mean and sigma of apparent activation energy distribution monotonically decreasing with the increase of reaction impact Δ.

### WTA Distribution Calculation

In a cluster for which the activation energy for each nanocrystal follows the initial distribution, the stepwise heating decay curve can be simulated for independent reaction model with a heat operator, as described previously. For the WTA model, the apparent activation energy distribution can be approximated as follows:

From a previous equation, we can find that when one nanocrystal has a significantly smaller activation energy Eamin, the apparent activation energy can be approximate as Eaₐₚₚₐᵣₑₙₜ=Eₐₘᵢₙ. When multiple nanodomains show the same minimum activation energy in the cluster, the apparent activation energy is Eaₐₚₚₐᵣₑₙₜ=Eₐₘᵢₙ−k_{B}Tln(m), where m is the multiplicity of the nanodomain showing the minimum activation energy in the cluster. Because the activation energy of each nanodomain follows an initial distribution, multiple nanodomains showing identical activation energy is very less likely to happen statistically, which can be ignored in this discussion. A cluster showing activation energy larger than Eax can only happen when all nanodomains within this cluster exhibit activation energy larger than Eax, the probability can be calculated as:

$$P ( {E}_{{a}_{apparent}} > {E}_{{a}_{x}} ) = {P ( {E}_{{a}_{nanodomain}} > {E}_{{a}_{x}} )}^{n}$$

Because the initial activation energy and apparent activation energy is continuously distributed, we can have cumulative distribution function (CDF) calculated as: CDF(Eₐ_{ₓ})=1−P(Eₐ>Eₐ_{ₓ}). Therefore, the equation can be written as:

$$1 - {CDF}_{cluster} ( {E}_{{a}_{x}} ) = {( 1 - C D {F}_{nanodomain} ( {E}_{{a}_{x}} ) )}^{n}$$

The probability density function can be calculated by derivation of CDF, the probability density function (PDF) of apparent activation energy distribution of cluster with WTA model can be calculated as:

$${PDF}_{c luster} = \frac{{dCDF}_{c luster}}{{dE}_{{a}_{x}}} = n \times {PDF}_{nanodomain} \times {( 1 - {CDF}_{nanodomain} )}^{n - 1}$$

A convolution of WTA apparent activation energy distribution from an initial Gaussian distribution with mean of 1.25 eV and standard deviation of 0.15 eV as size increase is shown in FIG. 32.

### CTMC in a Dimer System

Numerical Simulation with CTMC System with Discrete Activation Energy: In a dimer system with discrete activation energy, the state space is shown in FIG. 13. There exist four states: s_{0,1}, s_{1,1}, s_{1,2}, and s_{2,1} as labeled. The state probability vector can be written as π(t)=[P₀ P₁₁ P₁₂ P₂]. The transition rate constants in FIGS. 30A-30C could be calculated as:

$${k}_{x , 1} = {Ae}^{- \frac{{E}_{a}^{x}}{{k}_{B} T}} , {k}_{x , 2} = {Ae}^{- \frac{{E}_{a}^{x} - {Δ}_{u}}{{k}_{B} T}} , {k}_{y , 1} = {Ae}^{- \frac{{E}_{a}^{y}}{{k}_{B} T}} , {k}_{y , 2} = {Ae}^{- \frac{{E}_{a}^{y} - {Δ}_{u}}{{k}_{B} T}}$$

$$where {Δ}_{u} = {( {Δ}_{a \to b} \times {Δ}_{b \to a} )}^{\frac{1}{2}} .$$

As described previously, the transition rate matrix can be written as:

$$Q = [ \begin{matrix}- ( {k}_{x , 1} + {k}_{y , 1} ) & {k}_{x , 1} & {k}_{y , 1} & 0 \\ 0 & - {k}_{y , 2} & 0 & {k}_{y , 2} \\ 0 & 0 & - {k}_{x , 2} & {k}_{x , 2} \\ 0 & 0 & 0 & 0\end{matrix} ]$$

At t=0, with both nanocrystals in RS phase, the boundary condition is π(0)=[1 0 0 0]. From the above, we can have the following differential equation system:

$$\frac{d [ {P}_{0 , 1} {P}_{1 , 1} {P}_{1 , 2} {P}_{2 , 1} ]}{d t} = [ {P}_{0 , 1} {P}_{1 , 1} {P}_{1 , 2} {P}_{2 , 1} ] \cdot [ \begin{matrix}- ( {k}_{x , 1} + {k}_{y , 1} ) & {k}_{x , 1} & {k}_{y , 1} & 0 \\ 0 & - {k}_{y , 2} & 0 & {k}_{y , 2} \\ 0 & 0 & - {k}_{x , 2} & {k}_{x , 2} \\ 0 & 0 & 0 & 0\end{matrix} ]$$

In our experimental setup, the heat was applied as a function of time, as shown below. The measurements were conducted under room temperature, then the samples were transferred back to the oven (The sample achieved temperature equilibrium within 30 s. The XRD measurement time was set as 10 min, FIG. 6). Since activation energy is constant, therefore the reaction rate constant of each state transition can be converted to a function of time, as shown below using Eₐ^{x}=1.20 eV, Eₐ^{y}=1.50 eV, and Δ=0.1 eV as an example.

The above differential equation sets were plotted using the “odeint” function in a Python code, and the probabilities of different states were plotted vs time, shown in FIG. 14. The expected value of nanocrystals remaining in this dimer system could be calculated by the following equation:

$$< n > = 2 \times {P}_{0 , 1} + {P}_{1 , 1} + {P}_{1 , 2}$$

The fraction of nanocrystals retained in RS phase in this dimer system can be calculated as:

$$Frct = \frac{< n >}{2} = {P}_{0 , 1} + \frac{1}{2} ( {P}_{1 , 1} + {P}_{1 , 2} )$$

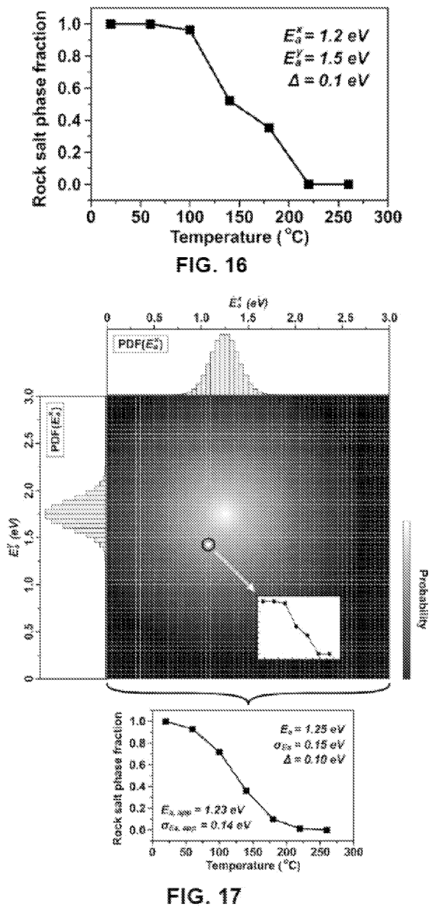

The fraction vs. time curve was shown in FIG. 15. To simulate our experimental data, the percentage of certain time point was extracted from the above curve, and the resulting temperature decay curve for Eₐ^{x}=1.20 eV, Eₐ^{y}=1.30 eV, and Δ=0.1 eV dimer was shown in FIG. 16.

Simulated Decay Curve of a Dimer System with Activation Energy Distribution using CTMC Process: In a dimer system comprising nanocrystals with activation energy distribution, a 2-dimensional library was built (in our program, a 60×60 library, each dimension is from Eₐ=0.05 to 3.0 eV), each component is a decay percentile curve calculated by the above CTMC model following the heating pattern for a dimer system with Eₐ_{^{x}}ᵢ and Eₐ_{^{y}}ⱼ, as shown in FIG. 17. X and Y nanocrystals follow the same activation energy distribution, PDF(Eₐ). The probability of each library element existing in the sample is PDF(Eₐ_{^{x}}ᵢ)×PDF (Eₐ_{^{y}}ⱼ). To calculate the percentage of samples that retain RS phase during the multi-step heating treatment in this dimer system, the previously built library was averaged by the probability weight of each possible combinations, using the following equation:

$$Frct = {\sum }_{\dot{t} = 1}^{60} {\sum }_{j = 1}^{60} PDF ( {E}_{{a}_{i}}^{x} ) PDF ( {E}_{{a}_{j}}^{y} ) {Frct}_{ij}$$

Then this decay curve was approximated by a first order reaction system, as discussed before. The resulting distribution is the apparent activation energy distribution of this dimer system. The apparent activation energy of coupled dimer system was calculated by a Python program.

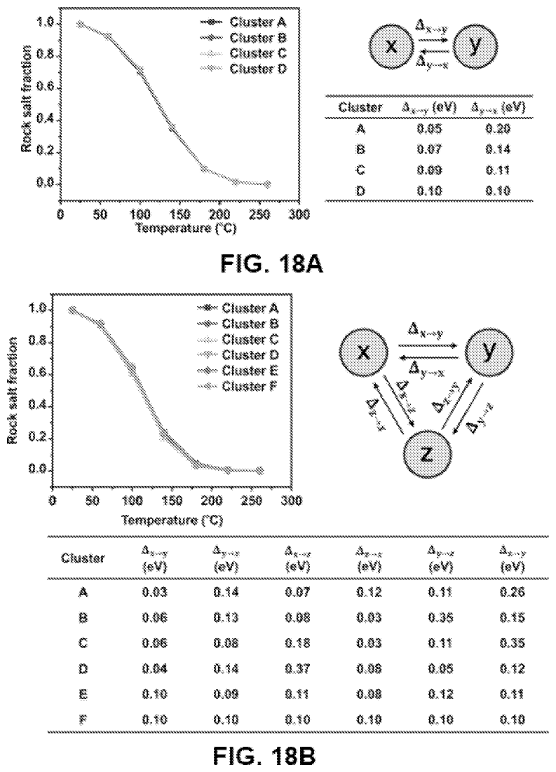

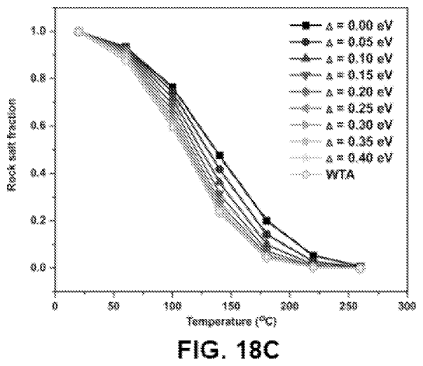

With the program developed, a group of three dimer clusters with random Δ_{x→y}−Δ_{y→x} pairs exhibiting geometric mean of 0.1 eV, as well as a dimer system with Δ_{x→y}−Δ_{y→x}=0.1 eV were simulated. The simulated result is shown in FIG. 18A. It can be found that the geometric mean is a good representation of the heating result of this group of dimer clusters, that the maximum error in this whole series is below 0.015.

A similar program was also developed for trimer system with additional differential equations and additional a dimension compared to dimer system. Note that when a nanodomain has multiple neighbors, the activation energy for this nanodomain is calculated by the initial activation energy minus the sum of impact energy from the reacted neighbors; when the sum of impact energy from reacted neighbors is larger than the initial activation energy of this nanodomain, the activation energy is counted as zero. A group of five trimer systems with random impact energy geometric mean of 0.10 eV, as well as a trimer system with all impact energy of 0.1 eV were simulated (FIG. 18B). The error for timer system is slightly larger than that of a dimer system (0.047), but still showing the geometric mean is a good representation of the topology information.

With the simulation result from dimer and trimer that the geometric mean is a good representation of the topology information of a cluster, in the following discussion, detailed topology information was approximated with a geometric mean of all non-zero impact energies in the cluster.

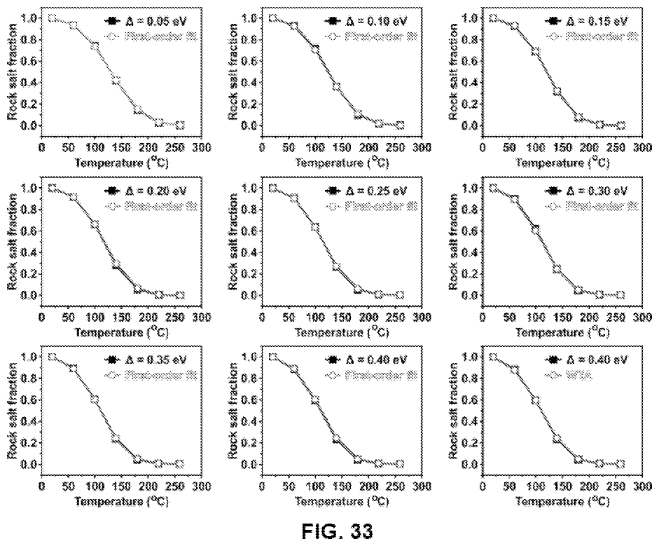

For a given initial X-Y dimer system with initial Gaussian distribution with mean E̅a̅ and variance σ²_{Ea}, and coupled by an impact energy Δ, the coupled decay curve was approximated by a first-order reaction with Gaussian distribution with mean E̅a̅_{fit} and variance σ²_{Eafit}. An initial distribution of E̅a̅=1.25 eV and σ_{Eafit}=0.015 eV was used a demonstration to determine the effect of Δ. When Δ=0, indeed the fitted distribution represents the original distribution, that there exists a network isolator when there is no reaction impact between x and y from both ways. It can be found with increase of Δ, E̅a̅−E̅a̅_{fit} increases and σ²_{Ea}−σ²_{Eafit} decreases, and when Δ>0.3 eV, E̅a̅_{fit} and σ_{Eafit} are stable. Such decay curve was then fitted by the WTA distribution generated from the original distribution, the fitted result showing good agreement between coupled reaction with Δ>0.4 eV and WTA model. The simulated results were shown in FIG. 18C and Table 7. To be noted, the coupled reaction system can be fitted with a first-order reaction system very nicely (FIG. 33).

TABLE 7
Fitted parameters as increase of Δ

| Δ (eV) | E̅_̅{̅α̅}̅_{fit} (eV) | σ_{Eαfit} (eV) | R² |
|---|---|---|---|
| 0.00 | 1.25 | 0.15 | 1.0000 |
| 0.05 | 1.23 | 0.14 | 0.9999 |
| 0.10 | 1.21 | 0.13 | 0.9999 |
| 0.15 | 1.20 | 0.12 | 0.9999 |
| 0.20 | 1.19 | 0.12 | 0.9999 |
| 0.25 | 1.18 | 0.12 | 0.9999 |
| 0.30 | 1.17 | 0.12 | 0.9999 |
| 0.35 | 1.17 | 0.12 | 0.9999 |
| 0.40 | 1.17 | 0.12 | 0.9999 |
| WTA | 1.17 | 0.12 | 0.9999 |

### Cluster Size Distribution, Reaction Impact Distribution

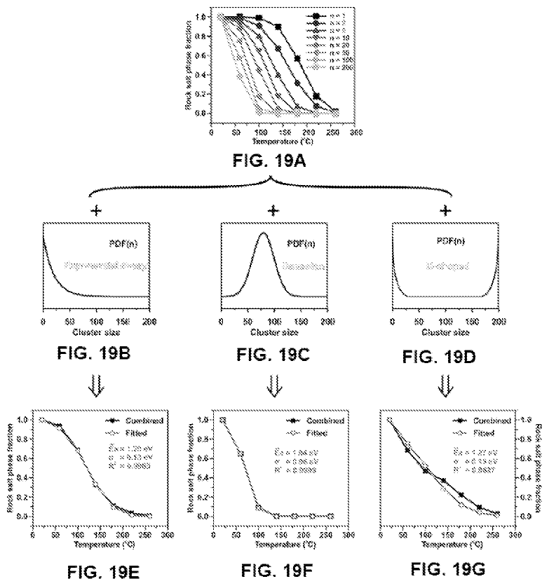

Under an extreme condition, when reaction impact between nanocrystals in a cluster is infinite, the decay curve of these clusters can be approximated by a WTA model with original distribution of E̅a̅=1.40 eV and σ_{Ea}=0.15 eV, the decay curves were shown in FIG. 19A. In the following discussion, three different cluster size distribution types were tested: an exponential decay model, a Gaussian model, or a U-shaped model (FIGS. 19B-19D). The decay curve of these three models were plotted in FIGS. 19E-19G.

The simulation result of size distribution follows exponential-decay or Gaussian distribution type can be fitted by a first-order reaction system with a Gaussian activation energy distribution with R²>0.995, while the U-shaped distribution cannot be fitted with R2>0.995. Therefore, it can be concluded that when reaction impact is large, the cluster size distribution cannot be a U-shape or a bi-model distribution.

Similarly, when the cluster size distribution is narrow in a sample, the reaction impact distribution between clusters should not be a U-shaped distribution, as such would lead to a non-fittable result.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

### REFERENCES

1. Aykol, M. et al. Sci. Adv., 4, eaaq0148 (2018).
2. Azéma, E. et al, Phys. Rev. E. 85, 031303 (2012).
3. Bai, X. M. et al, Science. 327, 1631-1634 (2010).
4. Besson, J. M. et al, Phys. Rev. B. 44, 4214-4234 (1991).
5. Beyerlein, I. J. et al, Prog. Mat. Sci. 74, 125-210 (2015).
6. Bian, K. et al, Nano Lett. 14, 4763-4766 (2014).
7. Brus, L. E. et al, J. Am. Chem. Soc. 118, 4834-4838 (1996).
8. Cao, Y. C. et al, J. Am. Chem. Soc. 126, 14336-14337 (2004).
9. Carbone, L. et al, Nano Lett. 7, 2942-2950 (2007).
10. Chen, C. C. et al, Science. 276, 398-401 (1997).
11. Chen, O. et al, J. Am. Chem. Soc. 133, 17504-17512 (2011).
12. Chen, O. et al, Angew. Chem. Int. Ed. 47, 8638-8641 (2008).
13. Chen, O. et al. Nature Mater. 12, 445-451 (2013).
14. Cullity, B. D. et al, in Elements of x-ray diffractions, (3rd edition, Pearson Hall, New Jersey, 2001).
15. Grunwald, M. et al, Phys. Rev. Lett. 96, 255701 (2006)
16. Grunwald, M. et al, Nano Lett. 13, 1367-1372 (2013).
17. Heitjans, P. et al, Eds, Diffusion in condensed matter: Methods, Materials, Models (2nd edition, Birkhauser, 2005), pp. 1-965.
18. Jacobs, K. et al, Rev. Miner. Geochem. 44, 59-72 (2001).
19. Jacobs, K. et al, J. Phys. Chem. B. 106, 3759-3762 (2002).
20. Jacobs, K. et al. Science. 293, 1803-1806 (2001).
21. Kim, B. H. et al. Science. 368, 60-67 (2020).
22. Koinuma, H. et al, Nature Mater. 3, 429-438 (2004).
23. Krishnaraj, K. P. et al, Phys. Rev. Lett. 124, 198002 (2020).
24. Li, B. et al, Sci. Adv. 3, e1602916 (2017).
25. Li, W. et al, Nano Lett. 14, 4951-4958 (2014).
26. Li, Z. et al, Phys. Status. Solidi. B. 248, 1149-1153 (2011).
27. Lu, K. Nat. Rev. Mater. 1, 16019 (2016).
28. Martin-Rodriguez, R. et al, J. App. Phys. 111, 063516 (2012).
29. McMillan, P. F. Nat. Mater. 1, 19-25 (2002).
30. Meng, L. et al, J. Am. Chem. Soc. 142, 6505-6510 (2020).
31. Mizushima, K. et al, Phys. Rev. B. 50, 14952-14959(1994).
32. Murray, C. B. et al, J. Am. Chem. Soc. 115, 8706-8715 (1993).
33. Ostojic, S. et al, Nature. 439, 828-830 (2006).
34. Parija, A. et al, J. Phys. Chem. C. 122, 25709-25728 (2018).
35. Podsiadlo, P. et al, Nano Lett. 11, 579-588 (2011).
36. Smith, W. F. Principles of Materials Science and Engineering (McGraw-Hill, New York, ed. 3, 1996).
37. Sowa, H. Solid State Sci. 5, 73-78 (2005).
38. Sun, W. et al, Sci. Adv. 2, e1600225 (2016).
39. Tanaka, S. in Materials Chemistry of Ceramics, J. Hojo, Ed. (Springer, Singapore, 2019).
40. Tolbert, S. H. et al, Science. 265, 373-376 (1994).
41. Wang, T. et al, Adv. Mater. 27, 4544-4549 (2015).
42. Wang, Z. et al, Rev. Sci. Instrum. 81, 093902 (2010).
43. Wickham, J. N. et al, Phys. Rev. Lett. 84, 923-926 (2000).
44. Yu, D. et al, Science 300, 1277-1280 (2003).
45. Zaziski, D. et al, Nano Lett. 4, 943-946 (2004)
46. Zhou, X. et al, Science. 360, 526-530 (2018)
47. Zhu, H. et al, J. Am. Chem. Soc. 139, 8408-8411 (2017).

1. A solid comprising an interconnected nanodomain network;
wherein the solid comprises a first phase and a second phase, wherein the first phase comprises one or more first nanodomains, wherein the second phase comprises one or more second nanodomains;
wherein the solid comprises from about 0.1% to about 99.9% of the first phase; and
wherein the first phase is a metastable high-energy, high-pressure phase that is kinetically trapped at ambient conditions, and wherein the second phase is thermodynamically stable at ambient conditions.

2.-3. (canceled)

4. The solid of claim 1, wherein the first phase is a rock-salt phase, a wurtzite phase, a zinc-blende phase, an amorphous phase, a monoclinic phase, a cubic phase, a rhombohedral phase, a hexagonal phase, a tetragonal phase, or an orthorhombic phase.

5. The solid of claim 1, wherein the second phase is a rock-salt phase, a wurtzite phase, a zinc-blende phase, an amorphous phase, a monoclinic phase, a cubic phase, a rhombohedral phase, a hexagonal phase, a tetragonal phase, or an orthorhombic phase.

6.-9. (canceled)

10. The solid of claim 1, wherein the solid comprises a II-VI semiconductor selected from CdSe, CdS, ZnO, CdTe, ZnSe, ZnS, CdTe, HgS, HgSe, HgTe, MgSe, or any combination thereof.

11. The solid of claim 1, wherein the solid comprises a Ill-V semiconductor selected from AlN, GaN, GaP, GaAs, InN, InP, InAs, or any combination thereof.

12. The solid of claim 1, wherein the solid comprises a IV-VI semiconductor selected from PbS, PbSe, PbTe, or any combination thereof.

13. The solid of claim 1, wherein the solid comprises a transition metal chalcogenide selected from MnS, MnSe, FeS, FeSe, InSe, In₃Se₂, In₄Se₃, Cu_{1.97}S, Cu₂S, TaS₂, Bi₂Se₃, Bi₂Te₃ and Sb₂Te₃, or any combination thereof.

14. The solid of claim 1, wherein the solid comprises a plurality of nanocrystals; wherein the individual nanocrystals of the plurality comprise one or more surface ligands; wherein the one or more surface ligands are present at a density of about 0.1 to about 6.0 ligands per nm² of surface area of the nanocrystals.

15.-17. (canceled)

18. The solid of any claim 14, wherein the one or more surface ligands comprise amines, fatty amines, salts of fatty quaternary ammonium ions, fatty acids or salts thereof, organophosphonic acids or salts thereof, thiols, fatty thiols, inorganic nitrogen-containing compounds, or any combination thereof.

19. The solid of claim 17, wherein the amines comprise pyridine.

20. The solid of claim 18, wherein the fatty amines comprise ethylamine, propylamine, pentylamine, hexylamine, heptylamine, octylaime, nonaylamine, decylamine, undecylamine, dodecylamine, tridecylamine, tetradecylamine, pentadecylamine, hexadecylamine, heptadecylamine, octadecylamine, nonadecylamine, eicosylamine, or any combination thereof.

21. The solid of claim 18, wherein the salts of quaternary ammonium ions comprise fluoride, chloride, bromide, or iodide salts of dodecyltrimethylammonium, didodecyldimethylammonium, or cetyltrimethylammonium ions, or any combination thereof.

22. The solid of claim 18, wherein the fatty acids or salts of fatty acids comprise acetic acid, propanoic acid, valeric acid, hexanoic acid, heptanoic acid, octanoic acid, nonanoic acid, decanoic acid, undecanoic acid, dodecanoic acid, tridecanoic acid, tetradecanoic acid, pentadecanoic acid, hexadecenoic acid, heptadecanoic acid, octadecanoic acid, nonadecanoic acid, eicosanoic acid, salts thereof, or any combination thereof.

23. The solid of claim 18, wherein the organophosphonic acids or salts of organophosphonic acids comprise ethylphosphonic acid, propylphosphonic acid, pentylphosphonic acid, hexylphosphonic acid, heptanylphosphonic acid, octanylphosphonic acid, nonylphosphonic acid, decylphosphonic acid, undecylphosphonic acid, dodecylphosphonic acid, tridecylphosphonic acid, tetradecyl phosphonic acid, pentadecylphosphonic acid, hexadecylphosphonic acid, heptadecylphosphonic acid, octadecylphosphonic acid, nonadecylphosphonic acid, eicosanylphosphonic acid, salts thereof, or any combination thereof.

24. The solid of claim 18, wherein the thiols comprise thiophenol, methylbenzenethiol, ethylbenzenethiol, or any combination thereof.

25. The solid of claim 18, wherein the fatty thiols comprise pentanethiol, hexanethiol, heptanethiol, octanethiol, decanethiol, dodecanethiol, tridecanethiol, tetradecanethiol, pentadecanethiol, hexadecanethiol, heptadecanethiol, octadecanethiol, nonadecanethiol, eicosanethiol, or any combination thereof.

26. The solid of claim 18, wherein the organosulfate salts comprise sodium dodecyl sulfate, sodium dodecylbenzenesulfonate, or any combination thereof.

27. The solid of claim 18, wherein the inorganic nitrogen-containing compound comprises (NH₄)₂S, (N₂H₅)₄Sn₂S₆, or any combination thereof.

28. (canceled)

29. A method for producing a nanocrystal solid comprising a metastable high-pressure phase and a second phase, the method comprising:
(a) surface functionalizing a plurality of nanocrystals; and
(b) sintering the plurality of nanocrystals.

30.-67. (canceled)

68. An article comprising the solid of claim 1; wherein the article comprises an ambient metastable semiconductor, a superconductor, a topological superconductor, a catalyst, a multiferroic material, a soft-hard composite magnet, a nanograined ceramic, a nanograined alloy, or a nanostructured superhard material.

69.-70. (canceled)
